(19) United States
(12) Patent Application Publication
(10) Pub. No.: US 2024/0191497 A1
(43) Pub. Date: Jun. 13, 2024

(54) MODULAR INTERCONNECTABLE HOUSING STRUCTURES AND BUILT STRUCTURES FORMED THEREFROM

(71) Applicant: CURRENTDESIGN PTY LTD, Haberfield NSW (AU)

(72) Inventor: Julie LEUNG, Sydney NSW (AU)

(21) Appl. No.: 18/287,994

(22) PCT Filed: Apr. 26, 2022
(86) PCT No.: PCT/AU2022/050374

§ 371 Date: Oct. 23, 2023

(30) Foreign Application Priority Data
Apr. 23, 2021 (AU) 2021901218

(51) Int. Cl. E04B 1/348; H05K 7/20; H01M 50/258

(52) U.S. Cl. CPC E04B 1/34869; E04B 1/34815; H05K 7/209; H01M 50/258; H01M 2220/10

(57) ABSTRACT

There is disclosed a modular, inter connect able housing structure; said structure comprising an enclosure having wall components which define an internal volume within the enclosure separated from an exterior of the enclosure by the wall components; the enclosure including electrically conductive components for communication of electrical signals from the internal volume to the exterior of the wall components of the enclosure. Also disclosed is an asset control system for controlling the operation of assets; said system including a plurality of modular housing structures formed into at least one built structure; the modules of the housing structures in communication with each other by means of communication modules housed within said plurality of modular housing structures; at least one of the communication modules housed within the built structure also in communication with a server thereby to communicate status of the modules within the built structure to the server.

### TECHNICAL FIELD

Embodiments of the present invention relate to Modular Structures and more particularly but not exclusively to Modular Housing Structures forming a part of or an entirety of a built structure.

More particularly but not exclusively it relates to modular interconnectable housing structures forming part of or an entirety of a built structure.

More particularly but not exclusively it relates to modular interconnectable housing structures forming a part of a built structure.

More particularly but not exclusively it relates to modular interconnectable housing structures forming part of a multiplicity of built structures.

More particularly but not exclusively the housing structures may be interconnectable mechanically. More particularly but not exclusively the housing structures may be interconnectable mechanically in a horizontal plane. More particularly but not exclusively the housing structures may be interconnectable mechanically in a vertical plane. More particularly but not exclusively the housing structures may be interconnectable electrically. More particularly but not exclusively the housing structures may be connectable electrically in a horizontal plane. More particularly but not exclusively the housing structures may be interconnectable electrically in a vertical plane. The electrical interconnection may facilitate communication of electrical power. The electrical interconnection may facilitate communication of electrical power from within a housing structure to external the housing structure. The electrical interconnection may facilitate communication of electrical power between housing structures. The electrical interconnection may facilitate communication of electrical power between built structures. The electrical interconnection may facilitate communication of communications signals for the purpose of communication between ones of the housing structures. The electrical interconnection may facilitate communication of communication signals for the purpose of communication between ones of the built structures.

### BACKGROUND

Batteries forming a wall or panel are known—see for example U.S. Ser. No. 10/439,248 and WO2019016663.

However, the arrangements disclosed are not readily available for a builder or non-electrical trade user to install reliably and with safety.

Batteries and batteries systems these days are being installed in association with sources of renewable energy—particularly sources of electricity derived from wind turbines or solar cells arrays. In these applications, the batteries are used to store electricity generated from these sources for use when the sources are not available (for example for when the wind is not blowing or when the sun is not shining). The batteries are also used for smoothing, load-levelling and “stiffening” of the power system.

Batteries are relatively bulky. There can also be issues with safety given the relatively large amounts of energy they can store.

It would be advantageous if batteries could be combined with or combined into other structures or actually comprise the structure—for example walls whereby the wall structure can perform with the function of energy storage and conversely the batteries forming the wall structure can perform the function of a wall—including but not limited to the structural (including load bearing) functions and the aesthetic functions.

Such an arrangement would address the bulk problem that batteries can represent.

Further problems are as follows:

### Problems Addressed by Embodiments of the Invention

It would be advantageous if the community had available to it solutions to the following problems:

PROBLEM 1: EMPOWERING BEYOND POLICY CONTROLS: Do-It Yourself construction power and building products which enable individuals or businesses to more readily enhance/build their infrastructure and assets.

PROBLEM 2: DEMOCRATISING HUMAN RIGHTS (HOUSE a POWER): Safety engineering of energy storage & building product, is possible through product design, electrical engineering, materials engineering, software control and sensors.

PROBLEM 3: REDUCING WASTE AND MAKING CONVENIENCE: If the materials engineering and product engineering could mitigate design obsolescence and provide a carbon sink using low-carbon emission sourced materials, and considering the lifecycle re-use.

PROBLEM 4: REMOVING UNETHICAL SALES TACTICS IN RENEWABLES: Modular DIY energy storage & building systems can systemise quality and access to a wider population, including the elderly who are currently vulnerable to unethical sales practices of being locked into under performing-over priced solar-energy storage system financial schemes.

PROBLEM 5: EMPOWERING ORDINARY PEOPLE: Smart software-application based systems can introduce baseline knowledge in user friendly form, using technology aids whilst reading instructions for assembly and understanding simple control interfaces.

PROBLEM 6: ENABLING SUSTAINABLE DEVELOPMENTS EASILY: Modular DIY micro-energy storage-building systems can reduce financial burden of the state infrastructure budgets and estate infrastructure development.

PROBLEM 7: HELPING THE COST OF ENERGY & INFRASTRUCTURE COSTS/TRANSITION for LOW CARBON ECONOMY: Infrastructure asset share prices are fluctuating to the financial controls of monopoly pyramid structures. The hypothesis is that DIY energy storage integrated into our building spaces and furnishings creates opportunity for infinite storage solutions depending on the embedded price of the battery technology and the by-products at the end of life.

PROBLEM 8: EMPOWERING RENTALS, OWNERs & CHANGEMAKERS: Modularity of energy storage embedded in building materials equivalent to “utility cabinets” in the DIY form allows people to by-pass excessively prescriptive legislation control policies and authority approvals.

PROBLEM 9: EMPOWERING HOUSE & FURNITURE BUILDS WITH ENERGY STORAGE (Untapped DIY): Task based energy usage will reduce the overall peak loads of the fixed grid network, and enable micro-scale power usage optimisation for renewables (plug in renewable grid supply and localised built in renewables).

PROBLEM 10: RENEWABLE ENERGY SPONGE: Peak energy demand will be buffered and offset with the task specific usage and energy storage economics.

PROBLEM 11: REMOTE ASSET CONTROLS & DATA MANAGEMENT: Large scale data management systems of the built-in energy storage building material will allow micro control optimisation (using large scale asset management techniques and strategies).

PROBLEM 12: POWER IN THE COMMUNITY (VIRTUAL POWER PLANTS): Virtual power plants is in symbiosis with current energy market parameters. Micro-energy optimisation systems including energy storage into building DIY products will allow greater scalability, by deconstructing the entry price to market to be lower and enabling the user to progressive purchase their asset.

PROBLEM 13: COMMERCIAL/INDUSTRIAL/EDUCATION/COMMUNITY: Variable usage of power include single phase, three phase, direct current and alternating current can be made available in the form of DIY modular-building materials for all usage scenarios when installed at scale.

PROBLEM 14: ENERGY HUBS—AGILE POWER: Built in-floor plan power cabled systems can be used less, when implementing micro-decentralised charging kiosks and monitored micro-scale controls. Eg. For libraries (as computer workstations are spread throughout the campus through hot desks and meeting rooms). Fixed installations can be phased out for staff meeting rooms etc.

PROBLEM 15: ENABLING FARMING & REMOTE SETTLEMENTS: Micro-storage grid islands allow for bespoke efficient use for all variable forms for energy generation, storage and settlements in remote areas without any other grid infrastructure.

PROBLEM 16: EMERGENCY RESPONSE AND INFRASTRUCTURE CONTINGENCY: Integrated DIY-energy storage & building systems can enable emergency response or basic infrastructure contingency during catastrophic events. A building material energy storage DIY system that enables “low/no skill levels” to deploy this technology—benefits quality of life and ability to redirect critical resources to higher priority issues.

### Existing User Problems of Prior Art

PROBLEM 17—Do-It-Yourself: Cross disciplinary challenges. Electricity is complex, dangerous and enough of a challenge. Combining aesthetic finishes and engineering performance and product design, exceeds technical skill set interests of standard remits in the qualifications of an industrial designer, electrical engineer etc.

The Do-It-Yourself market still has very rigid non-aesthetic solutions that do not give the flexibility that this invention intends.

The current systems are knowledge intensive regarding safety and reliability, this invention is designed to resolve this issue integrating features of hardware and software in the built environment.

### Problem 18—Professionals:

### Problem 18A—Architects/Builder/Developers/Renovators

The tick box process for services to provide electricity and buildings is under time-based financial pressures and the strict compliance requirements. Clean Energy Council and Australian Standards limit the ability to have creative solutions. Tesla/LG Power Walls are systems being implemented due to the availability and simplicity and have a proven track record.

Green Building standards lobby (e.g. Greenstar etc) is a development-oriented group to accelerate innovative sustainable performance in building design and construction.

Game-breaking innovations that are implemented can be awarded the prestigious “star”. However, it is well known this pursuit is at great expense and pressure to achieve.

### Problem 18B—Infrastructure Industry (Energy Generators):

Due to strict compliance rules because both the energy industry and the building industry are in almost silo ecosystems. Technologies integrating renewables via hybrids such as micro-grids in housing estates introduce additional costs and program complexity when both industries are highly commoditized. However, commercial and highrise have been optimising localised micro-grid systems for reducing overall facilities operational costs and improving their sustainability messaging.

Some electricity suppliers provide package deal options for micro-grid estates which include the localised substations and long term financing offerings in exchange (e.g. usage & operation charges).

Virtual Power Plants have been utilising existing established products on the market involving wired in solutions or Electric Vehicle to Grid power integration.

### Problem 18C—Community and Open Spaces Infrastructure/Educational Facilities

The town planning and infrastructure development process is led by council officers and consultants. These are engagements limited on time charge. The implementation of existing technologies is aligned to their program and delivery performance requirements

Unique technologies, street-art & streetscape showcase in this jurisdiction. However, opportunities present on small scale Expression of Interest community scale notifications or are large competitive prestigious campaigns

PROBLEM 18D—Emergency Response/Infrastructure Contingency: UPS, petrol generators, solar and battery systems requiring engineering expertise. R&D into this area for aesthetic, functional and convenient solutions is of lower priority compared to the speed of deployment and availability.

### BACKGROUND SUMMARY

Three key areas remain outstanding in the problem constraints of prior art, to which the boundaries of innovation are contained or limited by:

### Summary Part 1

1a. Problem Constraint of Prior Art: Energy/battery/building construction systems do not cater for a Do-It-Yourself consumer need.

1b. Corresponding Boundaries of Innovation to Date: Current safety extension cords and circuit breakers are existing in built-in wall sockets and existing fixed grid 240V AC equivalent system or 3-phase power supply outlet.

Current energy storage Virtual Power Plant technologies operate on the basis of wired-in technologies. Larger scale battery modules operate as localised large scale substations providing back up power during outages.

Alternatives such as a table top Uninterrupted power supply are available, however consume bench top space and are not aesthetic, not designed for rugged indoor/outdoor style surface treatment

Built-in wall sockets and charging points constrain users the convenience and aesthetics via extension cords, cable trays and limited charging points.

### Summary Part 2

2a. Problem Constraint of Prior Art: Back up power/battery systems are available in the current rigid and limited forms: Built-in-battery storage (trade certified); Server system energy storage (trade certified); Detached built in large scale shared infrastructure (community title or supplier agreement models); Micro-grids; Improvised home style battery arrays; and Petrol Generators.

2b. Corresponding Boundaries of Innovation to Date: High skill level required to safely install power systems, or requiring significant time investment to gain confidence. Virtual Power Plant technologies currently operate on the basis of wired-in technologies such as Electric Vehicles, domestic wired in power walls, and estate batteries. Task based energy usage has been overlooked. Focus has been on the large scale utility oriented power supply. Not including the micro-energy storage potential contained in isolated home office work stations, entertainment systems, lighting networks and electrical appliances people are reliant on in every day usage contexts.

### Summary Part 3

3a. Problem Constraint of Prior Art: Trade knowledge and engineering knowledge is intimidating due to the engineering complexity, safety risk and terminology.

3b. Corresponding Boundaries of Innovation to Date: User experience design is not present or available in the Do-It-Yourself context for optimising user flexibility and needs. Task based energy usage has not been available due to fixed grid and built-in wiring paradigm. Micro-scalable energy storage and assembly has not been available due to the safety implications, with current energy demand accumulating to higher voltages at the power source connection.

Consequently requiring cumbersome large battery systems to be installed.

Embodiments of the invention seek to address one or more of the above-referenced problems and issues.

### Notes

The term “comprising” (and grammatical variations thereof) is used in this specification in the inclusive sense of “having” or “including”, and not in the exclusive sense of “consisting only of”.

The above discussion of the prior art in the Background of the invention, is not an admission that any information discussed therein is citable prior art or part of the common general knowledge of persons skilled in the art in any country.

### SUMMARY OF INVENTION

Energy storage and power use is typically wired-in, expensive and bulky. Wall sockets are fixed, requiring extension cables or costly qualified labour.

Embodiments of the present invention provide for “smart” construction materials which may enable: Low-skill user interfaces for indoor/outdoors and temporary/permanent use; Quick and easy set-up, installation/adjustment to all things electrical from appliance to control-board; serviceability; recyclability; a carbon efficient alternative to big infrastructure.

Combining building materials, electricity/energy storage product markets may create savings in materials/energy/money whilst reducing carbon. Providing large-scale intelligent systems and control into everyday buildings, forms and spaces. Conveniently and aesthetically optimising limited real estate.

Prior art requires a lot of knowledge for safe assembly.

Embodiments of the present invention may enable “Do-it-yourself” (DIY) style of assembly of energy storage and supply systems. The basic level of skill is designed to be intuitive as building block toys.

Embodiments of the present invention may enable Automatic Control Switches (ACS) required to access and personalise current art of wired in energy storage and grid connection energy supplies. Embodiments of the present invention may enable connection to the wired in with expert trades to install the ACS.

Embodiments of the present invention may enable design to reduce the knowledge gap and time to deploy energy storage and power supply in either grid connected or energy micro-island scenarios.

Embodiments of the present invention may enable power supply, energy storage and building materials to be integrated to enable more easily the human right for warmth and lighting, and having a shelter for safety and comfort.

Embodiments of the present invention may enable safety engineering of energy storage & building product to be possible through product design, electrical engineering, materials engineering, software control and sensors.

e.g. All terminals (positive and negative terminals) are interconnected by specific compatible shapes.

Embodiments of the present invention may enable safety measures and control in the product by mechanical means with the interconnecting components. e.g. Incompatible shapes of the plugs will ensure the user does not need to have prior knowledge of what “positive” and “negative” terminals are.

Embodiments of the present invention may enable a power circuit to be activated only when plug connectors fit. Sensor control fail safes and remote hold points may need verification to ensure circuit is correctly interconnected. Remote sensor checks may verify and activate the current when verified, to enable the system to turn “On”. Mitigating risk of switching polarities around will occur for the specific bus bars and expander bars for the usage of 12V, 24V and 48V cells.

Embodiments of the present invention may enable usage cases of parallel and in-series arrangements.

Embodiments of the present invention may enable integration of these key elements to achieve and collectively include micro and low voltage energy systems interfacing with high voltage energy systems.

Embodiments of the present invention may enable “smart” construction materials which enable low-skill user interfaces for indoor and outdoors or for temporary and semi-permanent use for power storage and supply. Embodiments of the present invention may enable arrangements specifically for allowing convenience and personalization for power outlet locations and energy storage configuration.

Embodiments of the present invention may enable maximizing of function of limited spaces in our buildings and open spaces—in the confines of our walls and added furnishings.

Energy storage and power use is typically wired-in, expensive and bulky. Wall sockets are fixed, requiring inconvenient extension cables or costly specialized qualified labour.

This invention provides large-scale intelligent systems and control in micro-forms and spaces. Capturing the remnant energy efficiency opportunities through remote control data systems. This technology is not currently available in the art of energy storage, particularly in relation to coordinating micro-energy storage, where the optimization can account for large scale impact.

Embodiments of the invention may capture micro-opportunities to optimize on the spatial and financial burden of centralised infrastructure. The current art of energy efficiency focuses on centralized large scale assets built to achieve the benefit of large scale energy savings. The current arts appreciate building powerbanks to estate substation powerbanks. Virtual power stations are accounting for the larger scale and usage of powerbanks and energy storage.

Combining building materials, electricity-energy storage product markets creates savings in materials, energy and money whilst reducing carbon.

The embodiment of this invention is providing user interface “portal” for both operation, management and maintenance of their asset. The direct nature of this database-user control system is to ensure total quality management in the lifecycle of the product's use, installation and operation.

Able to be incorporated into portable power usage contexts such as furniture, streetscapes and retaining walls, or used in space via 3D printing.

Reduces “carbon” via carbon sink of providing circular economy based housing materials such as recycled products or by products (lower environmental impact and material waste cycles).

Able to modified and tailored to changing needs without material waste—due to relocatable, re-usable and repairable nature of components.

Enables larger scale energy efficiency opportunities through capturing task based energy usage.

Water tight/Air Tight Options

Part of Wall (indoor or outdoor)

Part of a furnishing (indoor or outdoor) including lighting infrastructure/lanterns, and hard landscaping.

Preferably the wall structure further incorporates frame components.

Modularity of energy storage embedded in building materials equivalent to “utility cabinets” in the DIY form allows people to by-pass excessively prescriptive legislation control policies and authority approvals.

Preferably the frame components include structural components to protect the battery modules from load.

The wall structure wherein the frame components are spaced so as to ensure thermal performance and longevity of the battery modules.

Preferably the frame components include a processing device to impart intelligence to control of the components of the wall structure.

Preferably the battery modules and the frame components are assemblable and disassemblable by non-trade personnel.

Preferably the battery modules are adaptable to a variety of technologies and can be reconfigured structurally for a variety of usage scenarios.

Accordingly, in one broad form of the invention there is provided a modular, interconnectable housing structure; said structure comprising:

An enclosure having wall components which define an internal volume within the enclosure separated from an exterior of the enclosure by the wall components;

The enclosure including electrically conductive components for communication of electrical signals from the internal volume to the exterior of the wall components of the enclosure.

Preferably the modular interconnectable housing structure or multiple ones of the modular interconnectable housing structure form part of a built structure.

Preferably the modular interconnectable housing structure or multiple ones of the modular interconnectable housing structure form an entirety of a built structure.

More particularly but not exclusively the housing structures may be interconnectable mechanically with adjacent like housing structures.

More particularly but not exclusively the housing structures may be interconnectable mechanically in a horizontal plane.

More particularly but not exclusively the housing structures may be interconnectable mechanically in a vertical plane.

More particularly but not exclusively the housing structures may be interconnectable electrically.

More particularly but not exclusively the housing structures maybe connectable electrically in a horizontal plane.

More particularly but not exclusively the housing structures may be interconnectable electrically in a vertical plane.

The electrical interconnection may facilitate communication of electrical power.

The electrical interconnection may facilitate communication of electrical power from within a housing structure to external the housing structure.

The electrical interconnection may facilitate communication of electrical power between housing structures.

The electrical interconnection may facilitate communication of electrical power between built structures.

The electrical interconnection may facilitate communication of communications signals for the purpose of communication between ones of the housing structures.

The electrical interconnection may facilitate communication of communication signals for the purpose of communication between ones of the built structures.

Preferably the wall components form a contiguous surround of the volume.

Preferably the surround is non-re-entrant in at least one dimension

Preferably the surround is re-entrant in at least one dimension.

Preferably the at least one dimension is a vertical dimension.

Preferably the at least one dimension is a horizontal dimension

Preferably the surround is re-entrant so as to interlock in at least one plane with a like, complementary wall component of a juxtaposed adjacent wall component of a juxtaposed like modular battery housing structure.

Preferably the wall components include a water resistant element.

Preferably the wall components include a vibration resistant component.

Preferably the wall components include a veneer.

Preferably the veneer is placed over and is coextensive with a substrate.

Preferably the wall components include more than one veneer whereby an outer veneer is overlaid over and coextensive with an inner veneer.

Preferably the outer veneer is an aesthetic veneer.

Preferably the veneer is a water resistant or water tight veneer.

Preferably the veneer is a vibration resistant veneer.

Preferably the veneer is a shock resistant veneer.

Preferably the veneer is an electrically insulating veneer.

Preferably the veneer is a temperature insulating veneer.

Preferably the modular housing structure includes a crack healing composition.

Preferably the modular housing structure is repairable and paintable.

Preferably the modular housing structure is of child proof level complexity.

Preferably the modular housing structure is tamper proof and tamper resistant.

Preferably the modular housing structure is fire resistant.

Preferably the veneer is designed for selective removal in specific locations e.g. at the tracking rails, at the parallel and single charge bus bars for locating the horizontal connection/tracking rail charge outlet.

Preferably the modular housing structure is moulded or 3d printed in combination of 1D,2D and 3D forms.

Preferably the modular housing structure is self healing.

Preferably the modular housing structure includes materials and composition which resisting-use natural wear and tear.

Preferably the materials impart environmental durability against degradation.

Preferably the materials impart self-healing to extend longevity, durability performance.

Preferably the materials impart repairable characteristics—or are repairable.

Preferably the materials include knitted steel.

Preferably the materials include knitted glass fibre.

Preferably the materials include weaved glass fibre.

Preferably the materials include intertwined knitted steel and glass fibre.

Preferably the materials include ultra light high strength engineered concrete composite.

Preferably the materials include a heat sink.

Preferably the materials impart a shock absorbent characteristic.

Preferably the veneer is formed of tiles.

Preferably the electrical signals are electrical power signals.

Preferably the electrical signals are electrical communication signals.

Preferably the electrically conductive components are busbars.

Preferably the electrically conductive components are rails.

Preferably the rails are tracking rails.

Preferably the rails are charging rails.

Preferably the electrically conductive component includes a releasably connectable component.

Preferably the releasably connectable component is a mechanically releasable component.

Preferably the releasably connectable component is an electrically releasably connectable component.

Preferably the wall components are stackable in a vertical dimension.

Preferably the wall components are juxtapose-able in a horizontal dimension.

Preferably the wall components are precast.

Preferably the wall components include frame components.

Preferably the wall components include sheet components.

Preferably the components are structural components.

Preferably the wall components are structural and contain battery cells.

and components.

Preferably the wall components are adaptive to accommodate fasteners.

Preferably the wall components of the modular structures are structured to support the weight of one or more like modular structures stacked on top.

Preferably the modular structures, the rails, inverters, bus bars, outlets are stackable.

Structure in combination.

Preferably the modular structures have positive and negative terminals that cannot be activated/contacted unless endcaps and expander bars are inserted.

Preferably the components are load-bearing.

Preferably the volume may enclose an electrical storage component.

Preferably the electrical storage component is a battery.

Preferably the electrical storage component is a fuel cell.

Preferably the volume may enclose an electrical generation component.

Preferably the electrical generation component is a solar cell.

Preferably the enclosure is releasably mechanically connectable to a juxtaposed like enclosure.

Preferably the enclosure is releasably chemically connectable to a juxtaposed like enclosure by clasps.

Preferably the clasps are electrically conductive.

Preferably the clasps are electrically conductive so as to function both as a clasp and as an electrical conductor thereby to maintain juxtaposed like enclosures mechanically connected when the clasp is in a clasping position and to conduct electrical signals between the juxtaposed like enclosures.

Preferably electrical signals are conducted from within the volume of a one of the juxtaposed like enclosures to within the volume of the other of the juxtaposed like enclosures.

Preferably the volume also encloses a communications module.

Preferably the volume also encloses a rectifier module.

Preferably the volume also encloses a switch module.

Preferably the volume also encloses a voltage converter module.

Preferably the volume also encloses sensors.

Digital Data storage.

Fast acting leak earth leakage switch.

Optional single way or bi-direction vents—for pressure/water regulation of the cavity (if required).

Optional add on plugs (tamperproof/single use) to seal the volume/repair.

optional control/indicator board

Fuel Cells

voltage sensing relay

Inverter for AC

AC induction charger or equivalent

Inverter for 3 phase

DC/wireless outlet connections suitable for any electronic appliance

Preferably the sensors include Internet of Things sensors.

In a further broad form of the invention there is provided a fault detection and installation optimisation system assisting personalized control features utilizing

Artificial Intelligence algorithms to assist both for load and energy use.

Configuration relative to spatial constraints (Semi-virtual reality guided assistance for assemblies and adaptations).

guiding and educating user of system optimisation strategies such as the Solar Sponge and interfacing with renewable system,

and designated user security levels for managing aspects of the operation of assets; said system including

A plurality of modular housing structures formed into at least one built structure;

The modules of the housing structures in communication with each other by means of communication modules housed within said plurality of modular battery housing structures;

At least one of the communication modules housed within the built structure also in communication with a server thereby to communicate status of the modules within the built structure to the server.

Preferably the modular battery housing structures are the modular housing structures of any of the above claims.

Preferably an asset includes the at least one built structure.

Preferably an asset includes multiple ones of said at least one built structure.

Preferably the built structures under management are located local to each other.

Preferably the built structures under management are located geographically separate from each other.

Preferably the communication modules of the modular battery housing structures are utilised to communicate with the server by transmission of signals over the Internet.

Preferably the signals contain status data.

Preferably the status data includes battery capacity data.

Preferably the status data includes battery level data.

Preferably the signals include control signals.

Preferably the control signals permit control of the built structures.

Preferably the control signals permit control of the built structures by transmission of command signals from the server to the modular battery housing structures forming the built structures.

Preferably the asset management system is a self initiated asset management system.

Preferably the asset management system is integrated with other energy storage systems.

Preferably an aspect includes orchestrating an aspect of the asset.

In a further broad form of the invention there is provided an asset control system for controlling the operation of assets; said system including
a plurality of modular housing structures formed into at least one built structure;
the modules of the housing structures in communication with each other by means of communication modules housed within said plurality of modular housing structures;
at least one of the communication modules housed within the built structure also in communication with a server thereby to communicate status of the modules within the built structure to the server.

Preferably each modular housing structure is a modular housing structure as claimed in any of the above claims.

Preferably the housing structures may enclose an electrical storage component.

Preferably the electrical storage component is a battery.

Preferably the electrical storage component is a fuel cell.

Preferably the housing structures may enclose an electrical generation component.

Preferably the electrical generation component is a solar cell.

Preferably the modular housing structures are the modular housing structures of any of the above claims.

Preferably the intelligence (AI) for optimization processes can receive inputs from modules unrelated to the invented system, and provide analytics to suggest methods for improvement in power saving and energy contracts, energy supplier agreement, or tenancy thresholds for power use W and KWh relative to the time of day, date and location, base load/draw of power for given intervals of time.

Preferably an asset includes the at least one built structure.

Preferably an asset includes multiple ones of said at least one built structure.

Preferably the built structures under control are located local to each other.

Preferably the built structures under control are located geographically separate from each other.

Preferably the communication modules of the modular battery housing structures are utilised to communicate the server by transmission of signals over the Internet.

Preferably the signals contain status data.

Preferably the status data includes battery capacity data.

Preferably the status data includes battery level data.

Preferably the signals include control signals.

Preferably the control signals permit control of the built structures.

Preferably the control signals permit control of the built structures by transmission of command signals from the server to the modular battery housing structures forming the built structures.

Preferably the control signals permit control of the built structures so as to orchestrate function of the built structures.

Preferably the asset control system is a self initiated asset management system.

Preferably the asset control system is integrated with other energy storage systems.

In a further broad form of the invention there is provided a virtual powerplant system; said system including
a plurality of modular housing structures formed into at least one built structure;
the modules of the housing structures in communication with each other by means of communication modules housed within said plurality of modular battery housing structures;
at least one of the communication modules housed within the built structure also in communication with a server thereby to communicate status of the modules within the built structure to the server.

Preferably each modular housing structure is a modular housing structure as claimed in any of the above claims.

Preferably the housing structures may enclose an electrical storage component.

Preferably the electrical storage component is a battery.

Preferably the electrical storage component is a fuel cell.

Preferably the housing structures may enclose an electrical generation component

Preferably the electrical generation component is a solar cell.

Preferably the modular housing structures are the modular housing structures of any of the above claims.

Preferably the system includes multiple ones of said at least one built structure.

Preferably the built structures under control are located local to each other.

Preferably the built structures under control are located geographically separate from each other.

Preferably the communication modules of the modular housing structures are utilised to communicate to the server by transmission of signals over the Internet.

Preferably the signals contain status data.

Preferably the status data includes battery capacity data.

Preferably the status data includes battery level data.

Preferably the signals include control signals.

Preferably the control signals permit control of the built structures.

Preferably the control signals permit control of the built structures by transmission of command signals from the server to the modular battery housing structures forming the built structures.

Preferably control includes orchestration of functions of the built structures to operate in tandem with built structures in other locations.

Preferably the virtual power plant system is a self initiated system.

Preferably the virtual power system is integrated with other energy storage systems.

In a further broad form of the invention there is provided a wall structure comprised of a plurality of battery modules; each battery module including

An electrical storage component

A mechanical interlock component for mechanical connection to adjacent battery modules

An electrical interconnection component for electrical connection for adjacent battery modules.

Preferably the wall structure further incorporates frame components.

Preferably the frame components include structural components to protect the battery modules from load.

Preferably the frame components are spaced so as to ensure thermal performance and longevity of the battery modules.

Preferably the frame components include a processing device to impart intelligence to control of the components of the wall structure.

Preferably the battery modules and the frame components are assemblable and disassemblable by non trade personnel.

Preferably the battery modules are adaptable to a variety of technologies and can be reconfigured structurally for a variety of usage scenarios.

### BRIEF DESCRIPTION OF DRAWINGS

Embodiments of the present invention will now be described with reference to the accompanying drawings wherein:

FIG. 1 illustrates a first embodiment of a wall structure 10 comprised of a plurality of battery modules

FIG. 2 illustrates a components of a processing system which can be incorporated into the structure of FIG. 1 in order to impart intelligence,

FIG. 2A—is a block diagram of three modular interconnectable housing structures, connected in a vertical array. So as to form a built structure.

FIG. 2B—An example of use of the built structure of FIG. 2A, as part of an Asset Control System.

FIG. 2C—An example of use of the built structure of FIG. 2A, as part of an Grid Control System.

FIG. 2D—A flow chart of the logic applicable to the example of FIG. 2C operating as a virtual power plant.

FIG. 3 is a wall structure illustrating the main components according to a first embodiment

FIG. 4. Illustrates the battery brick structure of FIG. 3 in more detail,

FIG. 5 illustrates further technical specifications for the battery structure

FIG. 6 illustrates details of the conducting clasps for interlinking the battery modules of FIG. 3,

FIG. 7 demonstrates features of brick outlet controllers applicable to the arrangement of FIG. 3,

FIG. 8 illustrates a standalone brick structure including layers and an aesthetic cover applicable to the arrangement of FIG. 3,

FIG. 9 illustrates further details of the brick structure applicable to the arrangement of FIG. 3,

FIG. 10 illustrates further options for the brick structure of FIG. 3 including conductive strips,

FIG. 11 illustrates further detail including support arrangements for the brick structure,

FIG. 12 demonstrates further options for the conductive strips and structure of the brick structure applicable to the arrangement of FIG. 3,

FIG. 13 illustrates details of the aesthetic cover with inbuilt circuit breaker applicable to the arrangement of FIG. 3,

FIG. 14 illustrates further details of the aesthetic cover and optional inbuilt circuit breaker arrangement,

FIG. 15 illustrates safety pins operable in conjunction with the aesthetic cover and inbuilt circuit breakers of FIG. 14,

FIG. 16 illustrates further arrangements for the aesthetic cover and its supports and further showing the arrangement where is that it covers have been interconnected with a class and an outlet is installed, all communicable with the processing arrangement of FIGS. 1 and 2,

FIG. 17 illustrates more detail of the conduction clasps operable to connect like battery components,

FIG. 18 illustrates a battery structure arranged in a wall configuration according to a second embodiment of the present invention,

FIG. 19 illustrates perimeter sensor structures usable with the arrangement of FIG. 18,

FIG. 20 illustrates further structural aspects of the arrangement of FIG. 18,

FIG. 21 illustrates yet further structural aspects of the arrangement of FIG. 1B and

FIG. 22 illustrates compatible corner interconnections and a sensor interface operable in conjunction with the arrangement of FIG. 18.

FIG. 23—Example of a preferred Embodiment utilising specific form factor of battery cell technology BYD Blade LiFePO4 composition. Detailed description of the physical attributes and functions of the module components at a functional level through labels M1, M2, M3 including M3.1 and M3.2 for the battery cell, and modular housing layers.

FIG. 24A HARDWARE-SOFTWARE INTERFACES Indicates hardware components connecting to the Internet Of Things Gateway processing chip. Diagrams list the range of example components to which hardware will interact and integrated sensors, remote controls and data tracking, to form part of the Asset Management Control System and the complement of the Virtual Power Plant capabilities.

FIG. 24B INTERNET OF THINGS GATEWAY ARCHITECTURE: Outline of datasets to and from various assets to the cloud, using remote algorithms and user control settings and features for various user types and asset classes.

FIG. 24C: Example of a IOT array block diagram of “Built In example embodiments” (2000 W and 3000 W threshold system) relating to the main console.

FIG. 24D: Example of a IOT array block diagram of “Non-Built In Semi-Permanent” example embodiments (both with 3000 W threshold system) relating to the main console.

FIG. 242: Example of a IOT array block diagram of “Non-Built In Temporary” example embodiments (both with 3000 W threshold system) relating to the main console.

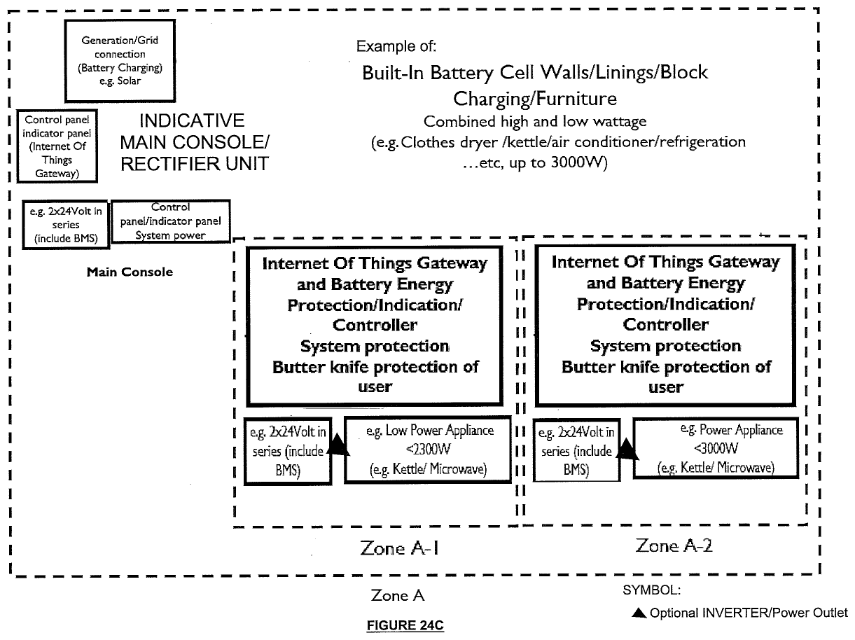

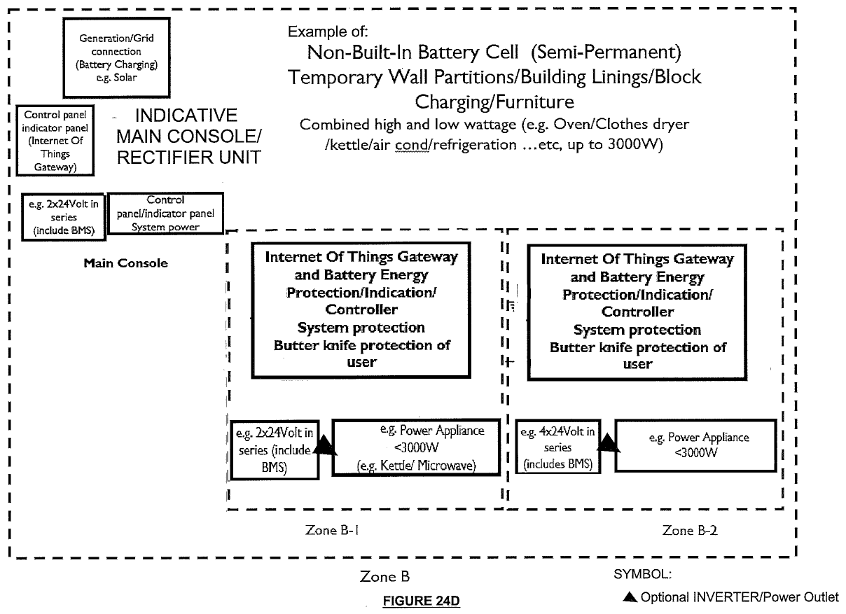

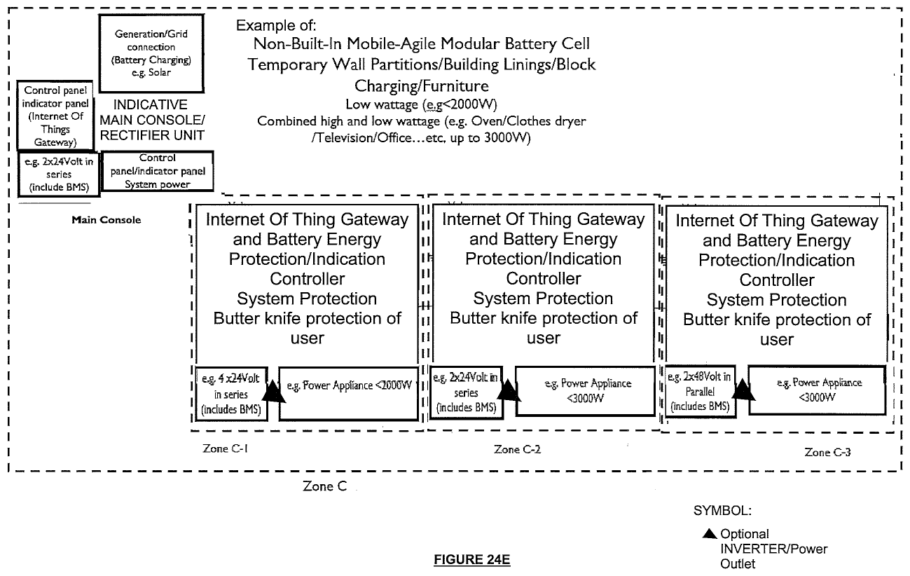

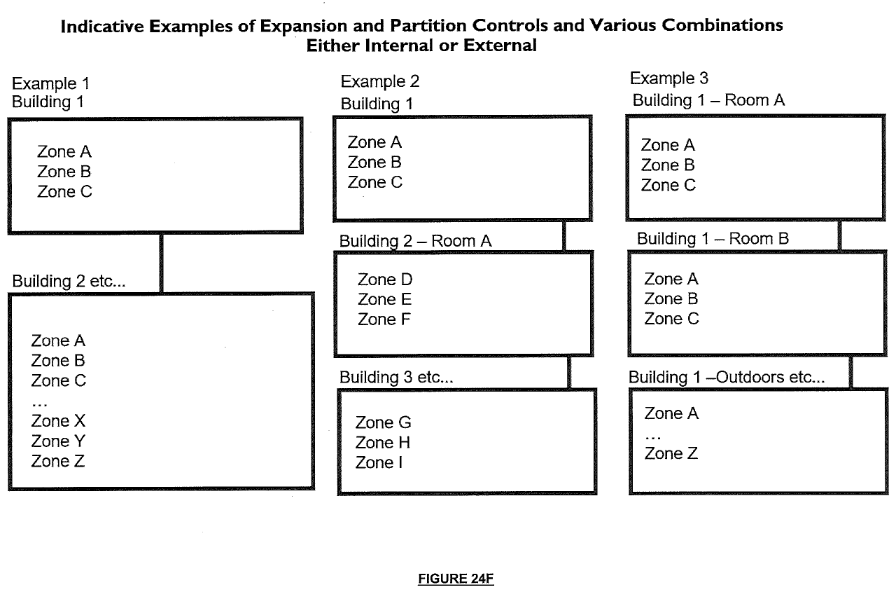

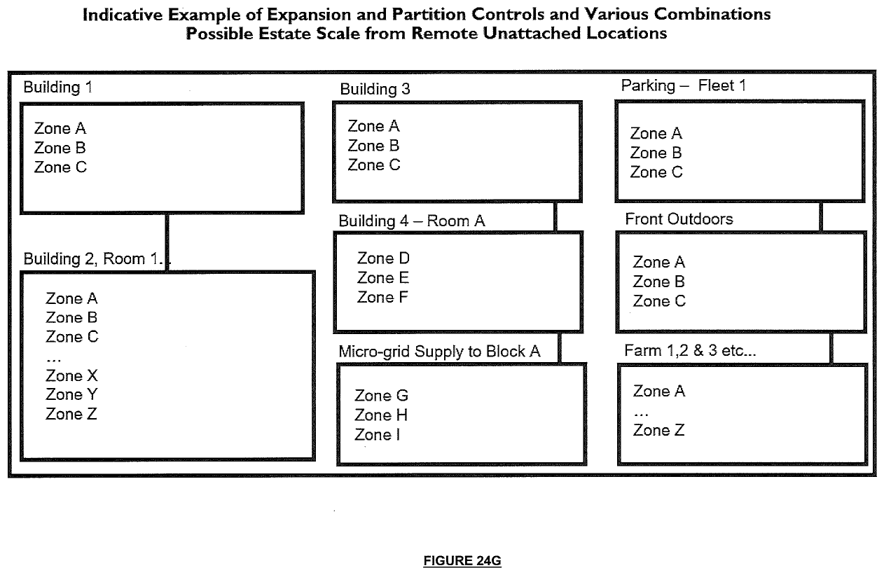

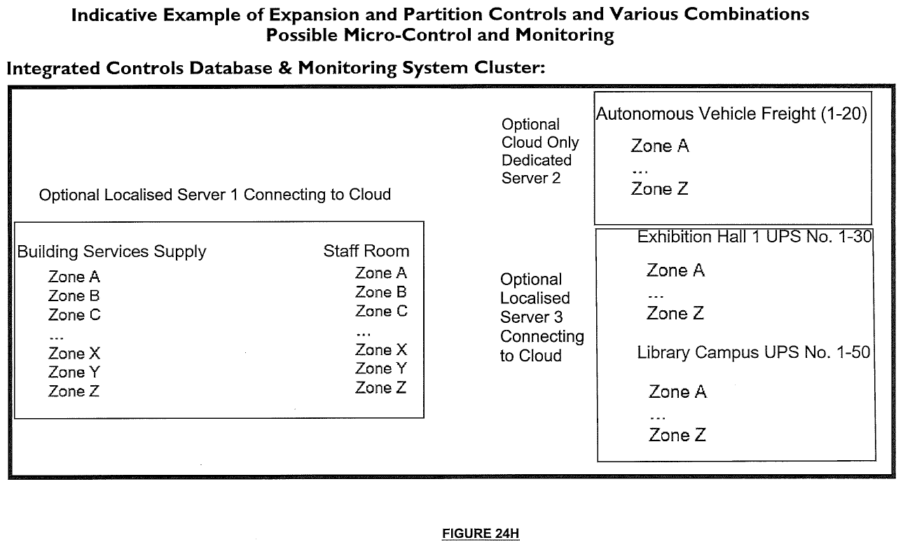

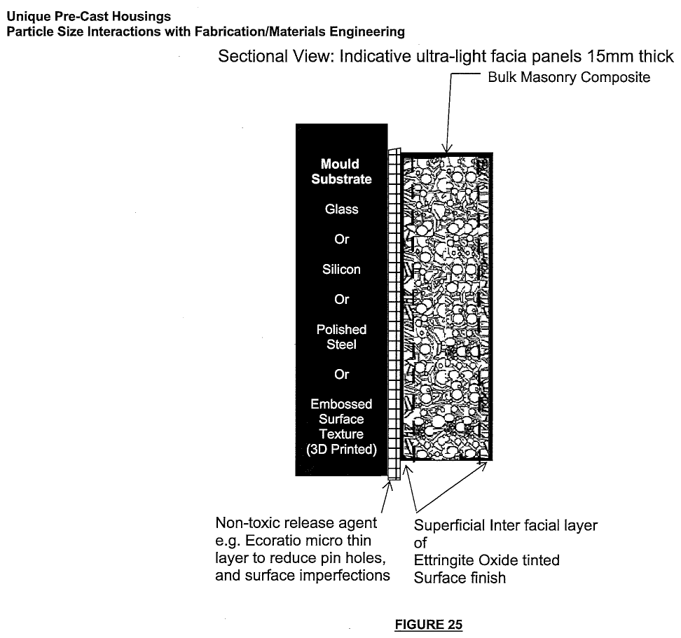

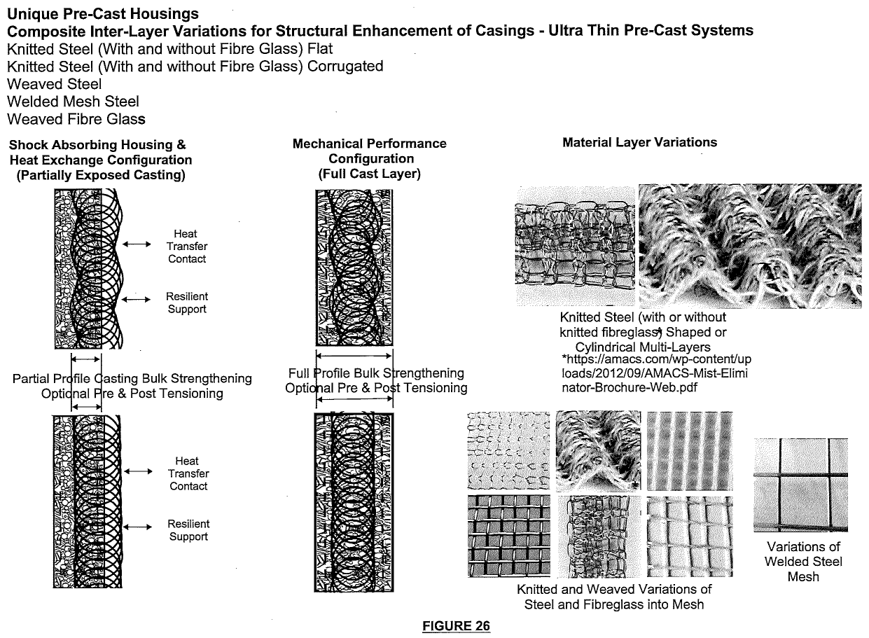

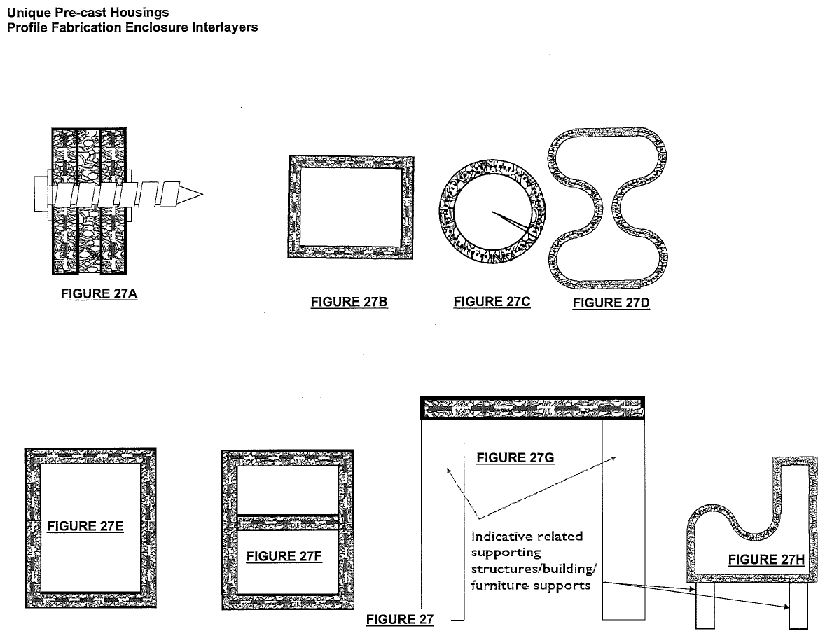

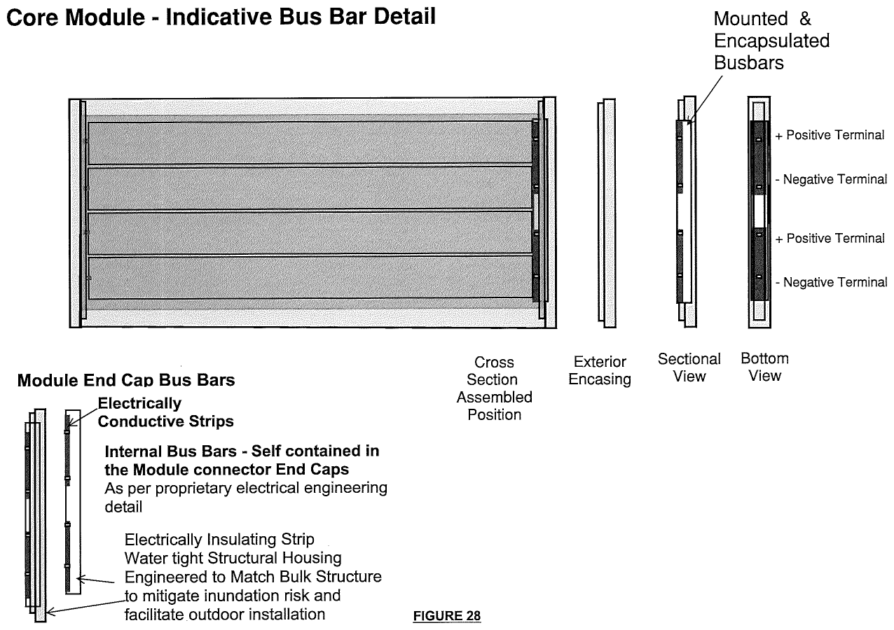

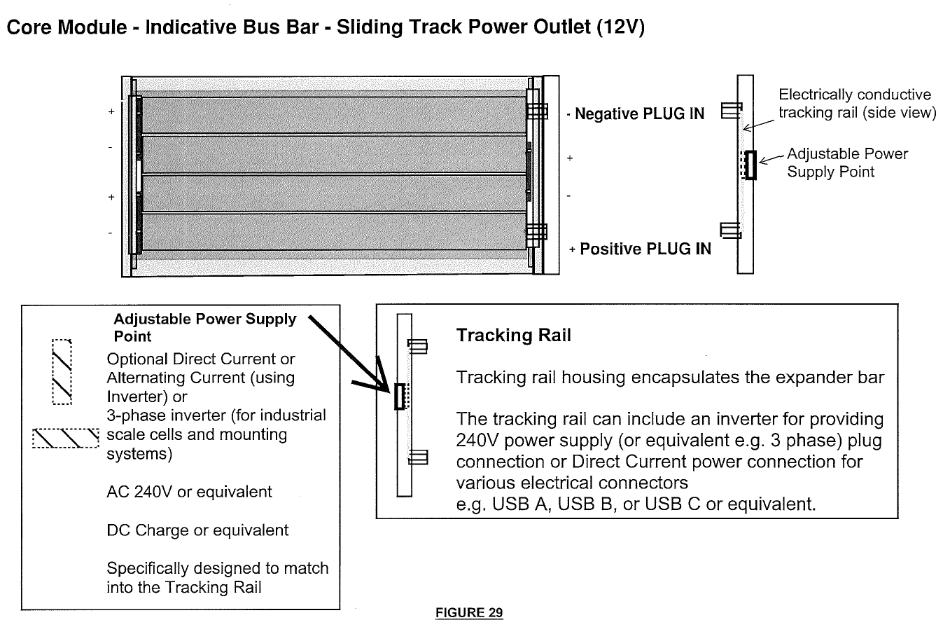

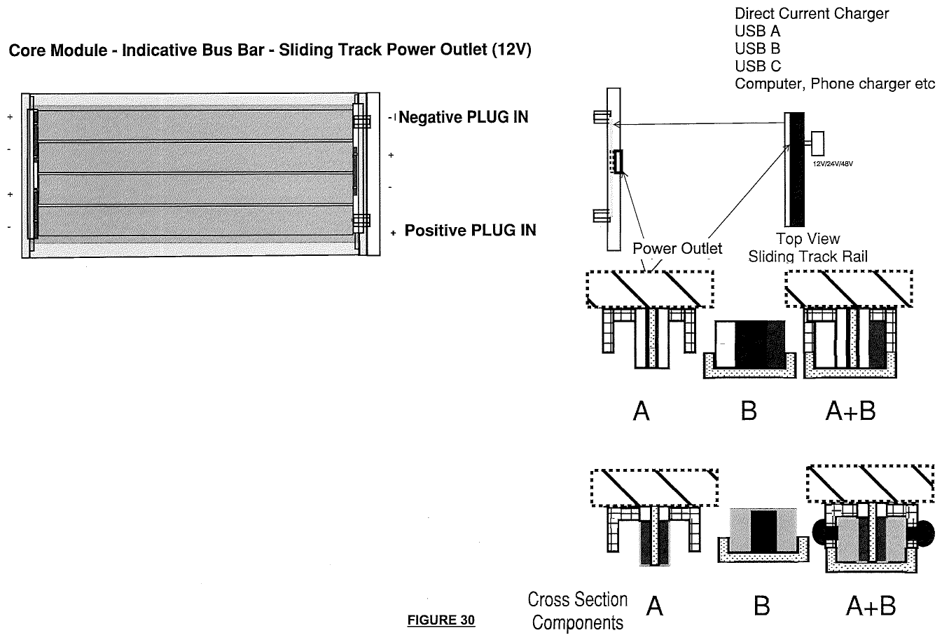

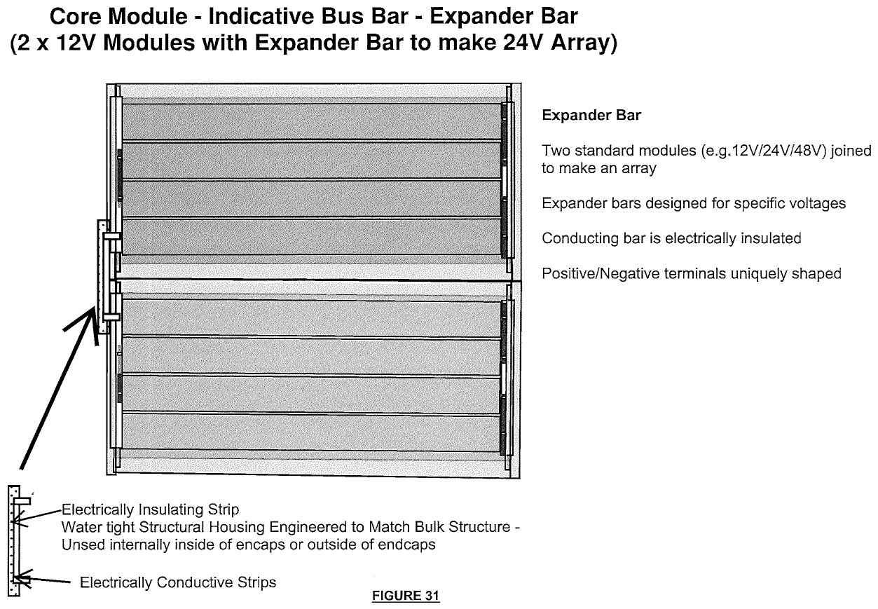

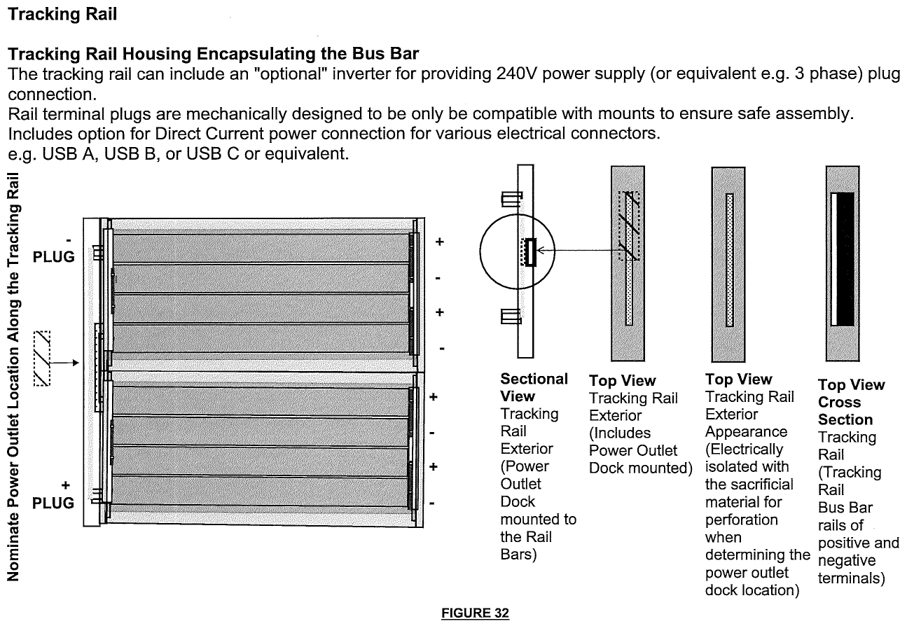

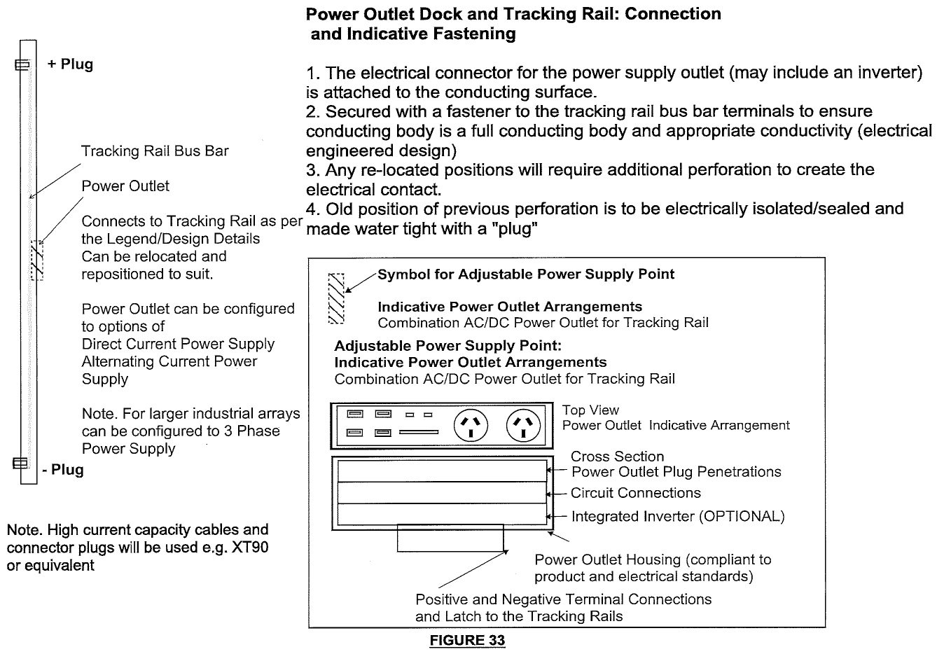

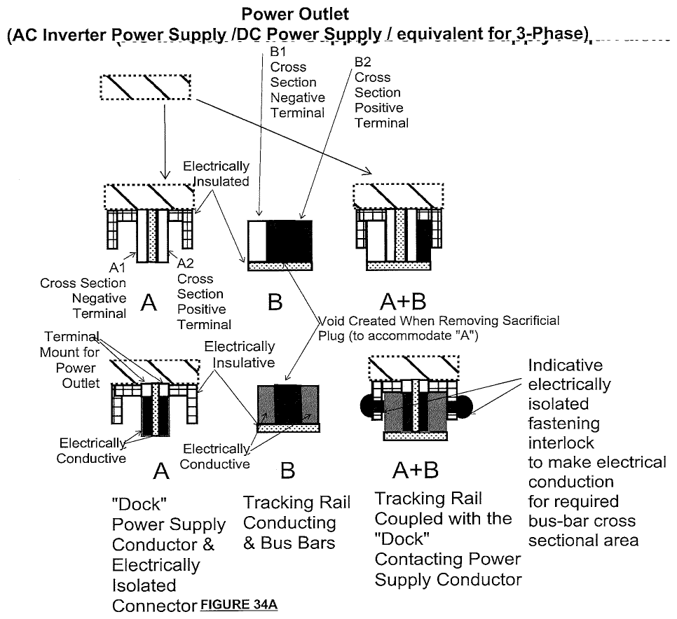

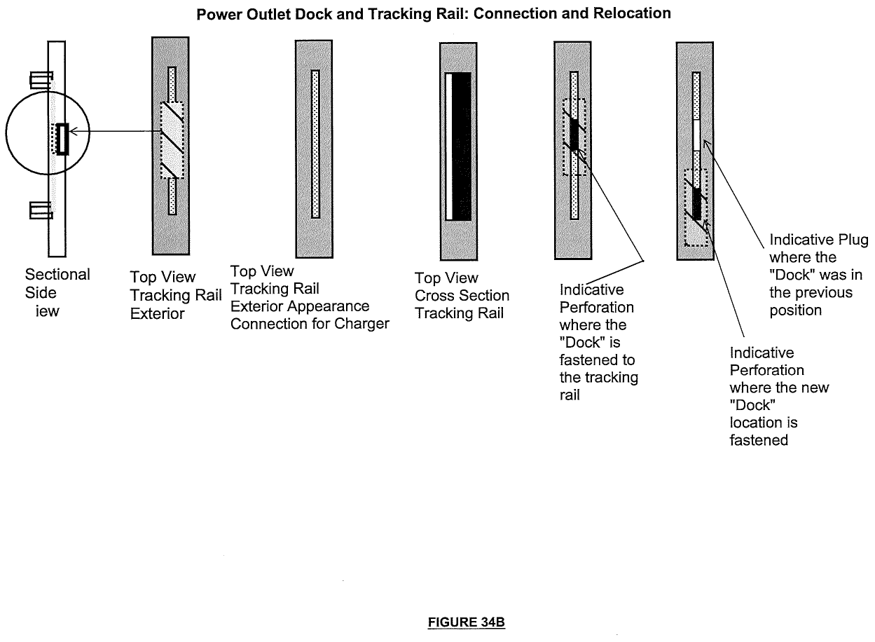

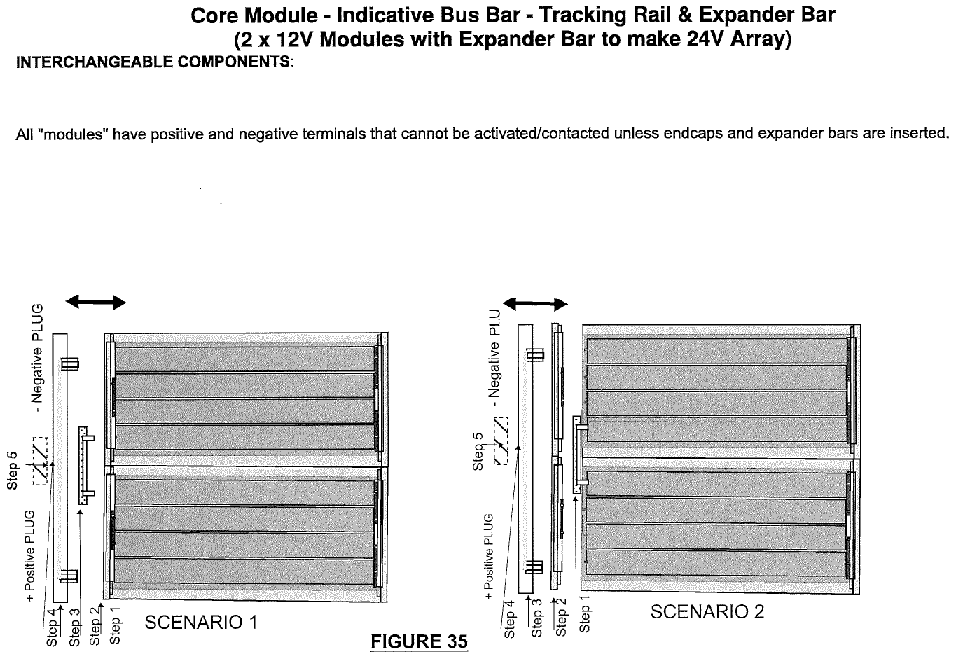

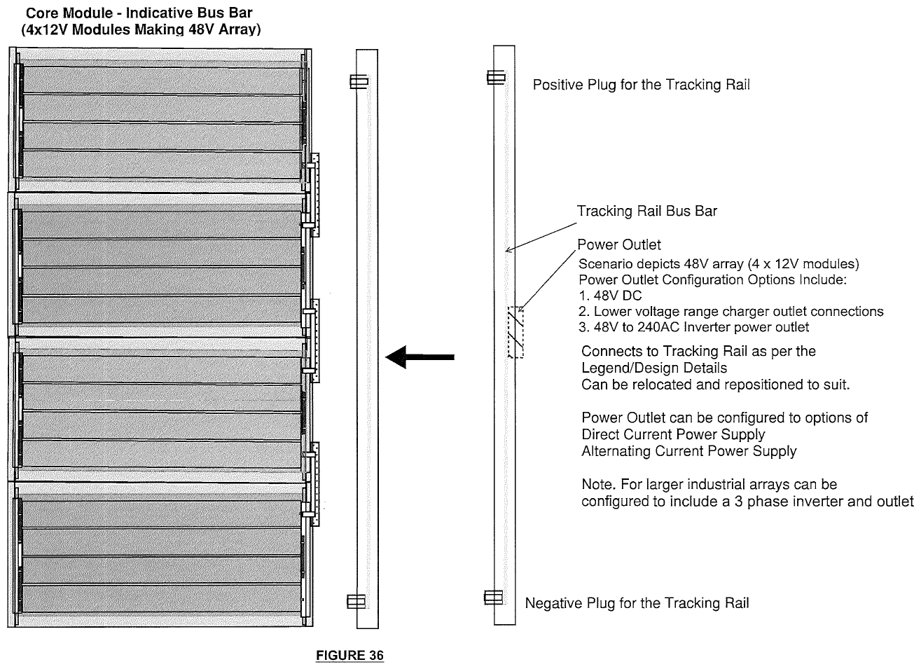

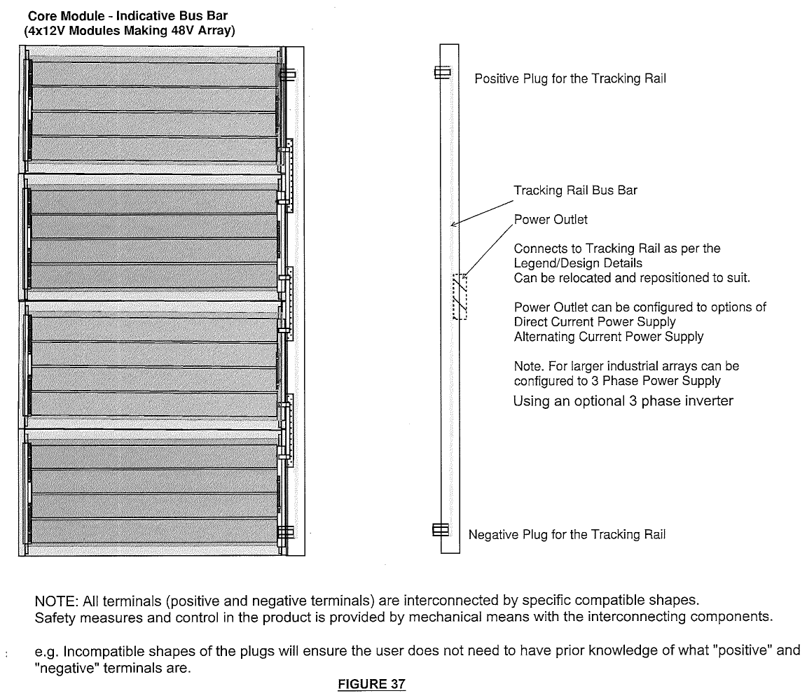

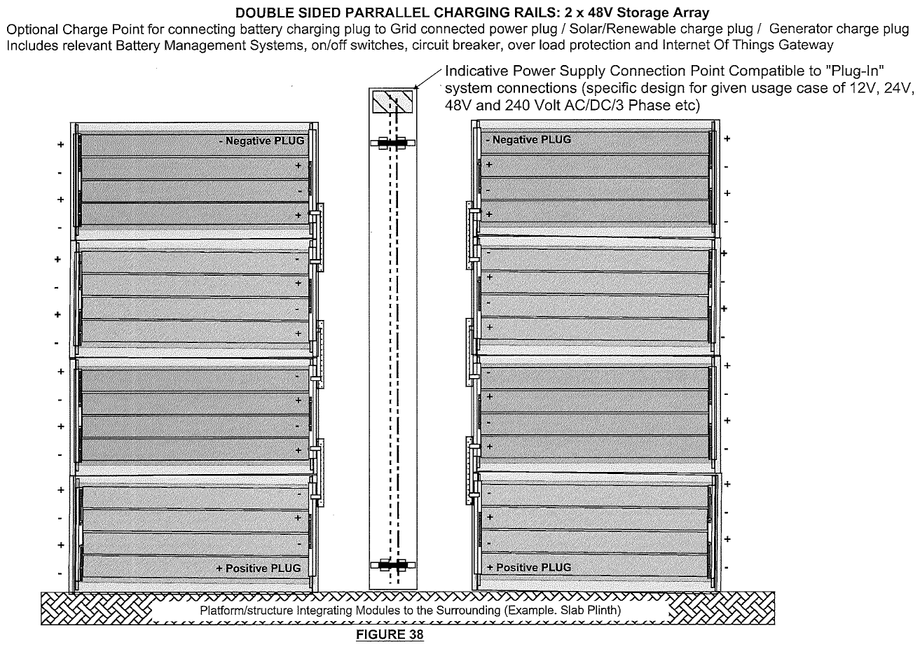

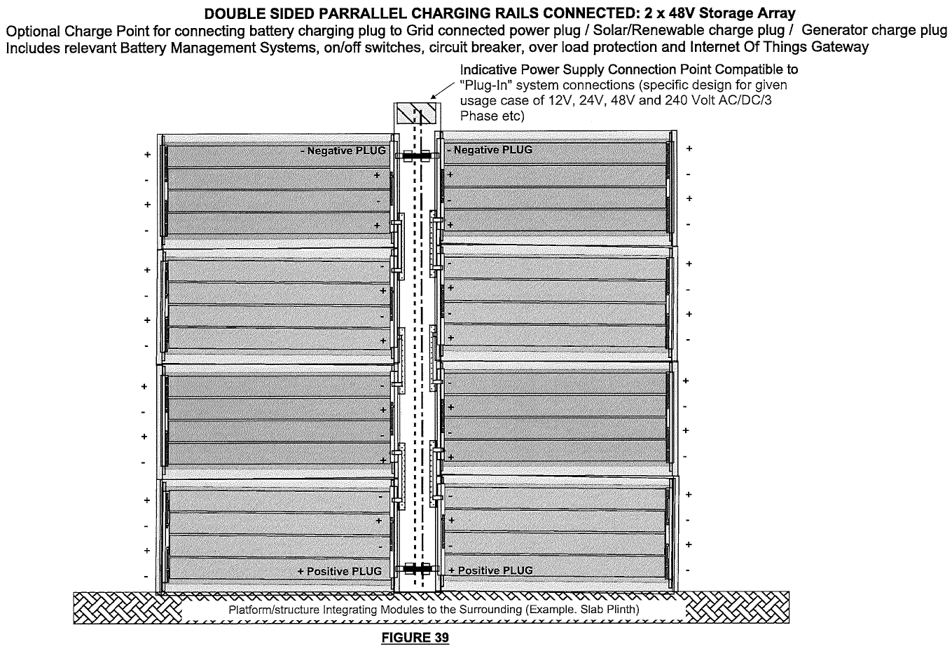

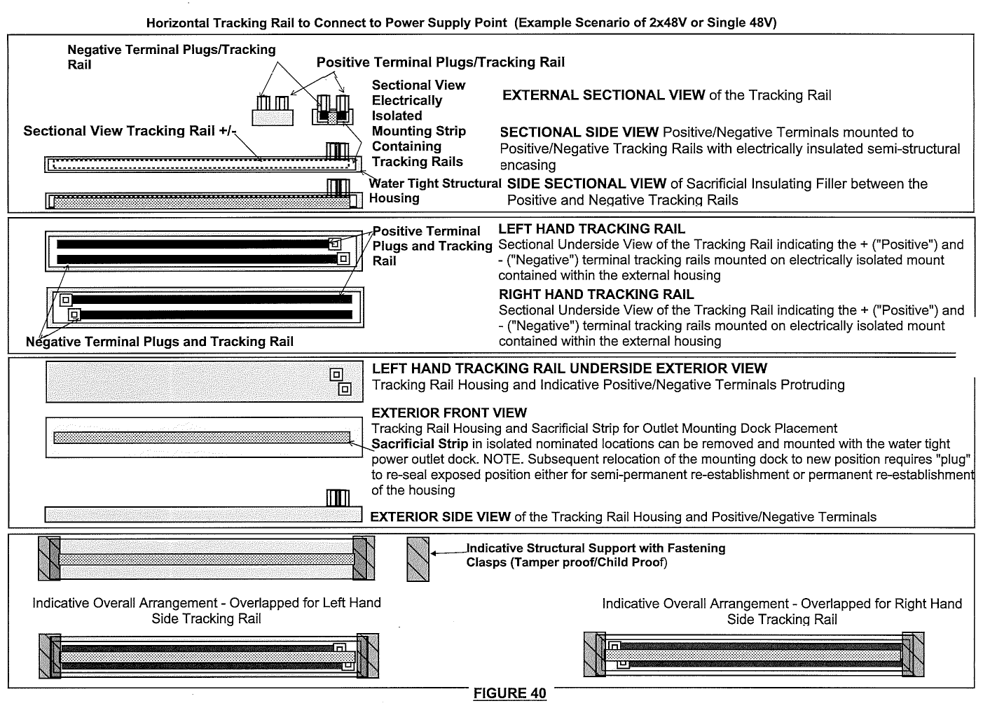

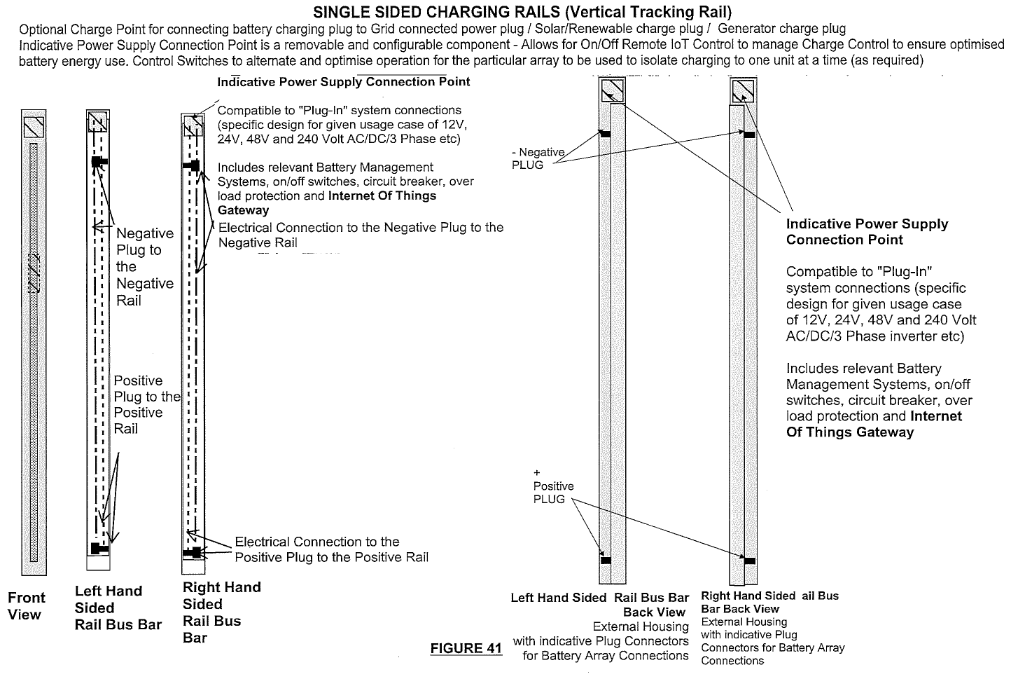

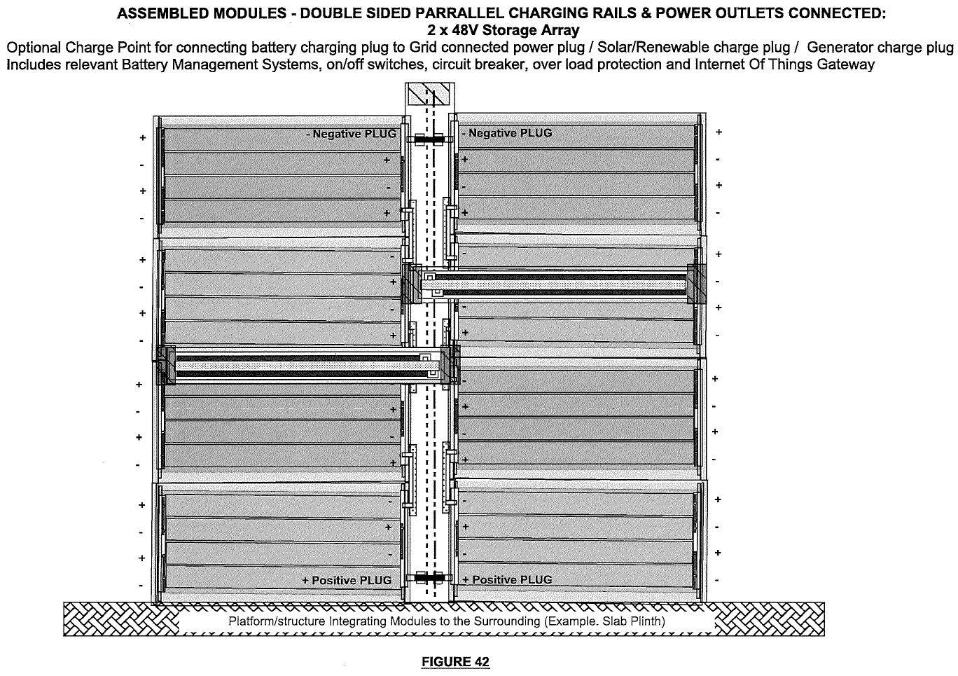

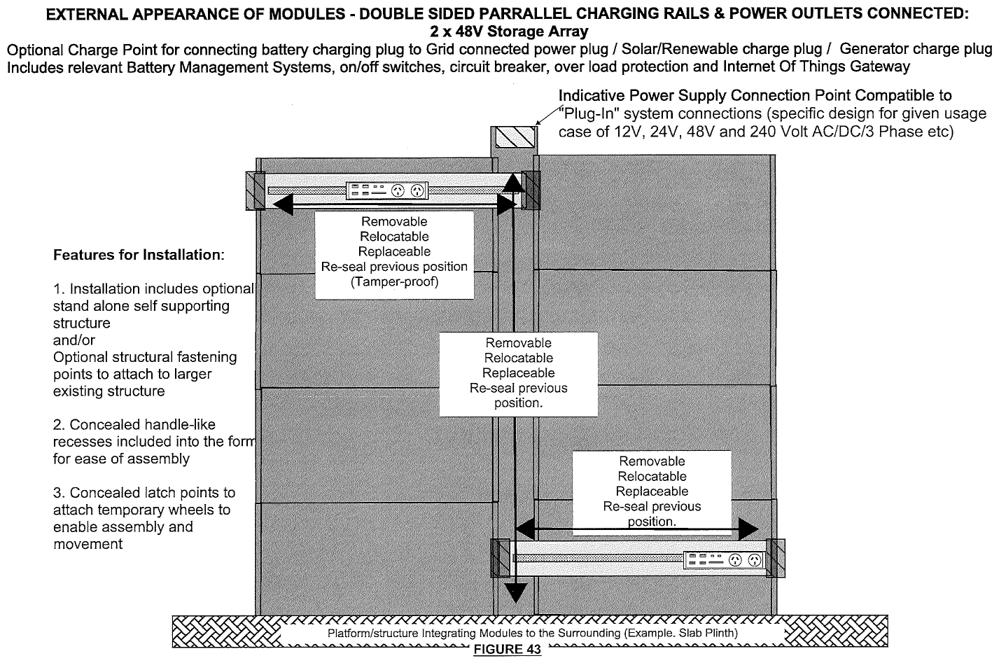

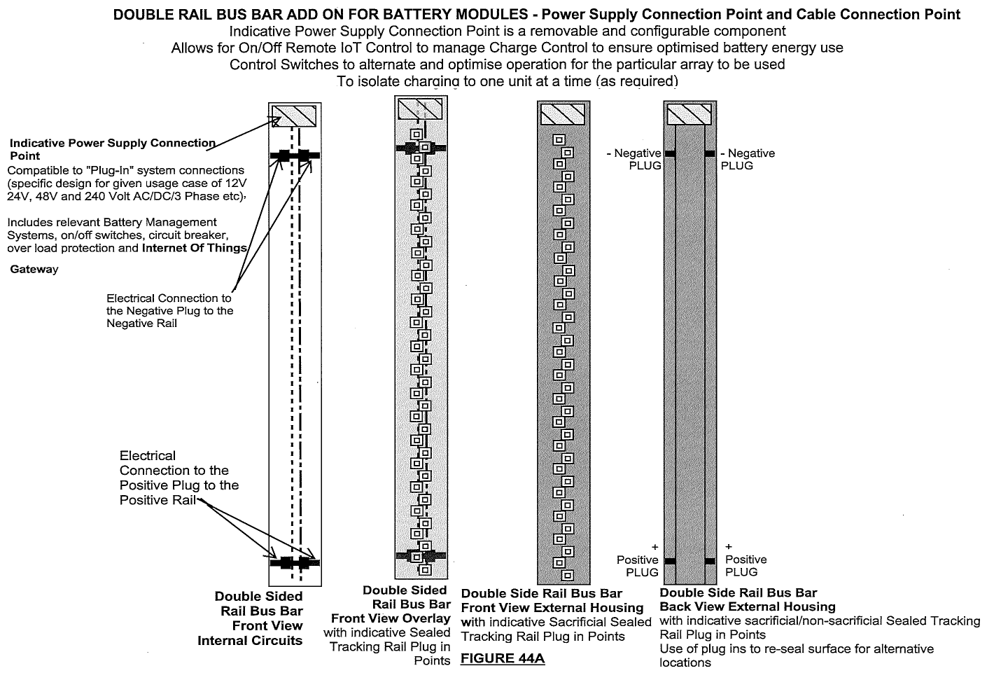

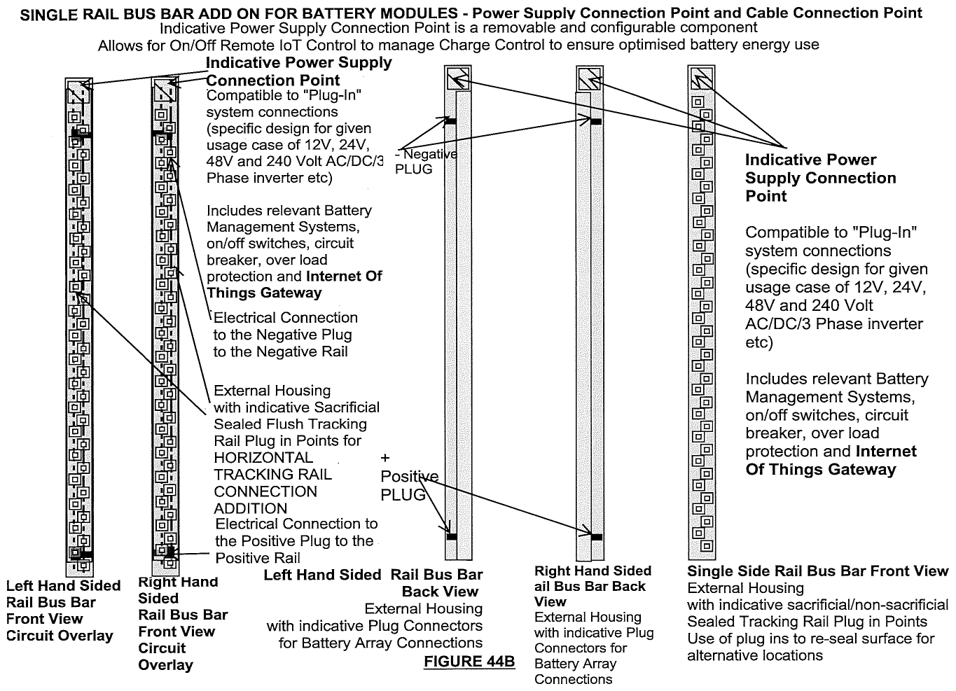

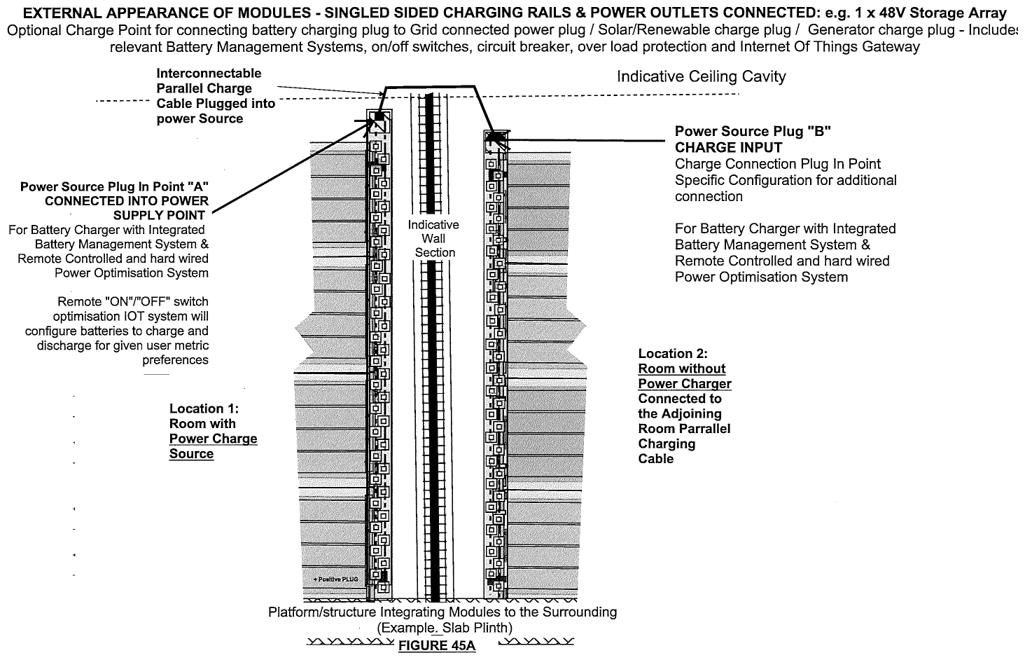

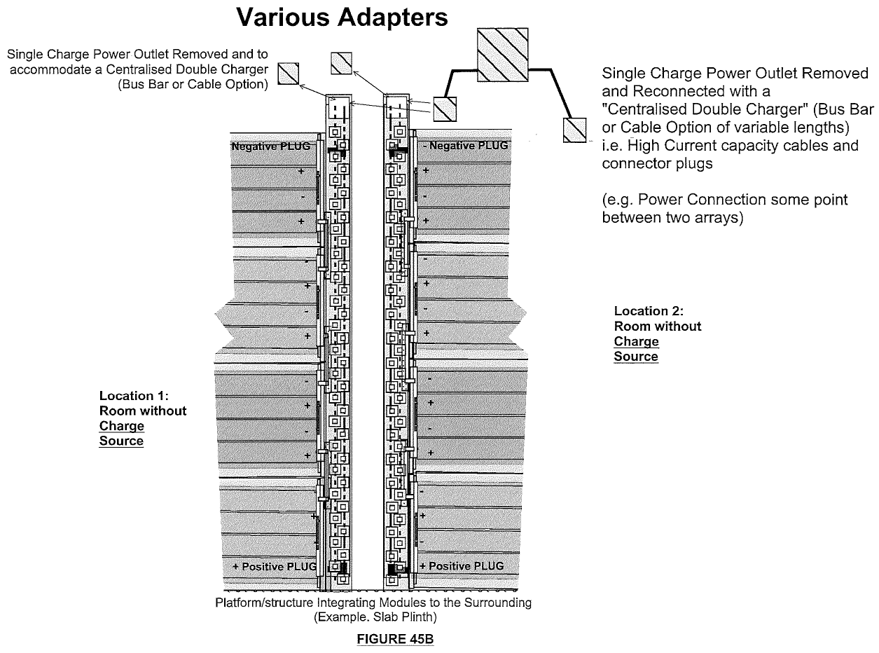

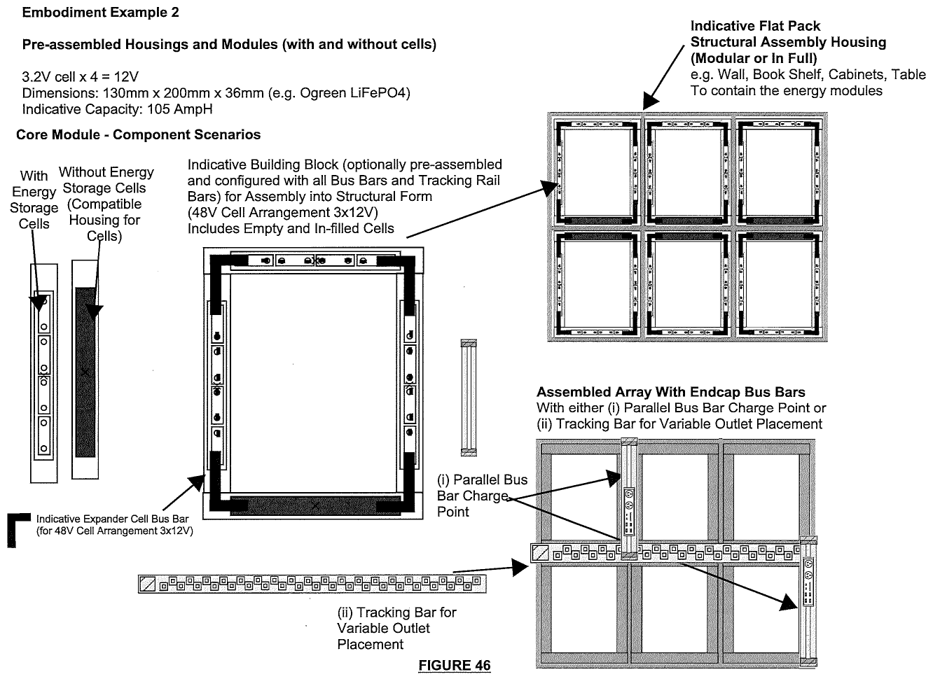

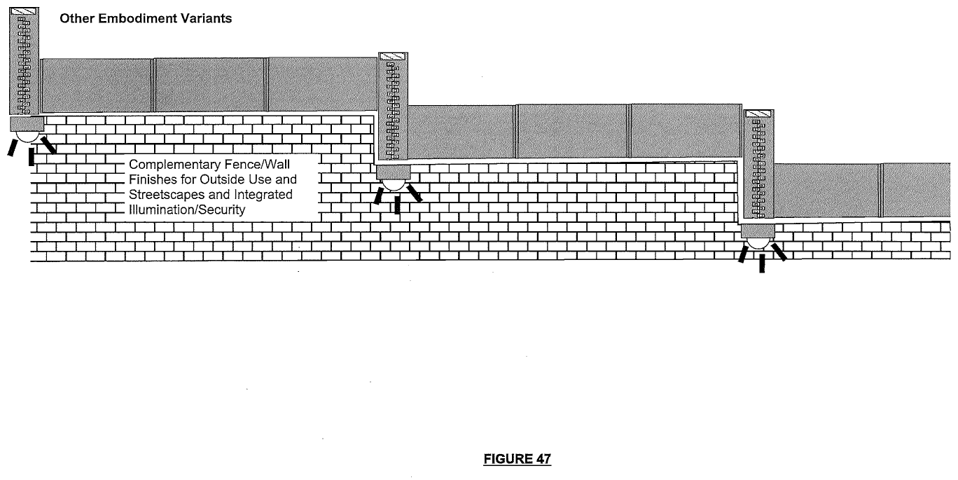

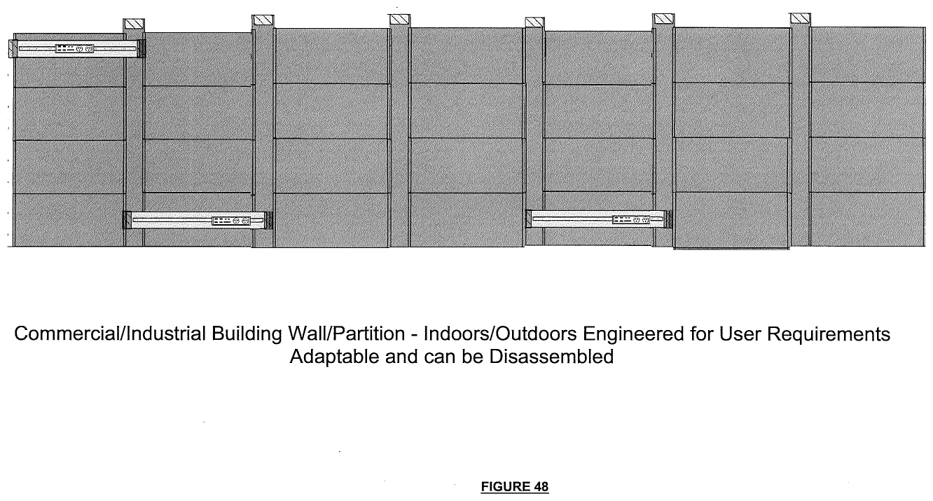

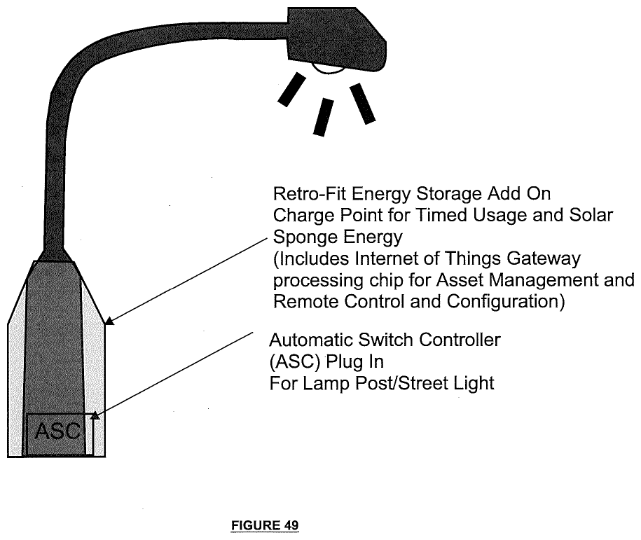

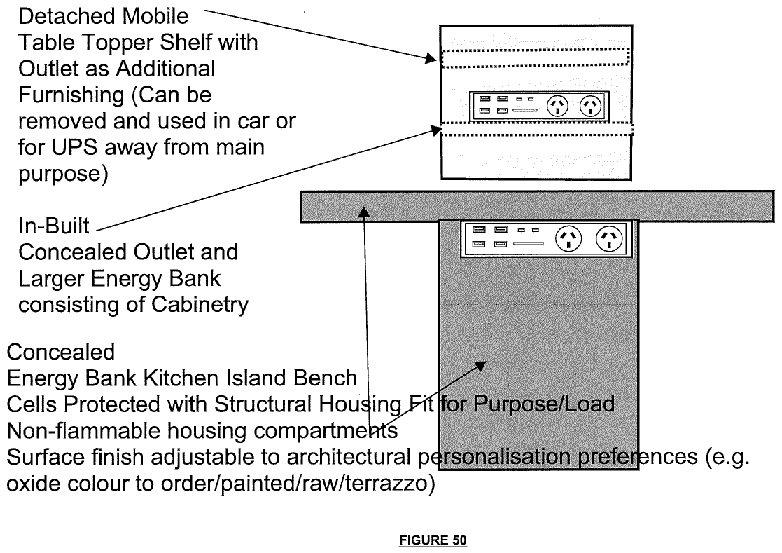

FIG. 24F: Example of IOT array block diagram of many indicative example embodiments in clustered zoned controls within “disparate locations, rooms, buildings and vicinities indoors and outdoors”.

FIG. 24G: Example of a IOT array block diagram scale up of zone configured remote control settings from “disparate locations and disparate buildings for indoors and remotely spaced environments”

FIG. 24H: Example IOT array block diagram embodiments scaled up with “zonal controls to jurisdictional and regional areas and vicinities. Including moving assets, and agile assets within indoor environments”. Diagrammatical representation of the scalability of the intelligence from task based energy modules and interconnectable housings into a large scale system, in orchestration to user control and asset management settings.

FIG. 25—Materials Engineering Disclosure of “Standard/Non-unique Material Housings” and “Unique Materials Engineered Housings”—Outlining the unique Bulk Composition, The unique formulation and proposed variations for casting layers for fabrication suited for structural engineering and user preferences for weight to strength ratios. Details for the unique housing structures and variations to the composite structure composition/formulation allows for personalised use of the semi-structural housings to wide usage scenarios.

FIG. 26 Materials Engineering Disclosure of non standard materials “Unique Pre-cast Housings” Outlining Composite Layered Structural Reinforcement Methods for Material Strengthening, Heat Sink and Shock Absorbing Housings—Detailing the unique techniques and methods for fabrications and engineering.

FIG. 27—Examples of Materials Fabrication Housing Forms and Enclosure Types to contain battery cell and associated components in consideration to 3D forms and variations to the assemble of flat surface panel structures to form hollow or solid body forms of linear or curve-linear shapes.

FIG. 28 Example of an Embodiment using a particular battery cell form/technology—detailing the bus bar End Caps and cell housing terminal interactions. Emphasis on the bus bar pre-fabricated assemblies and its superficial appearance to the engineered requirements relative to the interconnectable housings.

FIG. 29—Illustrates indicative Bus Bar—Sliding Track—Plug In connection. When mounted with a power outlet dock that can include an optional inverter or allow direct current outlets (USB A, USB B, or USB C or equivalent), light sockets 240V power supply (or equivalent e.g. 3 phase) plug connection

FIG. 30—Illustrates in more detailed Track Rail interaction of conducting components and how the mounting dock for the power outlets inter-connects to create a conductive bus bar electrical circuit connection.

FIG. 31—Expander Bar—capabilities through the example of 2×12V Modules to make 24V Interconnected housing structure. The Positive/Negative terminals uniquely shaped as a means to provide varied mechanical interlocks for the designation configuration and use. Such that the user will not require prior knowledge of positive or negative terminals. As the item will either compatibly interconnect or not, for the given designed purpose.

FIG. 32—Tracking Rail Overview—Tracking Rail Housing Encapsulating the Bus Bar for a larger cell array. This example demonstrates the advantage of being able to nominate power outlet location along the tracking rail length. Whereby either sacrificial perforations can be re-sealed or reusable/non reusable tamper proof plugs can be placed, such that a void is made to accommodate the power outlet mounting dock. So that the user can determine the position of the power outlet, and likewise re-locate the position if circumstance requires that to further be amended

FIG. 33—Tracking Rail—Power Outlet Optional Components—Power Outlet Dock and Tracking Rail: Connection and Indicative Fastening—for Adjustable Power Supply Point. Detailing sections of components to allow power outlet dock to be configured user's personalisation.

FIG. 34A—TRACKING RAIL, POWER OUTLET DOCK AND COUPLING SYSTEM—This diagram illustrates the internal components of the tracking rail and the methods to how electrical interconnection occurs.

FIG. 34B—TRACKING RAIL—Diagram further explains the tracking rail housing. The tracking rail is effective housed in an optionally aesthetically-semi-structural fabric similar in principles to the matching material to the core modules.

FIG. 35—INTERCHANGEABLE COMPONENT DESIGN BETWEEN TRACKING BARS AND EXPANDER BARS: This diagram indicates the optional interchangeability of the expander bus bar connections sequences are possible. This may be a desirable option, given the tracking rails are covered, and the size of the components and connections during installation would be cumbersome to re-assemble and detach if not initially configured correctly.

FIG. 36—Tracking Rail Bus Bar and Power Outlet—To be attached. This scenario depicts the example of a 48V array (4×12V modules) with the Tracking rail. Where the advantage of determining the power outlet dock into the broad range vertical position assists user convenience for connectivity.

FIG. 37 Tracking Rail Bus Bar and Power Outlet—Attached. This scenario depicts the example of a 48V array (4×12V modules) with the Tracking rail. Where the advantage of determining the power outlet dock into the broad range vertical position assists user convenience for connectivity.

FIG. 38—“To be” Connected Power Supply/Rectified Connection Point—Example of DOUBLE SIDED PARALLEL CHARGING RAILS: 2×48V Storage Array (and parallel expander bars). The intelligence of the power chargers operating in combination to the modules installed, in effect make the surface area available to determine power outlet locations using the nominated energy storage fuel cells installed in modules M3.2.

FIG. 39—“Connected” Power Supply/Rectified Connection Point—Example of DOUBLE SIDED PARALLEL CHARGING RAILS: 2×48V Storage Array (and parallel expander bars). The intelligence of the power chargers operating in combination to the modules installed, in effect make the surface area available to determine power outlet locations using the nominated energy storage fuel cells installed in modules M3.2.

FIG. 40—Horizontal Tracking Rails—to Connect to Power Supply Point—Example Scenario of 2×48V or Single 48V)—These details outline the horizontal tracking rails. To connect the power outlet tracking rails to any vertical and horizontal span of the array surface area.

FIG. 41—SINGLE SIDED CHARGING RAILS and TRACKING RAIL

Illustrated is the Optional Charge Points for connecting battery charging plug to Grid connected power plug/Solar/Renewable charge plug/Generator charge plug.

FIG. 42 DOUBLE SIDED PARALLEL CHARGING RAILS & HORIZONTAL TRACKING RAIL POWER OUTLETS CONNECTED: 2×48V Storage Array—Plinths and Water Tightness Designations for Inundation—This provides an overlay of the electrical interconnections of the components of the core modules, the power outlets, and parallel charging connection points, linked to the Internet of Things Gateway.

FIG. 43—EXTERNAL APPEARANCE OF MODULES—DOUBLE SIDED PARALLEL CHARGING RAILS & POWER OUTLETS CONNECTED: 2×48V Storage Array

This illustrates specifically the example where the embodiment has spanning ability to locate the docking mounts into locations ranging relative to the tracking mounts.

FIG. 44A DOUBLE RAIL BUS BAR ADD ON FOR BATTERY MODULES—Power Supply Connection Point and Cable Connection Point

This is a detailed illustration of the vertical plug in points to support the horizontal tracking rails. It indicates the internal circuits of the rail bars and the connections to the re-charging power connections.

FIG. 44B—Single Side Rail Bus Bars—Overlays and External Views

These diagrams illustrate the single rail equivalent of the of the double parallel charging rails, whereby it accommodates the horizontal tracking rails and associated power outlets.

FIG. 45A—Interconnectable Parallel Charge (Rectifier) Cable Plugged into power Source—CABLES

Indicated are non-rigid interconnections by use of flexible cables, in substitution of rigid expansion bus bar inter connectors. The advantage of this is to allow power connections into ceiling cavities or across spatially restricted contexts to enable maximum interconnectability.

FIG. 45B—Various Adapters—Single Charge (Rectifier) Power Outlet Removed and Reconnected with a Centralised Double Charger (Bus Bar or Cable Option of variable lengths)

This illustration shows a de-centralised option of the rectifier configuration relative to the original individual rectifier locations.

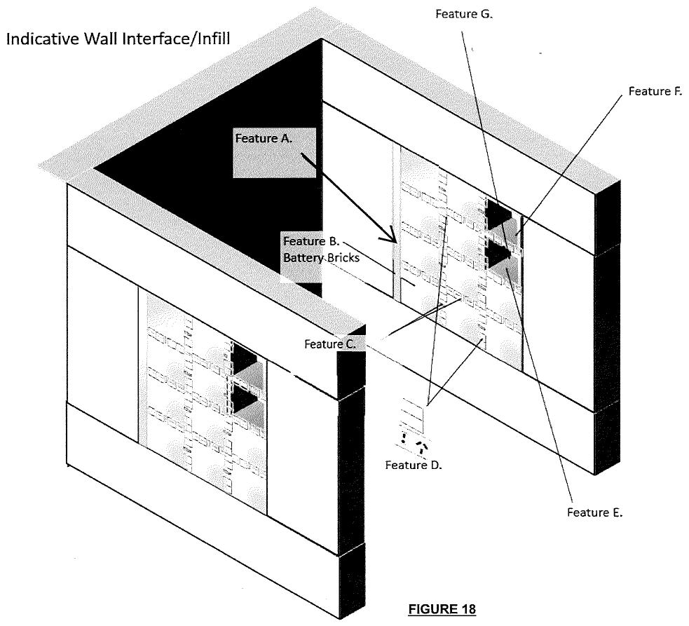

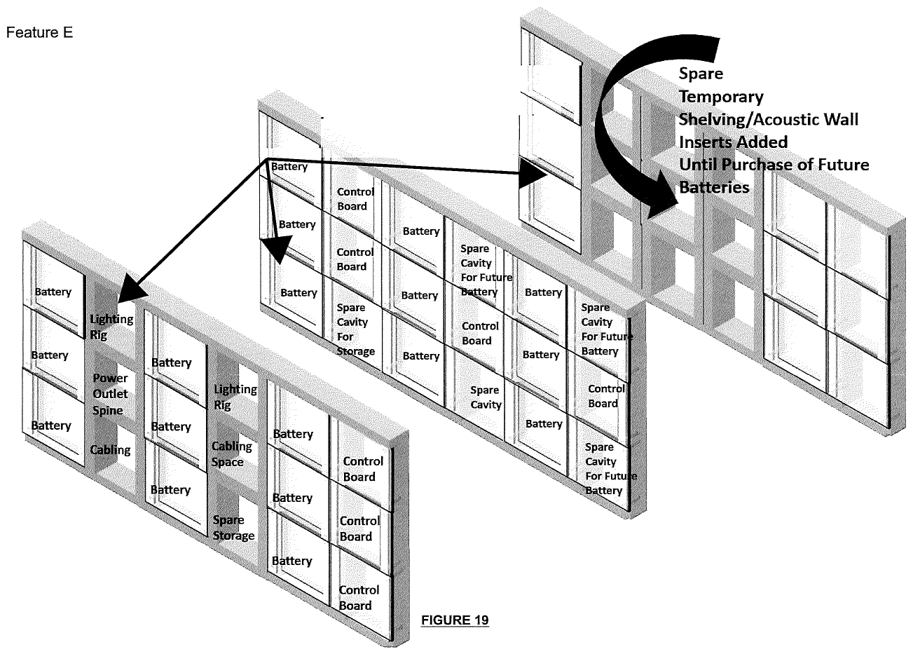

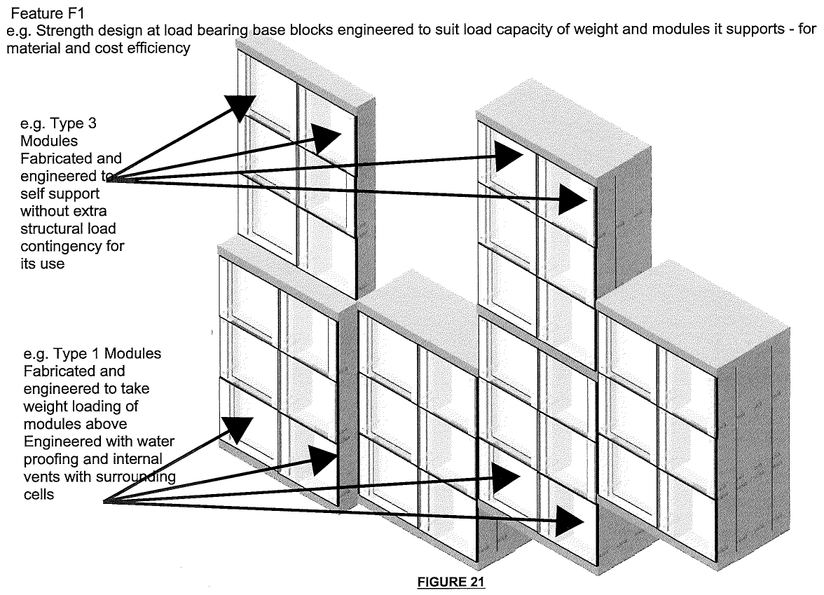

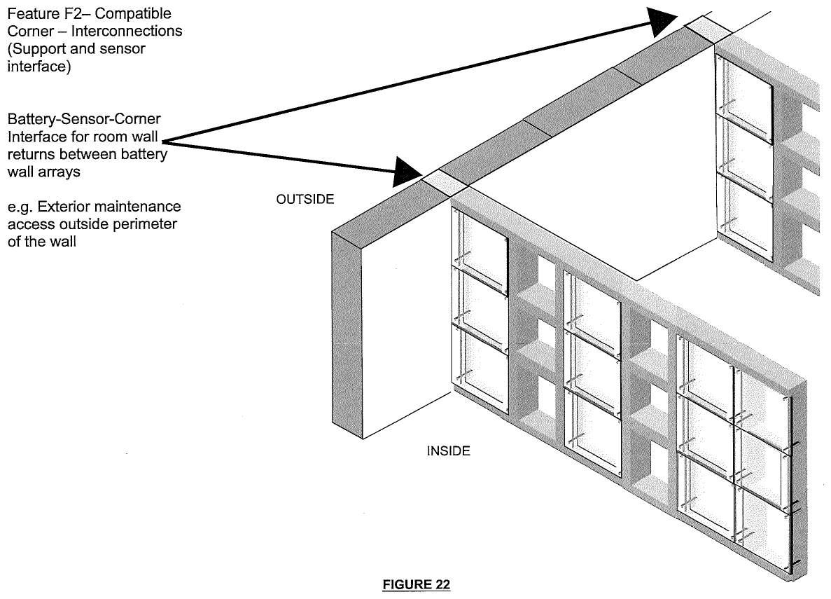

FIG. 46—Embodiment Example 2—Pre-assembled Housings and Modules (with and without cells)—Detailed example of SCENARIO IN FIG. 18-19, and FIGS. 21-22.

This diagram indicates battery cells assembled in more generical hollow cube modules that could be used for purposes of inbuilt walls or book shelving and storage, with or without cells.

FIG. 47—Other Embodiment Variant—Complementary Fence/Wall: This illustrates an example embodiment of an outdoor fence/wall/screen for permanent installation. The multi-function is being demonstrations using these modules as either a micro-grid asset, an uninterrupted power supply or grid connected asset which can provide open spaces amenity for public and private hard landscaping

FIG. 48 Commercial/Industrial Building Wall/Partition—Indoors/Outdoors Engineered for User Requirements This diagram illustrates the commercial, industrial, education and open spaces embodiment for larger surface areas/volumes.

FIG. 49 Retro-Fit Energy Storage Add On For Lamp Post/Street Light—This illustration shows one of the modules retrofitted around an existing light infrastructure. Housings can be designed for relevant aesthetic and functional forms. e.g. Including planter systems and banner rails.

FIG. 50—Detached or Built In Structure/Shelf with Outlet as Additional Furnishing

Illustrated is an example of modules that are built into the kitchen island bench to be part of the kitchen cabinetry. The cavity within the cabinets can further include expansion connections to the components to interconnect with power outlets and concealed energy cells. Components can be removed and used in car or for UPS away from main purpose.

### DETAILED DESCRIPTION OF PREFERRED EMBODIMENTS

Embodiments of the present invention will now be described in detail and with reference to the drawings.

Broadly what is described is a plurality of modular housing structures, each structure of a modular form.

In a particular form battery structures can be assembled into a structure, for example wall structure, solid volume or volume with a hollow or flat plane surface, or furniture, or supported in combination with (e.g. outdoor applications such as retaining walls or outdoor landscape amenities).

In preferred forms, each structure is a modular interconnectable housing structure. In preferred forms, each housing structure includes structures of load bearing capability and for mechanical interconnection to adjacent structures. In preferred forms, each structure includes structures for electrical interconnection to adjacent battery modules. In preferred forms, each structure includes additional electrical functionality. In one form, the additional electrical functionality takes the form of a power point or light switch or light or optional inverter for alternating current or for 3-phase power.

In one form, the additional electrical functionality takes the form of an Internet of Things Gateway for components that assemble and collate data and instructions, including user optimisation artificial intelligence feeds. The system orchestrates data and inputs involving the operation of the appliances to work in suiting dynamic user preferences. Using logic and needs hierarchies associated with the control systems and purposes of the configuration.

Further aspects of embodiments of the invention are as follows:

### Invention Problem and Solution

Energy storage and power use is typically wired-in, expensive and bulky. Wall sockets are fixed, requiring extension cables or costly qualified labour.

PREFERRED EMBODIMENT: This invention of “smart” construction materials enables: Low-skill user interfaces for indoor/outdoors and temporary/permanent use; Quick and easy set-up, installation/adjustment to all things electrical from appliance to control-board; serviceability; recyclability; a carbon efficient alternative to big infrastructure.

PREFERRED EMBODIMENT: Combining building materials, electricity/energy storage product markets creates savings in materials/energy/money whilst reducing carbon. Providing large-scale intelligent systems and control into everyday buildings, forms and spaces. Conveniently and aesthetically optimising limited real estate.

### Prior Art of Battery Storage Systems, Housings and Assemblies—Boundaries of Innovation

The existing craft of energy power supply and energy storage is regimented by compliance and certification standards. Furthermore, specialised trade skills are required for the installation or modification for current built systems due to the safety controls.

The existing art of uninterrupted power supply and energy storage units are not designed/recommended by manufacturers for users to personally configure energy storage and usage interfaces to their specific needs other than in use as independent entities.

Prior art for the installation of energy storage systems are focused on isolated usage contexts as a consumer good, in either optimising or enabling certified and qualified experts to install, assemble, modify and dismantle electrical related power supply or power infrastructure between the grid connected electrical control-fuse box all the way to the electrical outlet location.

Prior art requires a lot of knowledge for safe assembly. This invention is enabling “Do-it-yourself” style of assembly of energy storage and supply systems. The basic level of skill is designed to be intuitive as building block toys.

The knowledge barrier for the current art of energy storage and supply is creating victims who are purchasing poor quality and sub-standard installations. This exploitation of the consumer knowledge gap is enabling unethical trades and financial liabilities to vulnerable well intentioned community members. With subsequent restoration or removal of the inferior asset requiring additional costs for labour and materials.

Batteries are relatively bulky. There can also be issues with safety given the relatively large amounts of energy they can store.

The most common and simplest battery user interface experience is summarised in the example the humble car battery involving positive and negative terminals to be connected to another, to jump start a vehicle. To an uneducated person, in the scenario of a large campervan battery bank incorrect installation being due to erroneous placement of the terminals, can damage a battery array and be hazardous.

PREFERRED EMBODIMENT: This invention is providing user interface “portal” for both remote control, operation, management and maintenance of their asset. The direct nature of this database-user control system is to ensure total quality management in the lifecycle of the product's use, installation and operation.

However the arrangements disclosed are not readily available for a builder or non-electrical trade user to install reliably and with safety.

Batteries and batteries systems currently days are being installed in association with sources of renewable energy—particularly sources of electricity derived from wind turbines or solar cells arrays. In these applications, the batteries are used to store electricity generated from these sources for use when the sources are not available (for example for when the wind is not blowing or when the sun is not shining). The batteries are also used for smoothing, load-levelling and “stiffening” of the power system.

Industrial use of energy storage is changing and orienting towards built in domestic scale modules or appliance based Uninterrupted Power Supply (UPS) systems. Prior art for use of battery storage in micro-grid islands is now more financially feasible due to the prevalence, availability and low costs of solar charging cells.

Task based energy in our daily telecommunication devices and computers, such as phone, tablet, laptop and remote home office, offer strengths and weaknesses when dealing with built-in batteries. These critical appliances are highly depended on power outlet recharging locations, such that the fast pace of modern life does not miss a step, whilst providing comfort and convenience to daily living.

Under rare and unique circumstances such as emergency response and life-style related remote venues (including camper vans and remote expeditions), do isolated battery banks present itself available for multiple devices to be able to draw power.

From recent environmental catastrophes of bushfires, floods and earthquakes, the role providing power to our telecommunication devices and consumer electronic goods present life-saving opportunities.

Batteries our daily devices are tailored for specific energy density objectives, due to impacting the overall portability, weight, size and battery life when using the product without the charger.

PREFERRED EMBODIMENT: The scale of implementing task based energy storage and control systems have been overlooked. This invention presents a different light in task based energy usage. The result of complacency and routine having mobile devices/laptops in vicinity to the nearest power outlet, does not bring to question the reason and assumptions behind the infrastructure we have been using and continue to be reliant upon.

Modern day living and technological advancements have stimulated our attentions to overlook the opportunity of decentralised energy storage opportunities in our direct vicinities of solid objects. Prior art of uninterrupted battery power supply units, back up power battery banks and energy storage are not designed for aesthetic, space efficient usage and are configured to be exclusively a standalone item on the desk top, floor, or in a power bank server rack or utility cabinet.

PREFERRED EMBODIMENT: It would be advantageous if batteries could be combined with or combined into other structures or actually comprise of the structure—for example walls whereby the wall structure can perform with the function of energy storage and conversely the batteries forming the wall structure can perform the function of a wall—including but not limited to the structural load bearing functions and the aesthetic functions.

The history of battery storage uses non-readily recyclable materials in the form of metal and polymer housings. Prior art in the building industry uses construction materials in their standalone contexts. The latest cutting edge developments for progressive archaic masonry construction materials, is in the research underway Scandinavia for concrete battery cell compositions for creating battery cells.

PREFERRED EMBODIMENT: This invention is an intermediary, whereby the building material and the assembly combines to create the battery structure which can be assembled, disassembled and personalised with relevant additions without requiring technical assistance, other than your smart phone or computer.

Prior art exists in the basic form of people housing utility cabinets around their battery cells, or even the placement of placing lead-acid battery cells (or any variant) into concrete besser blocks.

The design of having batteries in alternative material housings is known.

PREFERRED EMBODIMENT: Currently, there is not modular battery cells system that is pre-emptively designed to be safety interchanged/modified, expanded and or physically relocated for permanent or temporary use—whilst forming part of the floor space in a visually low-impact way is not available. Such an arrangement would address the bulk problem that batteries can represent. This is a feature of the invention presented.

Existing arts are available for providing waterproof and weather proof utility cabinets house batteries for example CN201813078U Waterproof and dustproof outdoor double-door electric cabinet, US20140272509A1 Water resistant battery box, U.S. Pat. No. 6,889,752 Systems and methods for weatherproof cabinets with multiple compartment cooling

Existing arts are available to house electric vehicle batteries for weather proof and waterproof conditions for examples U.S. Pat. No. 8,900,744 Automotive battery case, and CN102447080A Waterproof battery jar of electric car.

There are existing designs to house batteries and electrical components in their unique encapsulated water proof, weather proof product designs for oceans and various outdoor environments. For example U.S. Pat. No. 2,669,596 Reserve Battery Buoys—Sonobuoys and other apparatus used at sea for sound detection are powered with electric batteries, CN202758948U Waterproof buried box for storage battery, U.S. Pat. No. 4,623,753 Watertight junction box

There are existing designs to encapsulate battery cells with chemical resistant housings and polymeric substances. Including fire retardant products and thermal management systems which are either complex installed systems or chemically harmful to users and less conducive for enabling recyclability or repair and maintenance. For examples US20100136405A1 Battery pack with optimized mechanical, electrical, and thermal management, US20130049971A1 Battery Thermal Event Detection System Utilizing Battery Pack Isolation Monitoring

PREFERRED EMBODIMENT: However, housing batteries in the fabric of the construction material and furniture has not been examined for its full potential. This invention explores engineered masonry composite materials engineering to fulfil the role of furniture, outdoor landscaping and building forms.

To date, batteries to service general purpose needs, have been housed as a centralised addition to the wired in building system, typically encased in a metallic or polymeric housing/utility cabinet. Only in unusual circumstances do the uninterrupted power supply consumables and petrol generators form roles in remote isolated conditions.

However, the role of having energy storage contained in the cells of “masonry” type building products, and other variants of building materials and surface finishes present advantages of chemical stability, thermal stability and structural stability.

PREFERRED EMBODIMENT: The systems proposed of “masonry” battery housings includes the use of composite materials and polymeric additives to achieve architectural style finishes in performance and durability.

PREFERRED EMBODIMENT: The advantage of smart construction materials in the form of a system of various material products and additive components, reduces overall material consumption, accommodates repair/modification user needs, and mitigates carbon load for associated materials for further labour and manufacture due to product design obsolescence.

PREFERRED EMBODIMENT: Smart construction materials will let users maximise on the benefits and convenience of power supply and comfort associated with making shelters, furnishings and spatial enhancements for indoor and outdoor spaces.

PREFERRED EMBODIMENT: The materials engineering associated with this invention includes a variety of scientific and engineered options. Including metallic, non-metallic, polymeric and organic-plant derived origin materials. Including the potential to fabricate these housings from battery cell composite masonry, to complement the higher energy storage density associated with battery cell technology.

This patent is time limited to the current materials technology available to date, forming best technical disclosure for the point in time. The variants to the materials engineering manufacture and fabrication of various materials technologies, may be held as trade secrets or be known as standard methods of manufacture those specialising in the known trade and craft.

It is an object of the present invention to address or at least ameliorate some of the above disadvantages or provide a useful alternative.

### Boundaries of Innovation in Current Power Outlets and Fixtures

The situation when plugging in from a fixed power socket in the wall from a building includes use of extension cords, multi-adapters, and additional plug in of USB ports and or potentially a wireless charging dock.

The underlying behaviour for the use of multi-adapters, extension cords and additional plug in stations is to circumvent the need to utilise disruption to the wall outlet and building material.

Currently there are space deficiencies and safety risks to overcome access limitations of fixed wall outlets using extension cables and multi-adapters—due to both unsightly trip hazards and multi-adapters balancing on surfaces when not mounted and fixed in place.

Current modular fixed furniture storage solutions and display cubicles for show rooms, trade fairs and retail tenancies have integrated lighting systems, demanding access to power through the form of extension leads circuits, portable use batteries etc.

Offsite offices and various off grid operations utilise electrical power in environments which may include emergency response recovery and remote services strategies. These usages may have power circuits utilising both extension chords and portable temporary control boards integrating either batteries with petrol generators or other off grid energy harvesting technologies.

PREFERRED EMBODIMENT: This invention mitigates the need to modify locations of power outlets when using this technology through the building floor plan or landscape plan. Energy storage systems can be tailored to the users requirements without need for demolition and reconstructive works.

### Context of Grid and Building Electricity Infrastructure and the Boundaries of Innovation

The known craft of electricity and cables in context to our built environment has included electrical trades, electrical engineers and builders to coordinate through sequencing of load planning, design (lay out and circuitry) and construction/installation. The materials designated as partitions for the rooms are determined by building walls. Typically internal non-structural room walls and partitions contain construction material (brick, gyprock, timber etc) and the services connections such as power and occasionally telecommunications and water. Most commonly internal building walls consist of building materials and power supply. Note. Where telecommunications outlets are predetermined either by the existing built form, or the design in a retrospective addition.

PREFERRED EMBODIMENT: The design and location of power outlets and light switches have been always predetermined by architects, lighting engineers, building engineers, builders and electricians in the context of design plans, floor lay out plans and configuring connectivity from the street frontage electrical easement connection points. This invention reduces the scale to which task based ceiling lighting plans and power outlet planning required for building fit out and design, due to the nature of it's adaptable outlets. Allowing flexibility in the layered fabric linings to be decided at later stages of the construction fit out.

Currently any adaptation of or addition to power outlets, light switches, and light fittings in relation to location have been a requiring the electrician/electrical qualified tradesman to chase cables and reconfigure the circuit from the fuse box/control panel.

Solar power and battery technology systems currently require electrical and building trades to participate with the installation of systems providing additional labour costs and logistical challenges for amending amenities associated with electrical power supply.

Power and electricity are currently confined into the context of built form, and energy retailers have been owning the asset beyond the pillar connection point.

PREFERRED EMBODIMENT: Electrical storage devices in the built environment in relation to back up energy supply and battery storage systems consist as separate items which are detached from the built form/building material and mechanically secured to a structure. As a consequence creating greater spatial demand allocations on the development floor plate areas. This invention resolves this issue due to the ability enable greater access to electrical infrastructure assemblies in smaller spaces and volumes.

PREFERRED EMBODIMENT: The trade specific role of builders and electricians participating in the installation of back up power or battery storage systems have been dominant in the housing, community development infrastructure and commercial/industrial building context. These tasks are repetitious, monotonous, time consuming, and are laboriously low skilled compared to the expert knowledge and capabilities. This invention used in the industrial contexts has the capability to distribute the stress and work load of tedious work, and direct their skills on expertise to enable building infrastructure more efficiently, and allowing a faster transition from the carbon economy—utilising their skills to establish extensive energy storage systems that support future renewable energy, hydrogen energy and fusion base load energy.

PREFERRED EMBODIMENT: Portable solar and battery storage devices are available in relation to camping and recreational outdoor or off grid mobile living environments. These items can be used in permanent or semi-permanent context where individuals can relocate and move panels as the solar access varies. Battery storage and back up energy options are available by utilising a back up petrol generator or the car alternator to top up the battery when power shortage occurs.

PREFERRED EMBODIMENT: Individuals who have portable detached or mobile off grid power infrastructure have the capability to optioneer their power systems and configure energy back up to match their preferences. This capability is currently not embraced when utilising power supply in current fixed building connected to the grid. This invention assists fast deployable infrastructure, suitable for emergency response and community re-establishment after catastrophic event recovery.

PREFERRED EMBODIMENT: This invention allows the capture of task based energy systems and for agile circumstances that include tenancies/non-permanent installations to a wider population and various usage cases. Increasing ability to optimise energy storage and use.

PREFERRED EMBODIMENT: This invention is the reflection from delivering infrastructure works. It would serve to assist urban activation and amenity of public and open spaces.

PREFERRED EMBODIMENT: The pre-designed modular nature resolves issues regarding safe and assembly using technology described in this patent.

### Invention User Categories:

1. Do-It-Yourself Retrofit Market: Domestic users that go to big-box suppliers needing convenient and child safe solutions for power use/access and storage. Addressing space optimisation such as walls, storage cavities and open spaces.
2. Professional: Architects/Builders/Renovators: Space optimisation, design and technology integration of building materials and intelligent systems. Also in open spaces and community areas in private and public sectors.
3. Emergency Response/Infrastructure Contingency—Blackouts/brownouts from floods, storms, fires etc. Enabling off grid (micro-island) uninterrupted power supply. Will reduce need for re-works if installed pre-emptively, or in mitigation to insurance schemes.

### Invention User Categories Prior Art:

NOTE. All of the user categories require high levels of expertise that are hard to access in remote areas. None of these user-groups have devised a solution that integrates safety and controls design in the building material and electricity & energy storage context.

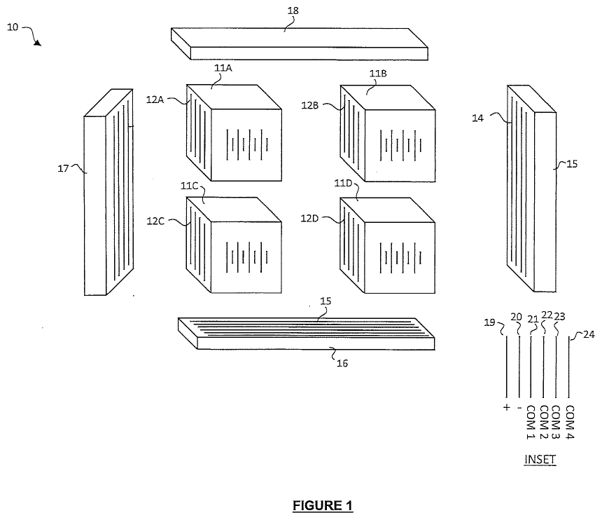

With reference to FIG. 1 there is illustrated a modular interconnectable housing structure arrangement 10, in this instance assemblable into a wall or wall—like structure.

### FIG. 1:

In this instance the arrangement 10 comprises first, second, third and fourth battery modules 11 A, 11 B, 11 C, 11 D, arranged in a juxtaposed relationship. In this instance the batteries comprise a DC power source which is communicable via respective battery bus 12 A, 12 B, 12 C, 12 D. The bus 12 can be juxtaposed against like bus structures of like batteries 11 or can be juxtaposed against like bus structures including bus 14 bus 15 of elongated support component 15, 16 respectively. Similar bus structures are incorporated within elongated support components 17, 18 (not shown).

As shown in the inset the bus structure comprises, in this instance, at least 6 separate conductive paths 19, 20, 21, 22, 23, 24 (see inset).

in this instance conductive path 19 comprises the positive power conductive path. Conductive path 20 comprises the negative power conductive path. Conductive paths 20-24 comprise of communication buses.

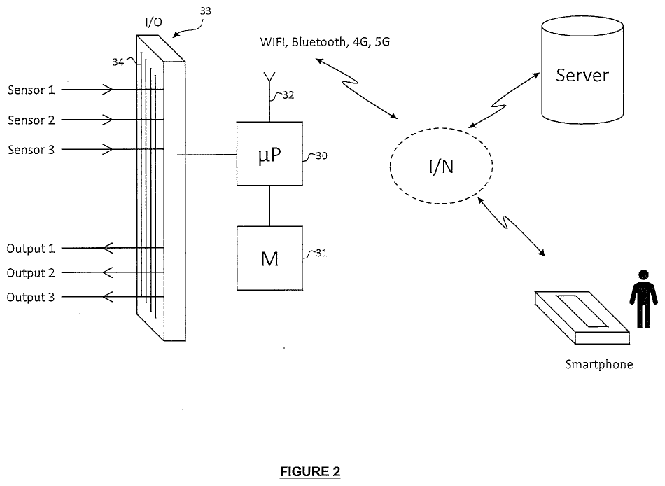

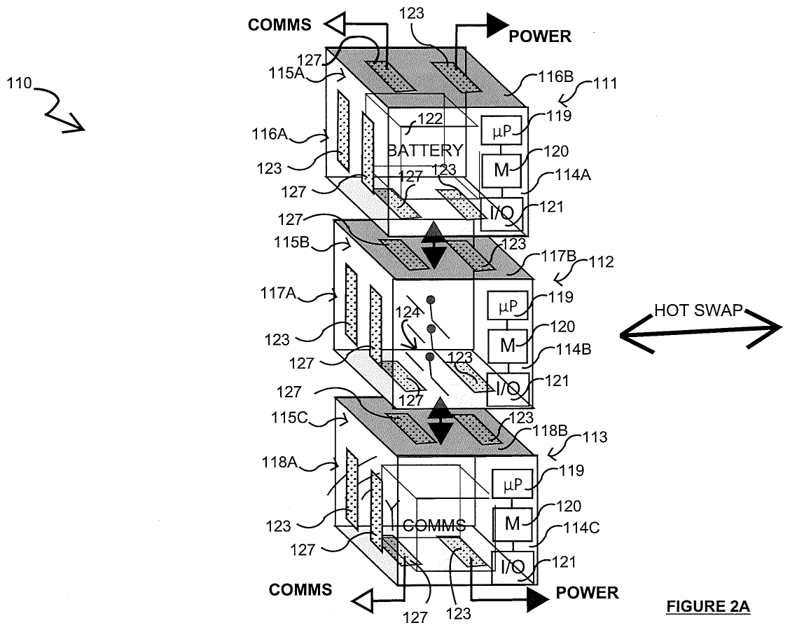

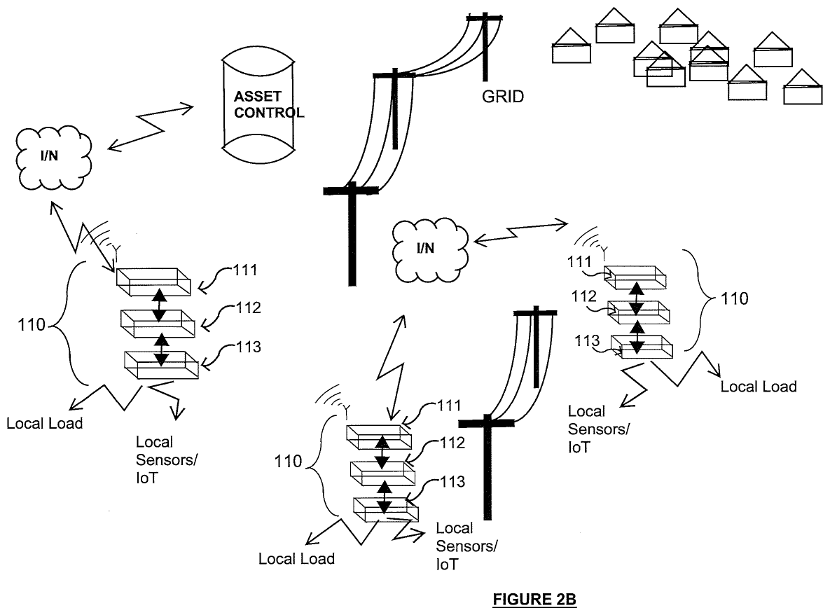

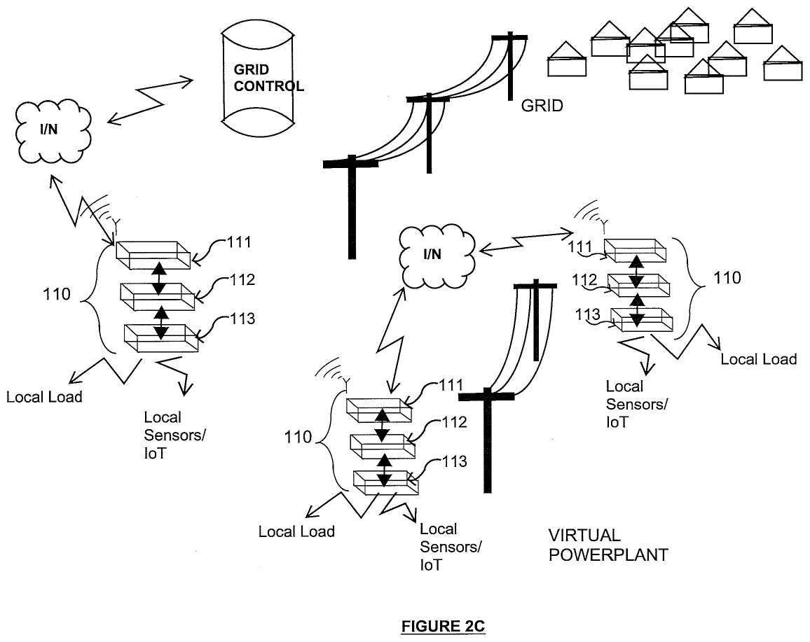

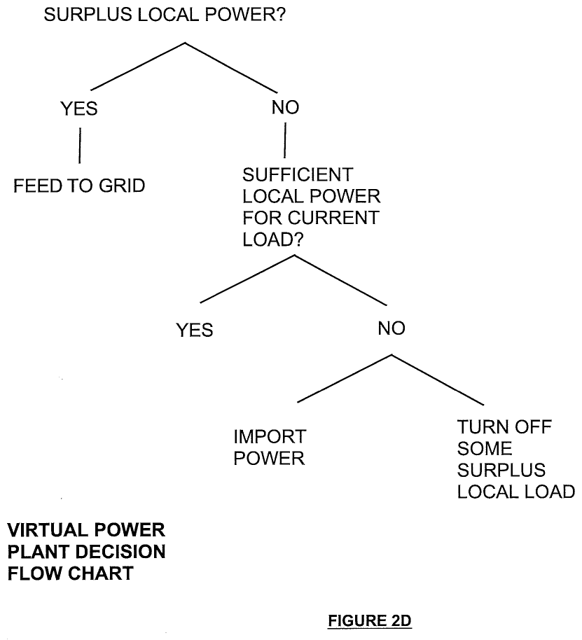

In addition, with reference to FIG. 2 “intelligence” can be incorporated within the elongated support components 15, 16, 17, 18 and/or within the battery modules 11 A, B, C, D.

### FIG. 2:

The diagram illustrates the basic components of the intelligence comprising, in this instance, a digital microprocessor 30 in communication with a memory 31 and also in communication with radio aerial output 32 and also in communication with an input output structure 33.

The radio communication can include but is not limited to Wi-Fi, Bluetooth, 4G, 5G technology capability.

The input output structure 33 can include a bus 34 of similar structure to the bus structures referenced above with respect to FIG. 1.

In this manner “intelligence” is communicable along the conductive paths 19-24 and thereby between all components comprising the modular battery structure arrangement 10 of FIG. 1.

The communications may be encrypted to provide security and reliability.

The components illustrated can be interlocked mechanically in a manner to be described below and with reference to additional figures. The structures may be of load bearing capability to protect the battery modules.

The end result is an arrangement which can be assembled so that every component is in a mechanically interlocked fashion and every component is also in electrical communication one with any other forming the modular battery structure arrangement 10.

In preferred forms the status of the structure including its structural load bearing capability, electrical functionality and its mechanical functionality can be communicated via aerial 32 over the Internet to a server 40 from there to individual users, for example via an application running on a digital device such as a smart phone 41.

### In Use—Interconnectable Housing Modules

FIG. 2A—is a block diagram of three modular interconnectable housing structures, connected in a vertical array. So as to form a built structure.

FIG. 2B—An example of use of the built structure of FIG. 2A, as part of an Asset Control System.

FIG. 2C—An example of use of the built structure of FIG. 2A, as part of an Grid Control System.

FIG. 2D—A flow chart of the logic applicable to the example of FIG. 2C operating as a virtual power plant.

### In Use

With reference to FIG. 2A there is shown a first modular interconnectable housing structure 111 interconnectable with a second modular interconnectable housing structure 112 which, in turn, is interconnectable with ⅓ modular interconnectable housing structure 113.

In this instance the three interconnected modular interconnectable housing structures form a built structure 110.

In this instance each modular interconnectable housing structure 111, 112, 113 comprises an enclosure, in this instance a rectilinear enclosure 114 A, 114 B, 114 C. The rectilinear enclosure defines an internal volume 115 A, 115 B, 115 C.

Each enclosure has wall components, in this instance planar wall components 116, 117, 118 defining respective rectangular prism shaped structures.

In this instance wall of the housing structures 111, 112, 113 making up the built structure 110 contain a processor 119 communication with a memory 120 thereby to permit execution of program steps stored in the memory. The processor 119 communication with components within the volume 115 via input output structure 121.

The internal volume 115 A of first modular interconnectable housing structure 111 contains, in this instance, a battery 122. The battery 122 is in power communication with power connectors in the wall components 116 A, B, C thereby to permit power communication to any like modular interconnectable housing structures juxtaposed against any of the walls of the housing structure 111.

In this instance the internal volume 115 B of the second modular interconnectable housing structure 112 contains a switch 124 in communication with power connectors 125 in each of the wall components 117 A, B, C thereby to permit switching of power communicated into or out of the housing structure 112.

In this instance the internal volume 115 C of third modular interconnectable housing structure 113 contains a communications module 126 stop the communications module 156 may communicate via radiofrequency communication via antenna 127. Alternatively or in addition communicate via communications connectors 127 in the wall components 118.

In use a user assembles the three modular interconnectable housing structures having first selected the structures for the functions each is to perform when assembled as part of the built structure. 110.

In this instance the functions are power storage (battery), switching and communications. As described elsewhere in this specification and many other functions may be incorporated within the internal volume 115.

The built structure 110 may communicate with other modular interconnectable housing structures either at the same location or at other locations. Examples of such communication are provided elsewhere in this specification.

In preferred forms the interconnectable housing structures are “hot swappable” in that individual structures may be removed whilst the built structure 110 continues to perform/be connected to other built structures.

As elsewhere described the wall components 116, 117, 118 may be structured in many different ways to provide functional behaviour (for example resistance to shock, waterproofing) or aesthetic function in the sense of allowing the built structure 110 to blend in in the environment in which it is placed.

### First Preferred Embodiment

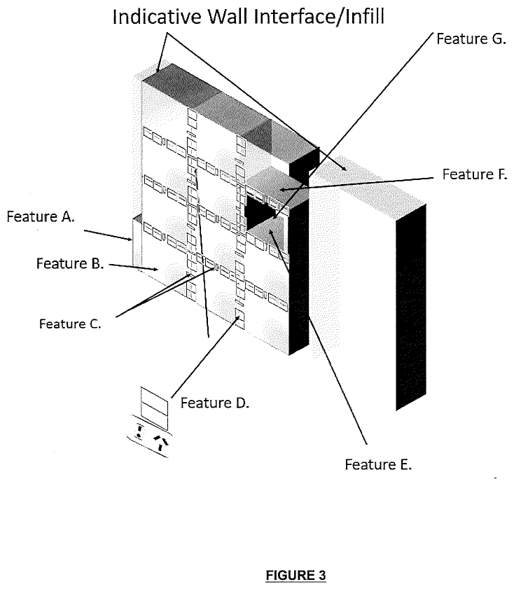

With reference to FIGS. 3 to 17 there is illustrated a modular battery wall arrangement according to a first embodiment as will now be described in greater detail below.

### Part 1. Context

Refer to the background section of this description for context for embodiments to follow.

### Part 2 Examples of Embodiment 1

Assembly and disassembly of electrical connection without electrician trades or building trades.

Location and settings determined with Bluetooth device and physical clasps

Fixed and non fixed structures incorporating battery walls apply. Such as:

Trade Shows

Live Venues

Construction Site Shed Demountables

Off grid villages

Vans/camper-vans

Tents

Renovations of various property types including revised fit outs

Established/Open plan retail and residential settings

Established/Open plan commercial/industrial setting

High Rise office.

The assembly and disassembly can occur with/without trade skills and qualifications.

Sequence for installation is guided by the software application for the simulated space to construct the battery wall.

Software to be compatible with Geospatial Information systems and Google earth, google sketch up and various software

Bespoke design service available for: the aesthetic finishes and engineering configuration to fit, with unique usage situation for structural specification requirements; Demand design e.g. standard single phase versus three phase use; including direction to appropriate energy vendors for the connection of solar/petrol generation/fixed power outlet/Hydrogen cell/wind cell/Algae etc

Scaling of the physical environment to then map out the usage of the battery modules.

Usage inputs—eg intended location of the battery modules.

software simulates the battery wall constraints demonstrating the capacity options of the existing system also outlining if there are system shortfalls to meet design performance and recommending adjustment to the system

A click and collect order service may occur.

Assembly sequence:

Locate/install Rectifier control source

Establish Battery block lay out (ensuring level surface)-hold point education for installer

Proceed with Placement and connection of modules

Synchronisation with application on the computer/phone to ensure the wall matches the design settings

Output controls and clasps communicate to optimise base load power and front battery power configuration for appliance draw.

appliance verification (for safety)

Clasps placed for the series and parallel circuits required for the battery array

Outlets placed for nominated locations. Note. Outlet interval spacings 1 cm, for the 50 cm×50 cm battery brick scenario.

Safety isolation compactors placed

Testing hold point with software app

Placement of circuit breaker aesthetic tiles.

Final power check and activation.

Battery array to be available for use.

Aesthetic upgrades:

Re-order aesthetic covers with compatible circuit breakers—using the phone/computer application or customer design service.

Dis-assembly sequence:

Existing model reviewed in the software application.

Modification design input into the phone/computer.

Dis-assembly/re-assembly sequence determined via software app and customer design service.

Hold points for safety to be ensured.

E.g. Aesthetic panel circuit breaker removed—isolates the immediate cell and various cells in series.

NOTES: Encrypted technology security and data security controls with sensors: Bespoke password keys are generated for individuals who purchase the technology. Bespoke Bluetooth technology add-on hardware is to be used to ensure that the individual's asset is secure and unhampered from interference from unknown threats. E.g. mutual power walls in an apartment complex, or employee theft from offices. Options available include specific locks and key systems as part of attachment mechanisms.

### Part 3. Variations of First Preferred Embodiment

Battery bricks scalability can vary according to the contexts from Low Voltage to High Voltage.

The battery bricks can vary in size, weight and composition. An infinite dimensional battery slab could apply as would as a building, or to the industrial scale for battery storage for industrial power generation.

Variations to the battery brick expandability is included. The option of individual cells with perimeter sensor controls are for safety engineering.

Educated individuals/customers may be able to order battery bricks without perimeter sensors which would be additive and cumulative, subject to electrical and structural engineering certifications of the design usage of the battery technology parameters (weight, electromagnetism, earthing etc) are to be determined.

Usage of these batteries could apply to high voltage adaptations, in the event trades/builders without electrician certificates, may utilise the technology.

Certification in the correct design and usage of this technology would be required to ensure safe adaptation of the sensor, controls and systems for usage. E.g. builder constructing battery wall for a library, or a High Voltage Engineer designing a back up battery bank for substation use. The risk and liabilities would be determined on a case to case basis for these larger scale embodiments for the given battery technology to be adopted.

If a battery technology manufacturer nominates this design for their product, consultation is required to ensure the sensor systems, cooling and thermal control systems are compatible.

### FIG. 3:

Feature A. Rectifier Power Connection Panel

Feature B. Battery Bricks

Feature C. Conduction Clasps

Feature D. Smart Outlets/Switches—Concealed Variable Connection Point Options for Smart Outlets to Connect

Feature E. Perimeter sensor Structures can be used as a cavity for centralised power boards and device connections etc

Feature F. Structural design specifications of perimeter supports (in isolated cubes and as independent longitudinal/lateral supports/beams in an array) are variable to the array/scale to be used. Materials engineering and structural design can be varied to suit to marry both the sensors and structures to protect battery components.

Feature G. Variable Battery Technology components/compatible technology inserts to ensure sensor compatibility.

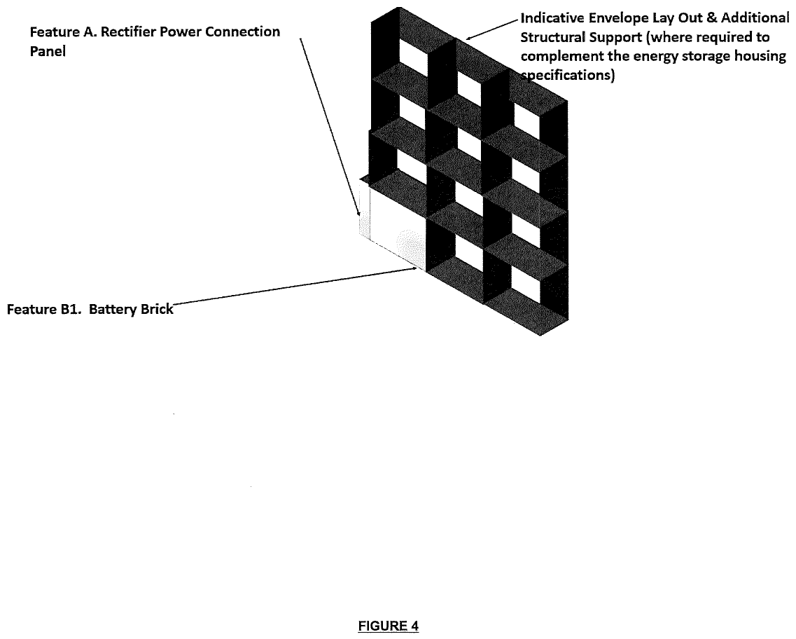

### FIG. 4

Feature A. Rectifier Power Connection Panel

Connectivity Panel Option of 4 or more types:

Direct Power Outlet connection to wall socket; or

Generator Power Connection; or

Solar Connection; or

Fuel Cell from alternative Renewable Generation.

Including the installation of a Alternating Control Switch Controller (ACS) at the control board

The ACS allows the cells to safely added/connected/expanded as part of the uninterrupted power supply source

.Notes.

No wiring required.

Functions by plugging into Feature B.

Feature B1. Battery Brick

Standalone battery brick composite product and designed to be water tight.

Stackable and interconnectable with other battery brick assemblies.

Compatible with Item (A) of 4 variations.

Length, width and depth variable to battery type used and aesthetic panels selected.

options available for tiling or grid aesthetics scaling from the bricks dimensions.

Interconnected bricks have interlocking charge points to maintain storage capacity.

The brick composite integrates structural circuit board controls into the frame and battery.

Battery bricks have front facing perimeter connection points which are compatible with future positions power outlets locations. Note. Perimeter perforation spacing connection points are of nominal variable distances.

Smart-ware device including:

Sensors to determine quantity of battery bricks configured into the wall.

Charge and draw of power determined from blue-tooth user interface.

Remaining time available for usage when in use.

Additional charge required if in battery mode and not being charged.

Future outlet locations have integrated Programmed Control Loops when interconnecting the outlets.

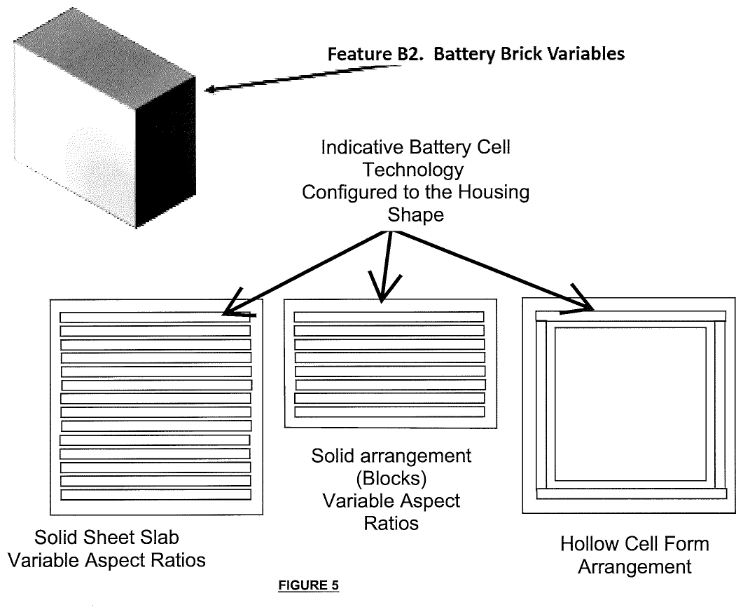

### FIG. 5:

Feature B2. Battery Brick Variables

Water Tight option available, with ability to enable safety short circuits if Feature D is subject to water.

Stackable and interconnectable details consist of:

Reinforced hollow sections to structurally withstand the weight of the batteries.

Contain sensors for the activation and configuration of the battery wall array.

Contain variable 1 cm increments along the X-Y perimeter axis to which the inverter outlet will be compatible to activate.

The hollow sections framing the battery brick can consist of metal and non-metal products that are flush with the surface finish.

The rear face can be fixed to other structures for structural reinforcement and stability.

Every batter brick will be design to have variable compatibility with Feature (A) Rectifier of 4 variations. The brick depth to vary to accommodate the battery technology inside.

Length, width and depth variable to battery technology used and aesthetic panels selected.

Interchangeable front panel linings are available to various aesthetic surface finishes

Design for assembly and disassembly. Only to the brick components. The entire unit is to go to the service centre for maintenance and inspection

Options available for tiling or grid aesthetics scaling from the bricks dimensions.

Interconnected bricks have interlocking charge points to maintain storage capacity.

The brick composite integrates structural circuit board controls into the frame and battery.

Battery bricks have front facing perimeter connection points which are compatible with future positions power outlets locations. Note. Perimeter perforation spacing connection points are of nominal variable distances.

Smart-ware device including:

Sensors to determine quantity of battery bricks configured into the wall—zone definition of which bricks will be activated

charge and draw of power determined from blue-tooth user interface.

Remaining time available for usage when in use.

Additional charge required if in battery mode and not being charged.

Future outlet locations have integrated Programmed Control Loops when interconnecting the outlets.

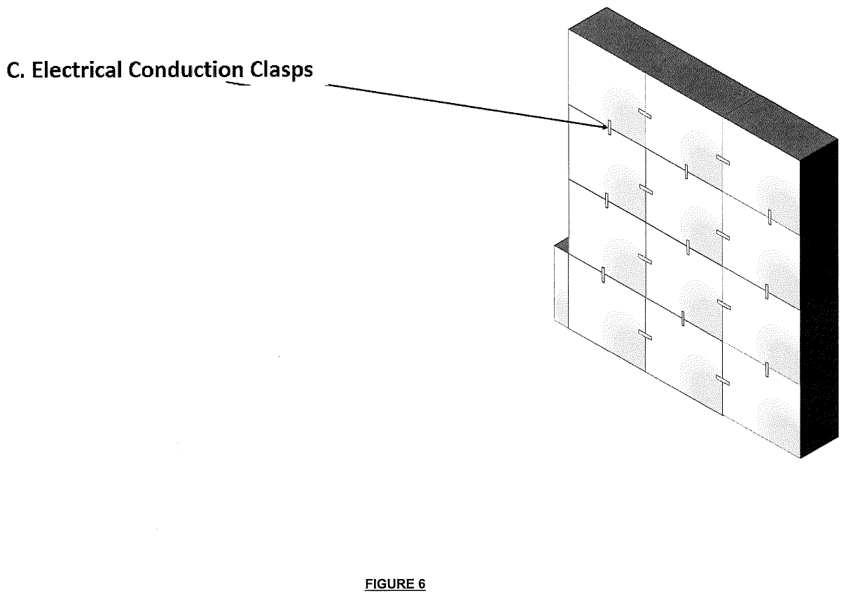

### FIG. 6:

C. Electrical Conduction Clasps

Choice of interlinking all battery bricks through use of conduction claps. The clasps are of varying copper diameter relative to the voltage demand and conductivity of material nominated e.g copper, aluminium or equivalent.

Clasps can be configured to tailor the battery usage to draw upon the full power, or to create zonal capability of the wall units

Choice of location to isolate the various units. E.g. 8 units for electrical draw power required for given usage.

Clasps are child resistant releases flush with the wall and are water tight. With optional tamper proof-tamper evident fasteners for public spaces.

Location of clasps to be determined for the given battery technology constraints and visual aesthetic selected by the user.

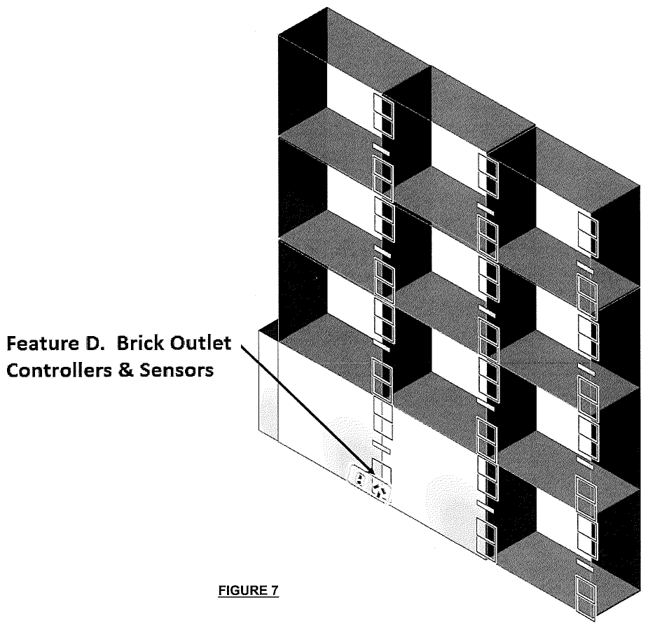

### FIG. 7

Feature D. Brick Outlet Controllers & Sensors

Battery bricks have front facing perimeter connection points which are compatible with future positions power outlets locations.

The Designed sensors activate upon placement and configuration of the control the power outlet using process control loops.

Capable of having light switch controls and light bulb/LED connections

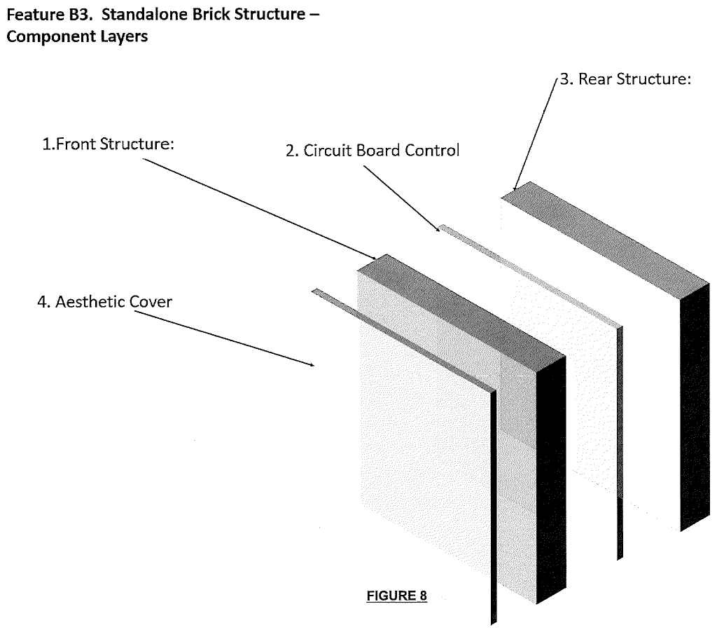

### FIG. 8:

Feature B3. Standalone Brick Structure—Component Layers (relative to the form of the battery technology)

Front Structure: Battery Draw/Discharge interface and Battery Management System interface

Circuit Board Control and electrical draw management system interface/cable connections

Rear Structure: Re-charge and Battery Management System life span, thermal control and storage

Aesthetic Cover for the battery bricks

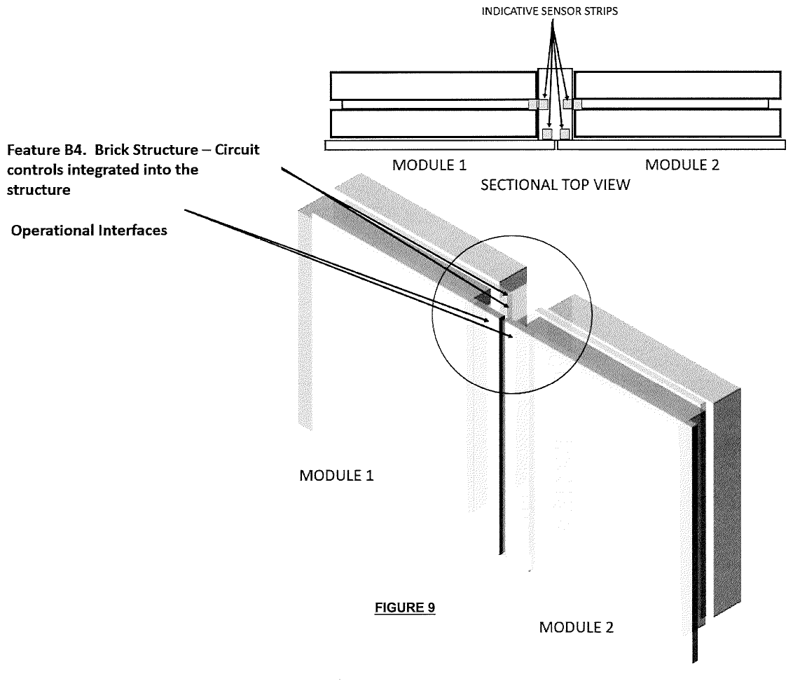

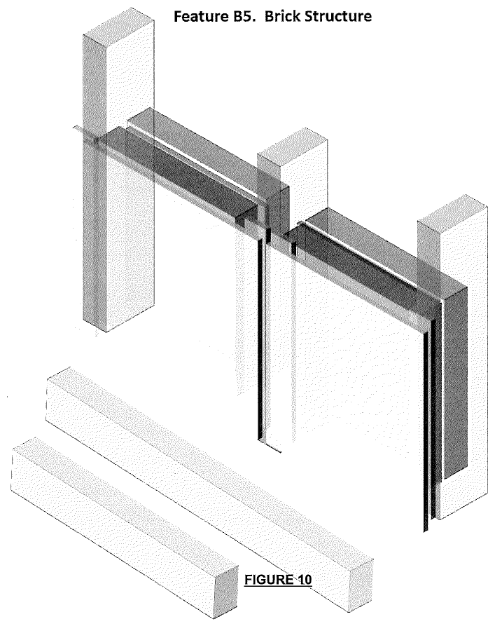

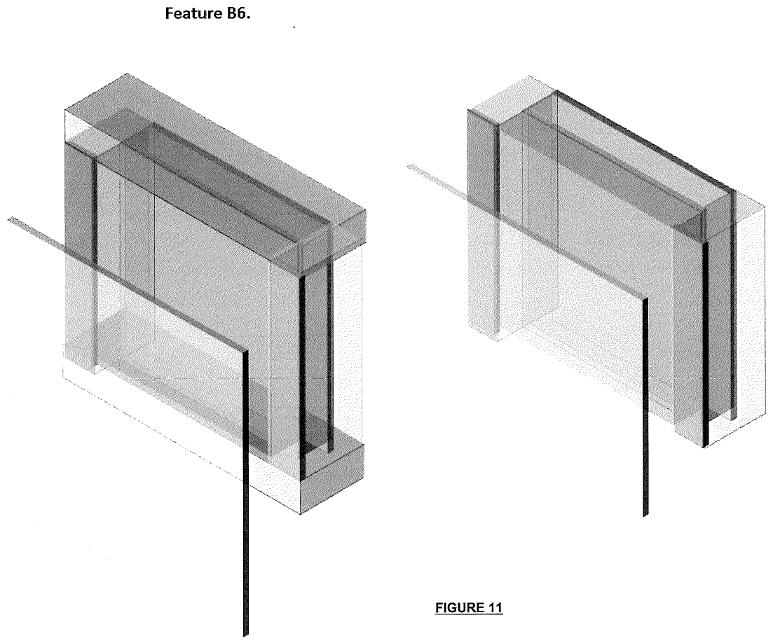

### FIG. 9

Feature B4. Brick Structure—Circuit controls integrated into the structure—Operational Interfaces

Circuit control board connection and sensors to the structural control strip

Aesthetic tiles have movable flaps/patches/plugs to enable access for:

Activation of control sockets for the battery enable battery circuit connections—

Activation of adjoining batteries to increase draw power at the desired outlet location.

### FIG. 10

Feature B5. Brick Structure—Options—Baton conductive strips can be provided with independent vertical or horizontal conductive strips to match into the battery array.

### FIG. 11

Feature B6. Brick Structure—Options—Vertical/Horizontal or All Sides having Baton conductive strips.

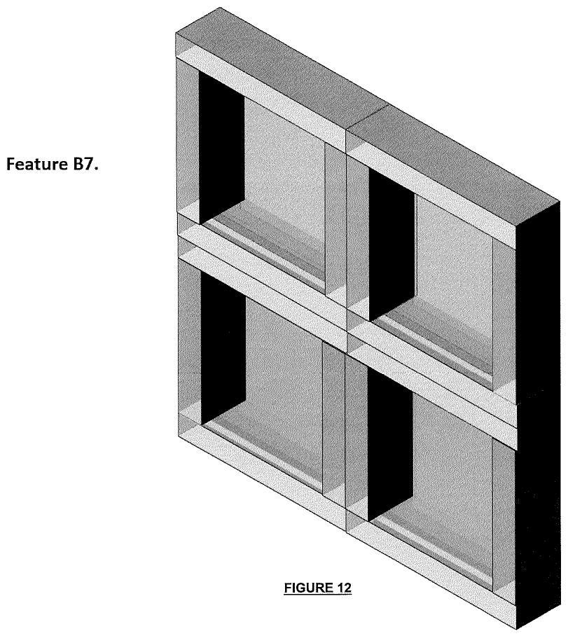

### FIG. 12

Feature B7. Brick Structure—Options—All Sides having Baton conductive strips 2×2 array.

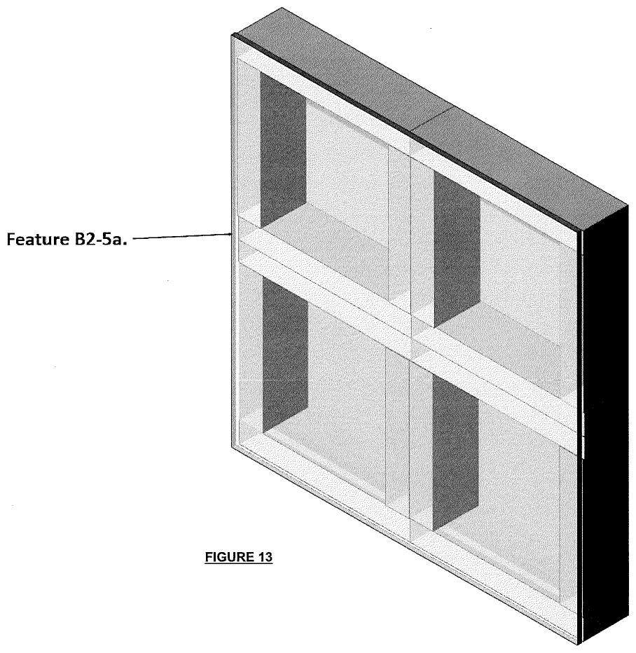

### FIG. 13

Feature B2-5a. Aesthetic Cover—Inbuilt Circuit Breaker.

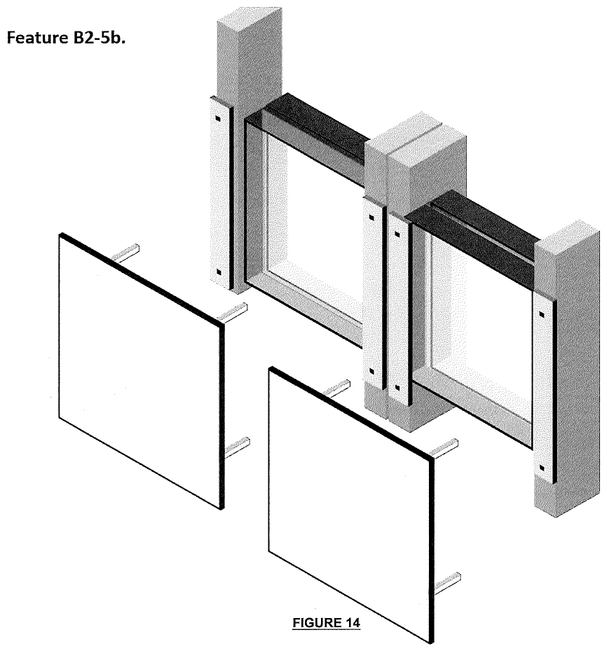

Aesthetic Cover clipped in—enables circuit to be “ON” for the series circuit FIG. 14

Feature B2-5b. Aesthetic Cover—Inbuilt Circuit Breaker.

Aesthetic Cover clipped in—enables circuit to be “ON” for the series circuit.

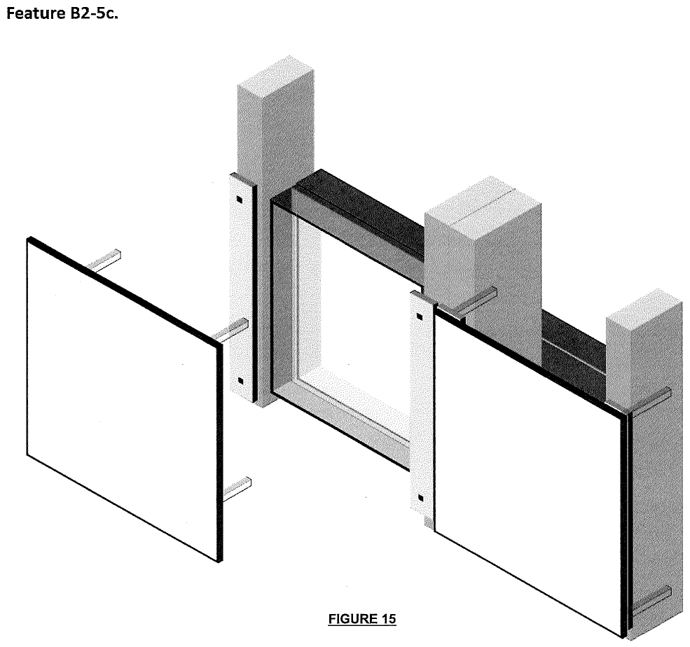

### FIG. 15

Feature B2-5c. Aesthetic Cover—Inbuilt Circuit Breaker—Safety Pins

Aesthetic Cover clipped in—enables circuit to be “ON” for the series circuit

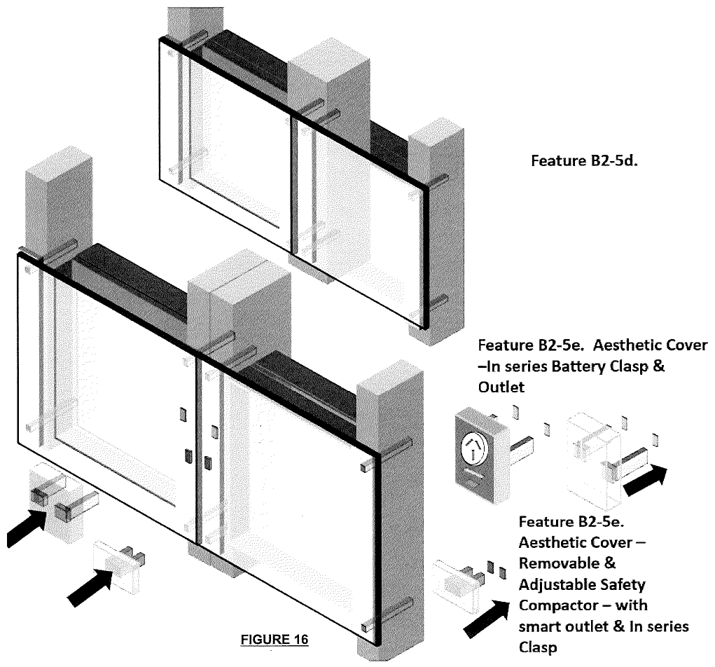

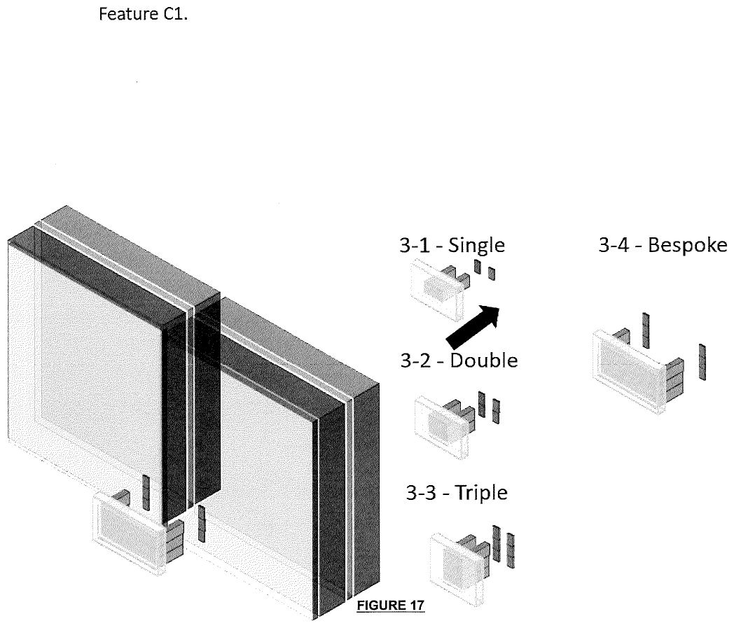

### FIG. 16

Feature B2-5d. Aesthetic Cover—Removable & Adjustable Safety Compactor/water proof and electrical isolating seals (to suit user need)—without smart outlet

Feature B2-5e. Aesthetic Cover—Removable & Adjustable Safety Compactor/water proof and electrical isolating seals (to suit user need)—with smart outlet & In series Clasp

Feature B2-5e. Aesthetic Cover—In series Battery Clasp & Outlet

### FIG. 17

Feature Cl. Conduction Clasps—Interchangeable of Variable Width, Conductivity and contact areas (Relative to the battery form)

Creates in-series circuit in one direction

Cross sensor controls across perimeter of the batteries May be used in combination or individually expanded for bespoke use e.g. for 3 phase battery linkages for the industrial scale modules where a 3-phase inverter is part of the optional module assemble.

Intended for use for configuring front batteries for user—zonal control/battery configuration

Sensors and Bluetooth programs rear battery draw.

### Second Preferred Embodiment

With reference to FIGS. 18 to 22, there is described a second preferred embodiment of the Modular Battery Structure.

### FIG. 18

Feature A. Rectifier Power Connection Panel

Feature B. Battery Bricks

Feature C. Conduction Clasps

Feature D. Smart Outlets/Switches—Concealed Variable Connection Point Options for Smart Outlets to Connect

Feature E. Perimeter sensor Structures can be used as a cavity for centralised power boards and device connections etc

Feature F. Structural design specifications of perimeter supports (e.g. in isolated forms/shapes and as independent longitudinal/lateral supports/beams in an array) are variable to the array/scale to be used.

Materials engineering and structural design can be varied to suit to marry both the sensors and structures to protect battery components.

Feature G. Variable Battery Technology components/compatible technology inserts to ensure sensor compatibility

### FIG. 19

Feature E Perimeter sensor Structures can be used as a cavity for centralised power boards etc—if configuring batteries in a unique spatial arrangement
e.g. Cavity for control boards
e.g. Cavity for specialised lighting/sound rigs
e.g. Cavity for centralised power cablings for sockets/devices utilising power
e.g. Cavity without perimeter central circuits for non-weighted shelving/carpentry interface

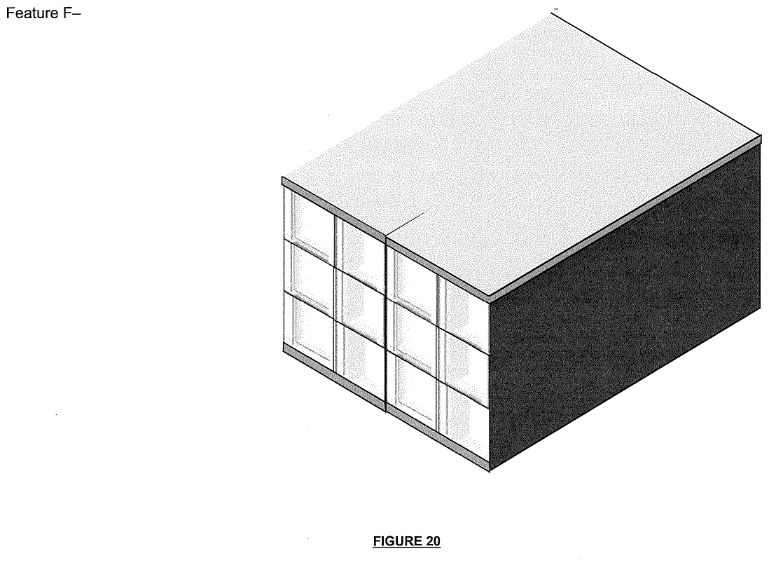

### FIG. 20

Feature F—Structural design specifications are variable to the array/scale to be used.

Materials engineering and structural design can be varied to suit to marry both the sensors and structures to protect battery components.

### FIG. 21

Feature F-1—Structural design specifications are variable to the array/scale to be used.

Materials engineering and structural design can be varied to suit to marry both the sensors and structures to protect battery components.

### FIG. 22

Feature F 2—Compatible Corner—Interconnections (Support and sensor interface). Maintenance access hatches can be made from these junctions either for indoor or outdoor access configurations relative to the spatial designation.

### Third Preferred Embodiment

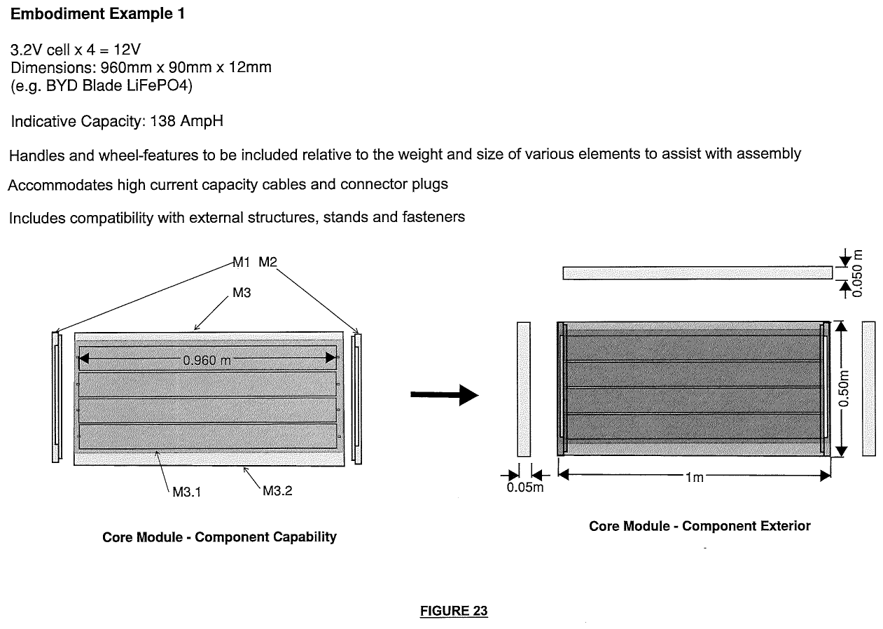

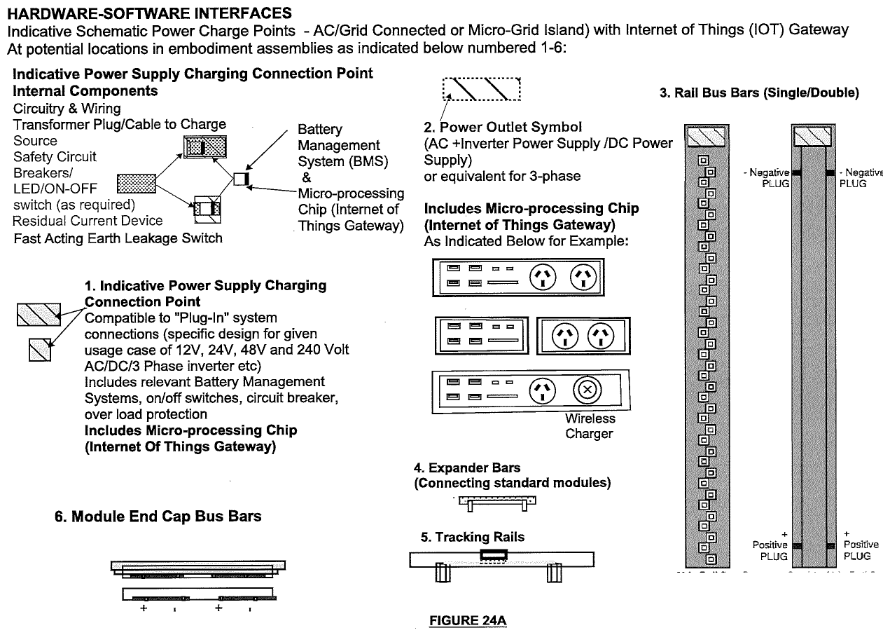

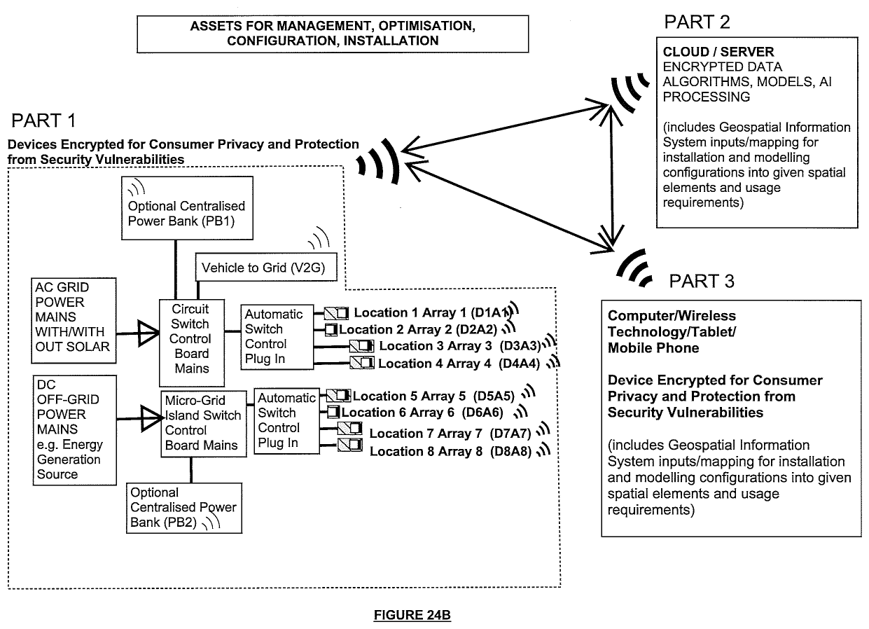

With reference to FIGS. 23-41, there is described a third embodiment of the Modular Battery Structure. Restatement of preferred forms of the invention

The modules can be used indoors, outdoors or in other environments optionally where architectural appeal is required.

Energy storage and power use is typically wired-in, expensive and bulky. Wall sockets are fixed, requiring extension cables or costly qualified labour.

Embodiments of the invention of “smart” construction materials enables: Low-skill user interfaces for indoor/outdoors and temporary/permanent use; Quick and easy set-up, installation/adjustment to all things electrical from appliance to control-board; serviceability; recyclability; a carbon efficient alternative to big infrastructure.

Combining building materials, electricity/energy storage product markets creates savings in materials/energy/money whilst reducing carbon. Providing large-scale intelligent systems and control into everyday buildings, forms and spaces. Conveniently and aesthetically optimising limited realestate.

Embodiments of the invention is designed to make it easy to personalise current energy storage and outlet supply arrangements. Currently in buildings, energy storage and supply is wired in with energy storage being in a centralised location. This invention allows the agile and semi-permanent use of energy.

This invention allows energy storage and power supply in either grid connected or energy micro-island scenarios or off grid.

Power supply, energy storage and building materials are integrated in this invention to enable shelter, safety and comfort.

Safety engineering of energy storage & building product is possible through product design, electrical engineering, materials engineering, software control and sensors.

Embodiments of the invention integrates these key elements to achieve and collectively include micro and low. voltage energy systems interfacing with high voltage energy systems.

Embodiments of the invention of “smart” construction materials enables low-skill user interfaces for indoor and outdoors or for temporary and semi-permanent use for power storage and supply. Designed specifically for allowing convenience and personalization for power outlet locations and energy storage configuration.

Maximizing function of limited spaces in our buildings and open spaces—in the confines of our walls and added furnishings.

Embodiments of the invention provides large-scale intelligent systems and control in micro-forms and spaces. Capturing the remnant energy efficiency opportunities through remote control data systems. This technology is not currently available in the art of energy storage, particularly in relation to coordinating micro-energy storage, where the optimization can account for large scale impact.

Embodiments of the invention is capturing micro-opportunities to optimizes on the spatial and financial burden of centralised infrastructure (industrial power plant generation, estate scale, to isolated building power generation). The current art of energy efficiency focuses on centralized large scale assets built to achieve the benefit of large scale energy savings. The current arts appreciate building powerbanks to estate substation powerbanks. Virtual power stations are accounting for the larger scale and usage of powerbanks and energy storage.

combining building materials, electricity-energy storage product markets creates savings in materials, energy and money whilst reducing carbon.

### Third Embodiment—Enabling Disclosure

A battery assembly of components enclosed in an engineered environment with aesthetic simple interlocks and available to be combined with other compatible components that are easily assembled and disassembled for varied uses/locations as required.

It provides DIY building ease into construction materials, whilst also being an engineering technology-hardware, software and expansion capabilities. Including adjustable and can be personalised to suit changing needs.

Safety engineering of energy storage & building product, is possible through product design, electrical engineering, materials engineering, software control and sensors.

Smart software-application based systems can introduce baseline knowledge in user friendly form, using technology aids whilst reading instructions for assembly and understanding simple control interfaces.

These modules combine systems for energy storage and use independently and interchangeable. Using additive or substrative components in highly engineered housings are equivalent to “utility cabinets” that are translated into a simpler interface suitable for a wider skill set equivalent to the “do-it-yourself” person, who can use the technology that is designed for assembly and equivalent disassembly.

These modules are designed so that task based energy usage will reduce the overall peak loads of the fixed grid network, and enable micro-scale power usage optimisation for renewables (plug in renewable grid supply and localised built in renewables).

The Internet of Things Gateway will be able to receive data from the users existing systems and provide analysis and metrics associated with the hardware, operations, user preferences, installation configuration and arrangements so that the broad range of energy storage can operate in orchestration with other assets and energy supplier subscriptions.

The technology of integrating systems is an asset management system with initiative. Diagnostic of hardware interfaces, fault detection of installation and system condition reviews, battery performance, and physical environmental facts with sensors e.g. thermal/acoustic/motion etc. Using combinations of real-time based data, and user setting configurations and preferences.

Providing integrated user experience to ensure that power use and systems remain on or off either for user requirements relative to other assets eg. Electric Vehicle to grid charging, or Solar Array power bank optimization, or increasing battery energy capacity saved for use during peak fee timeframes (according to fee structure subscriptions), or to not exceed energy demand thresholds for given time slots on an industrial tenancy.

DIY micro-energy storage-building systems can reduce financial burden of the large scale infrastructure budgets and estate infrastructure development costs by mitigating the demand and impact on developable foot prints and floor plate size of buildings.

The modular nature of these energy storage power outlet building systems allows systemization and choice in personalizing their assets, relative to the technology type, and specification standards. The disassemble nature of the product allows users to be removed from fixed assets and fixed contracts, where features of the size and scale of their battery cells and power outlet types are changeable, removable and repairable.

The scale of adopting such building materials, provides opportunity for mitigating against design obsolescence, and provides additional carbon sink opportunities, allowing persons to prefer items that consist of low-carbon emission sourced materials, or has planned lifecycle re-use in the future circular economy of waste reduction and carbon reduction strategies.

Do-It Yourself construction power and building products will enable individuals or businesses to more readily enhance/build their infrastructure and assets

Large scale data management systems of the built-in energy storage building material will allow micro control optimisation (using large scale asset management techniques and strategies).

The embodiments of this invention sees it's role for substitution of regimented and fixed “utility cabinets”, when incorporating energy storage/power outlets in a more agile engineered housing for easy use and modification. Allowing users to add-on components and accessories suitable to the user needs and context. The innovation provides opportunity for people to by-pass the risk and inconvenience of resource delays for example, associated absence of specialist trades during a environmental catastrophe. It also enables specialist skillful trades to divert their efforts to more complex tasks suited for their skill set. Removing responsibility for demolition of facia panels/gyprock/brick, reducing need to undertake services locations for wires and cable either in the concrete panel or in-built building services channels of the plant room.

The embodiments of this invention will assist in reducing waste and remediation through the means of enabling retrofit solutions in building floor plans and outdoor hard landscaping. The enabling of varied surface finishes for architectural and structural performance requirements can reduce design obsolescence of existing assets. Also, in nominating low carbon materials and recycled products in effect provide a larger scale positive impact for carbon mitigation in the construction and built environment. Considering the life span of products can be extended, enhanced or repaired through retrofit modifications.

FIG. 23—EXAMPLES OF THIRD PREFERRED EMBODIMENT—Embodiment utilising specific form factor of battery cell technology BYD Blade LiFePO4

### 1: Modular Core Building Block for Building Array

Each building block housing various battery technology

Modules are able to be used as a 12V energy storage/power supply.

“End plates” are pre-designed to contain bus bars (water tight/electrically isolated)

Modules can be used in series to build 24V Building Blocks Modules can be used in series to build 48V Building Blocks

All modules are then able to be configured in parallel to adjust the form and space to which the modules are to be used.

### Core Module—Component Capability

Electrical components M1 and M2 are designed specific to the battery capacity, battery form and configuration requirements, maximum stacking capacity/use threshold relative to the requirements of the cell technology terminals and interfaces.

M3 is the battery cell module assembled with appropriate “housing” to meet relevant design requirements. E.g. Thermal and structural needs, air-tight or chemical resistance, hardness, water permeability, and shock absorbing dampers/resilient supports required to contain battery pockets/envelope M3.2.

M3 consists of 2 housings:

Feature M3.1 Indicates the internal pocket/envelope containing battery cells and components packaging and protection, including the primary water proof seal/electrical isolation container (is the primary sealed product that can include intumescent fire-retarding agents and additional engineered solutions compatible with the battery cell materials).

Feature M3.2 Indicates exterior architectural-semi structural housing that will be fabricated to engineering requirements equivalent to the usage case. For example, similar to a building material of required tensile and compressive strengths including an exterior for aesthetic, physical properties and structural-fastening functions required.

Feature M1, M2 and M3.1 provide an aesthetic that is materially consistent on the exterior.

Feature M1, M2 and M3.1 mechanical performance and materials engineering and structural design will accommodate not only the mass and rigidity of M3.2 but in addition:
(1) Enable additional external structural supports or modifications to raise and prop the module, or accommodate fastener connections in specific locations for purposes of concealed handle hook points and for temporary wheel connections.
(2) Accommodate stands for additional propping and supports.
(3) Accommodate load bearing capability according to the load rating of the housing to provide structurally resilient systems, in conjunction design interfaces and clasp requirements as indicatively shown in FIGS. 21 and FIGS. 35 to 50.
(4) M3.1 can consist of either non-unique material housings such as sheet metal, polymers, and composites.
(5) M3.1 can consist of the unique composite pre-cast engineered material that uniquely integrates elements of functionality such as:
(a) Heat-sink/thermal mass temperature distribution
(b) structural reinforcement of the ultra high strength composite concrete bulk matrix panel
(c) Dampening/shock absorbing mechanical buffer mutually for the housing itself (with or without pre/post tensioned treatments, as well as supporting M3.2 in the event of low grade impacts.

The unique composite material housing engineering of M3.1 utilises unique layers of knitted steel knitted with glass fibre intertwined (using Marine Grade Stainless Steel 317 for outdoor/aggressive surface environments). Whereby the knitted reinforced mesh in various forms (corrugated/flat sheets/cylinders/multiple layers) operates to provide spring-like interaction with feature M3.2.

M1, M2 and M3 are assembled to comprise of sealed interconnects to be water tight, fire resistant etc. Matching to the required properties of M3.2.

M1, M2, and M3 have relevant thermal sensors and controls and connections with the Internet of Things Gateway system, including safety circuit breakers, and residual current device fast acting earth leakage switches.

Upon assembly of M1, and M2, will the circuit breaker/associated sensor be dis-engaged to allow power.

The Internet of Things can use interdirect Blue-tooth/wireless encrypted communications with the cloud. Such that modules will be able to be spatially identified relative to the Global Positioning system and Geospatial engineered model during the installation process. The registration of the uniquely indentified modules, will assist the user to assemble other associated modules and components requiring connection (electrical and structural interfaces). Quality and manufacturing origins will be included. The option of including a data control panel could be included in the module, however the Internet of Thing Gateway will be able to project the control panel options to the user's telecommunication/smart devise, in effect operating as a encrypted end to end remote control. The data control and monitoring settings includes performance data, maintenance schedule and fault detection trouble shooting.

The intelligence connecting the core modules to adjoining modules, include assistance and direction on the assembly using three-dimensional mapping/locational control as a check point quality control management process (processes will be designed specific to the battery cell/chemistry manufacturer requirements). Optimised placement and use of the modules of either connected or non-connected positioning can be relayed to the user and the cloud, relative to other panels, and physical spatial attributes the panels will be placed in the given usage. The array of modules interconnecting with other matching appliance controls can be registered into the database and modelling algorithms to be designated “zones” for timely use and operation. The “zones” are identified to ensure that the various battery panels can appropriately charge and discharge during use. So that the modules can be engineered or configured to achieve user objectives for power supply. For example, ensuring full battery capacity from roof top solar energy generation during high cost kilowatt hour charge rates (i.e. from 5 pm-9 pm). Conversely a building or structure without solar energy can set energy settings in the Internet of Things Gateway to intentionally measure and monitor time based kilowatt hours surplus solar diverted from the grid into the modules relative to the retail energy plan agreements. Such measurements and calculations can be made for the overall effective energy “saved” that would other wise be wasted, is now acting as a remote battery system to a distant unattached solar array/renewable energy generation source. Measurements can capture from the rectifier module battery charger (plugged into existing power outlet/Automatic Switch controller connection point) such that possible financial deduction schemes could apply and provide rebates/discounts, to ensure that the solar sponge effect is maximised relative to the grid connected renewable infrastructure.

The embodiments of various battery storage forms such as this example in FIG. 23, FIG. 46-50, can be used in the registered “ecosystem” of energy storage established through the building.

INTERCONNECTIONS OF CORE MODULES: This embodiment example shows modules to be flush in nature with edges and profiles designed to suit aesthetic preferences such as bevel/rounded edges or flat straight edged. The colouring M1, M2 and M3 can be personally coloured to suit in the manufactured form. Optional seal and gloss finishes can be applied.

M1 and M2 end caps have capability to be made with connections to be either sacrificially “pierced”, or present with re-usable or non-reusable tamper evident plugs to open/close connection cavities.

Sealing at M1 and M2 is available at the end caps interfacing to M3, to ensure water tightness or the air pocket is “maintained”. Optional re-sealable uni-directional or bi-directional vents are present to accommodate relevant air pressure/expansion for the “use” for indoor, outdoor, low-pressure and high pressure environments and for external façade water proofing management.

Component design is able to be maintained and repaired.

Details of the plug-in capability in line with electrical compliance certifications. Refer to indicative connections in detailed diagram for “Module Stacking”.

Dimensions are variable according to the structural design, compliance and material selection performance preferences and certification requirements to the relevant quality standards recognised in the country.

Components are ideally metric and can have concealed indicators of units/measures on the surface to assist building and stacking during assembly for ease.

### FIG. 24A Hardware-Software Interfaces

Indicates hardware components connecting to the Internet Of Things Gateway processing chip and integrated sensor and remote control system

Virtual power plants of micro-task based energy under current energy market constraints allows further optimisation of systems. Allowing greater scalability and orchestration, by deconstructing the entry price to market of energy storage eco-systems and scope for measuring and capturing subsidization or reward on efficient energy use and operations.

Modular DIY micro-energy storage-building systems can reduce financial burden of the state infrastructure budgets and estate infrastructure development.

Peak energy demand will be buffered and offset with the task specific usage and energy storage economics, as demonstrated with the uptake of the rooftop solar market.

Infrastructure asset share prices are fluctuating to the financial controls of monopoly/market forces and policy challenges. The hypothesis is that DIY energy storage integrated into our building spaces and furnishings creates opportunity for infinite storage solutions depending on the embedded price of the battery technology and the by-products at the end of life.

Task based energy usage will reduce the overall peak loads of the fixed grid network, and enable micro-scale power usage optimisation for renewables (plug in renewable grid supply and localised built in renewables).

The agile use of orchestrated task-based energy storage enables alternative uninterrupted power solutions in more generic terms equivalent to the analogy of a water vessel that contains water which can readily, clearly and visably stored, used and transferred.

For example, reliance of charge points for long haul electric vehicles can be supplemented or substituted with change-over stations for electric vehicle battery cell substitution. Acting interchangeably from the semi-permanent energy storage structure or energy storage array that is easily mechanically dispensed and documented (e.g. using Global Positioning Systems (GPS) and Geospatial Information System (GIS) mapping in combination to sensors for monitoring motion, acoustic, moisture and thermal performance where relevant for refrigerated cargo).

This example is such that battery cell and its housing, is a non-permanent attachment and equivalent to an asset comparing a freight container is to a delivery truck using freight cargo trailers. Various battery technologies can be made accessible and transferrable, as part of a operating system/ecosystem

Micro-storage grid islands allow for bespoke efficient use for all variable forms for energy generation, storage and settlements in remote areas without any other grid infrastructure.

Integrated DIY-energy storage & building systems can enable emergency response or basic infrastructure contingency during catastrophic events. A building material energy storage DIY system that enables “low/no skill levels” to deploy this technology—benefits quality of life and ability to redirect critical resources to higher priority issues. For example in space, if an air-lock compromise where to occur from meteorite strikes, the priority is activating energy to systems to ensure the air-lock is re-established quickly. The use of the decentralized power supply systems provides emergency response times faster and easier, without requiring significant skill, time and effort to deploy.

Smart software-application based systems can introduce baseline knowledge in user friendly form, using technology aids whilst reading instructions for assembly and understanding simple control interfaces. These systems of smart components that can be assembled using visual aids (e.g. remote screen/projection/camera/phone) providing an interface away from meta-verse, and aligning towards scaled back virtual reality, prioritizing visual aid for assembly and alternative options for configuration.

### FIG. 24b Internet of Things Gateway Architecture:

The following is an outline of datasets to and from various assets to which data streams will interact between the cloud, the embodiment hardware (using remote algorithms and user control settings and features for various user type and asset classes) and the telecommunication devices/smart technologies/Personal Computer/optional localised server and main console panels.

SYSTEM ARCHITECTURE DATA STREAMS—Interaction of the algorithm outputs of the three components listed below.

### Part 1: Energy Storage Array:

Data Streams for Each Location Program Encrypted End To End, Data Stream “1”, “2” . . . “n” for n-infinity Array “1”, “2” . . . “n” for n=infinity (Notation for D“n”A“n”), Add On Data Stream PB “1”, “2”, . . . “n” for n-infinity (Notation for PB“n”), optional Electric Vehicle to Grid setting for system optimisation, User Personal Details, Address, Date of Purchase, Installation, Cell Chemistry, Manufacture Origin, Warranty, ID Reference, Housing Type, Battery Specifications, Time, Temperature, Current, Voltage, Watts, GPS Location (Mobile & QR Code mapping), Optional Appliance Input, On/Off Remote Control, Usage Metrics and Configuration, Cell Configuration, Load Demand Analysis, Battery Management Settings and Systems Re-charge Settings, Outlets, Busbar configurations, expander bars, inverters in use.

### Part 2: Cloud/Server Features:

ENCRYPTED DATA SOFTWARE, Artificial Intelligence, Operations for Operational, Optimisations, Spatial Configuration Mapping of Data, Analytics for Asset Class, Optmisation in combination with other software feed, metrics unrelated to the modular system for overall, system optimisation and reporting (risk, safety, maintenance and operations),

Part 3: Synchronised Mobile Devices and Smart Technology Devices (e.g. Computer/Wireless Technology/Tablet/Mobile Phone Etc)

Includes Localised Storage Setting Data, Temporary Control Settings, and Fail-Safe Controls and Configuration when Internet Cloud Connection isn't available), Includes User Category, Access Control Levels to Monitoring and Settings, Includes Virtual Reality Projection for Guided Installation Processes of Components, Optimisation & Safety Hold Points.

HARDWARE-SOFTWARE INTERFACES (Data Transmission): Indicates hardware components connecting to the Internet Of Things Gateway processing chip. Diagrams illustrate and list various components which are showcased through out from FIGS. 28 to 50, Hardware and software will interact and integrated sensors, remote controls and data stream algorithms (including Artificial intelligent programs from the multi-variable inputs). The interoperability and communications is described in the text outlining the core-modules inter-connectivity and communications, as well as outlined in the embodiment sections following the text describing FIG. 50. Such as: SCALED INSTALLATION, ASSET MANAGEMENT, REMOTE CONTROL CONFIGURATION; VIRTUAL POWER PLANT; and RENEWABLE SOLAR SPONGE.

### FIGS. 24C-24H:

### Outline Summary:

These figures outline the scale and context of the Internet of Things Gateway interactions, categorisations of the data, and the scalability and intercommunications and controls of the modules remotely utilising the cloud, optional local servers and smart devices/computers. In effect this section of drawings summarises example systems between:

zoning and Block Diagrams—Remote asset management and control

Micro-Virtual Power Plant and Task Based Energy Storage Systems

Integrated software for feedback and optimisation of the task based usage

Integrated software modes for grid-charge mode, solar off grid-charge mode, Renewable Mode i.e. solar sponge mode/Wind Mode (if offset agreements in place with renewable generator/supplier)

Web-based encrypted software system with localised usage setting preferences, and real-time physical system duplication and reporting.

Streaming updates are available from localised blue tooth/wireless technology. Allowing synchronisation with the encrypted user details to their phone/computer/table using the software application that is user authenticated.

Systems can be personalised to the varied usage cases and asset classes for zonal management and control optimisation.

User systems may be combined, or separated to varied hierarchies of control

FIG. 24C: Example of a IOT array block diagram of “Built In example embodiments” (2000 W and 3000 W threshold system) relating to the main console.

FIG. 24D: Example of a IOT array block diagram of “Non-Built In Semi-Permanent” example embodiments (both with 3000 W threshold system) relating to the main console.

FIG. 24E: Example of a IOT array block diagram of “Non-Built In Temporary” example embodiments (both with 3000 W threshold system) relating to the main console.

FIG. 24F: Example of IOT array block diagram of many indicative example embodiments in clustered zoned controls within “disparate locations, rooms, buildings and vicinities indoors and outdoors”.

FIG. 24G: Example of a IOT array block diagram scale up of zone configured remote control settings from “disparate locations and disparate buildings for indoors and remotely spaced environments”

FIG. 24H: Example IOT array block diagram embodiments scaled up with “zonal controls to jurisdictional and regional areas and vicinities. Including moving assets, and agile assets within indoor environments”.

Variable usage of power include single phase, three phase, direct current and alternating current can be made available in the form of DIY modular-building materials for all usage scenarios when installed at scale.

This invention allows the easy use and creation of energy hubs and use of power in agile ways. Built in-floor plan power cabled systems can be used less, when implementing micro-decentralised charging kiosks and monitored micro-scale controls. Eg. For libraries (as computer workstations are spread throughout the campus through hot desks and meeting rooms). Fixed installations can be phased out for staff meeting rooms etc.

The Internet of Things Gateway, allows user-configuration controls that can be personalized for the usage case. E.g. for public setting, the open spaces energy hubs will be designed to allow limited energy draw that is surplus to the solar access, relative to the usage demand. In converse, a university campus library can set timers on the power bank to switch off until returned to the charging bay 30 minutes before closing, when students have finished hot-desking.

FIG. 24H: Building infrastructure (Commercial, Industrial, Education & Community Assets): Variable usage of power include single phase, three phase, direct current and alternating current can be made available in the form of DIY modular-building materials for all usage scenarios when installed at scale.

This invention allows the easy use and creation of energy hubs and use of power in agile ways. Built in-floor plan power cabled systems can be used less, when implementing micro-decentralised charging kiosks and monitored micro-scale controls. Eg. For libraries (as computer workstations are spread throughout the campus through hot desks and meeting rooms). Fixed installations can be phased out for staff meeting rooms etc.

The Internet of Things Gateway, allows user-configuration controls that can be personalized for the usage case. E.g. for public setting, the open spaces energy hubs will be designed to allow limited energy draw that is surplus to the solar access, relative to the usage demand. In converse, a university campus library can set timers on the power bank to switch off until returned to the charging bay 30 minutes before closing, when students have finished hot-desking.

### FIG. 25:

Materials Engineering Disclosure of standard and non standard materials “Unique Pre-cast Housings”

Bulk Composition, Formulation and Fabrication Details Materials Engineering Technical Disclosure (M1, M2, M3.1 and M3.2 from FIG. 23)

1. Non-Unique Materials Engineering of Housings (M1, M2 and M3.1 or M3.2 from FIG. 23)

Variable aspect ratios and depths relative to battery cell form factors. Including solid state battery technology and future energy energy storage cells for unknown future current technology suitable for mobile/moveable energy storage of fusion energy, hydrogen energy forecast in the not to distant future.

Housings to consist of suitable engineered composition for safe contained storage and use.
e.g. Use of flame retardant materials surrounding the energy storage cells which are sealed in a water tight electrically tight vacuum pack.
e.g. Use of a heat exchange and shock absorbing materials housing the energy storage cells using a combination of closed cell foams, metallic heat transfer rods, mechanical fasteners, and adhesives.
e.g. Use of an exterior encasement consisting of polymeric, metallic, organic composition, or ceramic material to house the cell.
e.g. Use of ultra light weight minimal packaging for internal use and configuration of an existing component, for retro-fit purposes.

### 2. Unique Materials Engineering of Housings (M1, M2 and M3.2 of FIG. 3):

The unique housings consist of shapes, forms, fabrications—For Interiors & Exteriors—Bricks, Panels, Furnishings.

Consisting of variable aspect ratios and depths relative to battery cell form factors.

Consisting of variable wall thicknesses for specific loading capacities and usage cases due to reinforcement composition. Examples as follows:

2.1 Matrix Composition: Microstructural composition is described as needle like matrix of Ettringite microstructure (“C-A-S-H” calcium sulfoaluminate, or equivalent to achieve ultra-high strength concrete performance. Technically known as 3CaO-Al2O3-3CaSO4-32H2O. The mass structure, can include the low-carbon concrete technology such as Aalborg Extreme or Excel as available, utilising the FutureCem low carbon concrete technology (WO 2010/130511 A1)

2.2 Using admixtures: To create a highly durable light weight and self-healing material.
e.g. Addition of Xypex C-1000NF for self-healing of crack propagated materials to ensure product longevity.
e.g. Addition to the matrix of ultra-fine hollow sealed alumino silicate microsphere particles to enhance the ettringite ceramic composition.
e.g. Addition to any performance enhancing low carbon material by products from the circular economy and re-use market, such as silica-fume surface treated Styrofoam balls. Or fibrous weaved or knitted meshes (from organic or synthetic origins such as knitted/weaved fibreglass, weaved/knitted metals, weaved/knitted organic fibres such as hemp, konjac etc).

2.3. Using admixtures: to provide additional energy storage capability in combination to the battery cell.
e.g. additions of micro-polymer composite particles with Aluminium oxides or equivalent metal oxides. With a local embedding of electrochemical compatible particles. Such that. they locally interact to create a network of micro-cathodes and micro-anode interactions. Such that the housing itself can act at a energy storage cell in combination with the larger system's technology as outlined in this patent.

Casting into the structure to form a pre-fabricated panel for either indoor or outdoor use, including potential use for under high pressure or vacuum environments.

Examples of Fabrication include:
e.g. Pre-cast structures utilising following methods of injection nozzle or pre-cast assemblies using multiple layers (3d printed or poured) utilising calcium alumina and water dispersing polymeric cement additives to accelerate and or slow cure concrete joint bonds.
e.g. Pressure cast or gravity fed casts requiring high frequency vibration or shaker pads for removing de-aeration or pin-hole defects.
e.g. Pre-cast and cured panels will demonstrate water resistance and fire resistance through the choice of fire resistant additives forming part of the matrix.
e.g. Including additional layers into the product consisting sacrificial coatings and retrospective insertions of injection moulded items that can act to seal and plug any access component/item than needs either electrical isolation, physical isolation or water-tightness. For purposes of creating safety from electrical hazards.

2.4 Composite nature: Pre-cast panels can include cast in fasteners for structural interconnections and interfacing electrical fastenings to battery cells. Or additional retrospective additions of Glass Fibre reinforcement mesh, bolts or equivalent, that is contained/sandwiched between panel fabrication layers via pouring, casting or nozzle injection. For primary purpose of ensuring structural integrity of the bulk housings and additional fastening interconnects.

2.5. Housings to be compatible and interconnectable—structurally interfacing with elevated plinths, surfaces or surrounds raised separately from the natural floor surface level

Pre-cast panels may be supported for 500 mm from floor height level in the form of mounted legs, or structural support systems.

Pre-cast panels will have anchoring support systems to the adjoining wall or to the ceiling.

Particle Size Interactions with Fabrication/Materials Engineering:

The various particle interactions consist of interplaying materials in a bulk matrix of various particles. The ultra light high strength concrete composite, has the following particle and material additives interactions:

Matrix Microstructure: Needle like Ettringite microstructure (C-A-S-H) i.e. calcium sulfoaluminate
e.g. Utilising low carbon masonry and material compositions
e.g. FutureCem low carbon concrete technology (WO 2010/130511 A1)
e.g. Water cured fly-ash cement with Xypex subject to a 28 day immersion cure.

2. Mixed matrix of hollow alumino silicate/pearlite ceramic/high strength glass micro-spheres. Diameter of aggregates to be determined relative to the strength & requirements
e.g. Thermal Resistance, Fire Resistance, Hardness, Strength
e.g. Elastic Modulus, Water Resistance/Tightness, Density, Surface Wear

3. Additives for material re-use
e.g. Optional weight reducing fillers such as Styrofoam spheres
e.g. Optional fibre glass or recycled polyethylene micro-fibres
e.g. optional flyash and silica fume

4. For Bulk Strengthening, Heat Transfer, Insulation and Shock Absorbency
e.g. Optional addition of knitted mesh or welded metallic mesh for required structural performance

Using Marine Grade 317 Stainless Steel or knitted sock mesh in corrugated form for outdoor exposure

Using various additional layers of weaved fibre glass matting or steel mesh
e.g. various combinations of 3 mm×3 mm weave, wire gauges and threads

5. For Bulk Strengthening, Heat Transfer and Shock Absorbency
e.g. Optional Additional interlocking Glass Fibre Reinforced interlocking Knitted Mesh Socks
e.g. Knitted fibreglass in combination to knitted steel

6. Addition of fasteners and structural fixtures to support internal walls or external housing
e.g. thin galvanised steel angle attached using structural 2-pack epoxy &/fasteners

Example Composition for 15 mm for Ceramic Composite Non-load bearing panel.

### Formulation and Fabrication Variations

Microstructural composition: Needle-like Ettringite microstructure (C-A-S-H) Approximately 5 mm depth for internal and external layers, by using Aalborg concrete manufacturer product methods and recommendations

Internal sandwich layer option:

Fibrous composite admixture (micro-polyethylene/bamboo/hemp) with matrix of Ettringite (optional 0.3-3%)

Coarse hollow aluminosilicate spheres with matrix of Ettringite (optional 30%)

Recycled Styrofoam spheres with matrix of Ettringite (Optional 30% volumetric to the silica fines volume)

Assembly: Whole cast structures (in 3D) and flat cast (2D) structures will be assembled and reinforced with composite inter-layers (exposed/not) for the additional function of heat exchange/shock absorbance

Colours achieved by mixing oxides of up to 3% weight and the balance of natural product colours

Water immersion cure for 28 day strength

Single body cast, or post-cast assembly using structural 2 pack epoxy adhesive to be used for additional structural adhesion of disparate members of the housings with a mechanical locking function to secure the exterior lid and attachment to future structural members.

### Formulation

Technical disclosure includes non-standard material housing masonry engineered composite includes relatively low density (to ultra high strength concrete), waste material re-use, shock absorbing performance, heat sink capabilities water tightness and crack healing, and non-volatile flammability.

Most Recent Testing has presented that this composition delivers exceptional strength and toughness relative to weight.

Batch: For Resilient 15 mm Pre-cast Panel Composite Concrete (1 kg Batch):

Add 450 g Cement (Using White Cement—Cement Australia https://www.cementaustralia.com.au/products/white-cement) or equivalent

Add 300 g Flyash (Using Cement Australia Fly-ash https://www.cementaustralia.com.au/products/fly-ash)

Add Volumetric Equivalent 750 g of the above cement content using City Mix (Using https://www.mandct.com.au/shop-2/gfrc-mix-products/city-mix-lightweight-concrete-additive-100-1/)

For the combination of volumes of 1-3 having an equivalent range of 30-70% of the siliceous material content by weight Examples of siliceous material include use of fly-ash, silica fume, or cement based equivalent

NOTE: Further examples of siliceous material content include the use/addition of pearlite or glass alumino silicate micro-spheres of varying porosity and sizes (sealed or unsealed, solid or hollow spheres). Using the volumetric equivalent to the weighed proportions for “typical” siliceous material additives such as fly-ash, silica fume, and or cement. However, the range of pearlite or glass alumino silicate micro-spheres of varying porosity and sizes additive can be from 0-70% of the volumetric proportion of the siliceous additive noting that the binding properties between the matrix will vary.

Add Trinix Glass Fibre Reinforced Concrete additive 26.25 g Using https://www.mandct.com.au/shop-2/gfrc-mix-products/trinic-tec10-gfrc-admix-polymer-2-27-kg/)

Add 26.25 g Micro-polymer fibre (https://emesh.com.au/)

Add 1% (of 750 g of Xypex): 7.5 g C-1000 NF formulation (https://www.xypex.com.au/products/admixtures/xypex-admix-c-1000-nf)

Add 37.5 g of oxide colours

Add water 34% of 750 g: 255 mls

Mix thoroughly with a drill concrete mixer until combined prior to adding fibres

Mix with half the water for 3 minutes

Mix with the remaining half of the water for another 3 minutes (6 minutes in total)

Cast into the mould and water cure with intermittent 24 hr dry cycles at 7 days and 14 days. Ensuring other days are immersed in water for 28 days.

Pending further research, using other proprietary products in part as composite layers cast, as listed in this specification e.g. such as Aalborg Excel, and Aalborg Extreme (for production and use with the above in variation to the products listed (pearlite and glass hollow micro-spheres) for structural performance of these pre-cast structures.

Standard use of polymeric water dispersants and surface treatments will be expected to be used to achieve a multi-layered composite product interfacing the substrate or nozzle.

For example use of Ultra High Strength Concrete such as Aalborg Extreme or Excel etc, utlilising the FutureCem low carbon concrete technology (WO 2010/130511 A1).

For example use of Xypex C-1000NF for self-healing of crack propagated materials to ensure product longevity.

For example use of material by products such as fly-ash and silica fume for carbon sink and circular economy benefits.

For example use of by product materials such as Styrofoam, and polyethylene for reducing density.

For example use of knitted fibre glass and or fine gauge wire marine grade stainless steel mesh for composite panel stiffening and toughness and enhancement.

For example use of by-product for low-density micro-ceramic hollow spheres/balls (of pearlite/silica glass) for enhancing fire resistance/retardation and strengthening.

The material pre-cast sheet/sections are crafted in variations to achieved desired structural and physical performance.

In addition to the use of various fasteners and structural adhesives etc.

Variants of these pre-cast housings will be designed and manufactured for specific load requirements/thresholds.

For example, battery modules that can stack up from heights up to 2.5 m will have a singular material consistent housing.

Alternatively, heights above 2.5 m will have a varied range of material housing modules for the base of the structure to increase load bearing capability.

Also structural additions to enhance the stability of the modules is available, subject to structural design certification and as-constructed certification for the given usage.

4. This invention includes all housing types. Current focus in on composite engineered masonry exterior housings. With emphasis on performance attributes of electrically isolated, thermally stable and resisting fire, good thermal conductivity profiles required for the relevant battery technology, and water tight.

With consideration of Circular Economy re-use and re-purposing at the end of life of the product material.

Noting that the housings supporting the batteries aim to have differentiated shock absorbance to protect the cells, compared to typical aluminium and polymeric housings. Via the housing and combining shock-absorbing materials/fasteners operating as dampeners. E.g. Spring steel heat exchanges, or knitted steel wire.

Architectural Finishes:

In relation to the materials and compositions, oxides and masonry glazes will be used to enhance/personalise final finished surfaces to achieve relelevant surface durability, hardness, smoothness. Including using unique cast surfaces to create a raft of surface finishes. E.g. glossy, matt, smooth or embossed for bespoke surface replication (via 3D printed mould surfaces or equivalent through casting surface substrates.

### FIG. 26

Materials Engineering Disclosure of non standard materials “Unique Pre-cast Housings” Outlining Composite Layered Structural Reinforcement Methods for Material Strengthening, Heat Sink and Shock Absorbing Housings.

FIG. 26 illustrates the embodiment materials engineering, in the section (accounting for one or more layers) cast including various forms of knitted mesh intertwined with knitted fibre glass mounted in either corrugated wave forms, cylinders and sheets. Either cast partially in or fully into the unique material housings of example embodiment housings.

The advantages of casting the materials into such configurations include the ability to vary the depth of the knitted mesh (with both or either steel or fibre glass intertwined together or separately) being cast into the structure. Allowing variation to install specific:
(1) Variations to the rigidity of the dampening support/elastic spring back from the housing onto the supporting module M3.2 contained in the housing.
(2) Variations to the thermal transfer/heat sink performance capabilities to the bulk housing M3.1 material's thermal mass.
(3) Variations to the tension of the intertwined mesh diameter and knitted density to vary the weight to strength ratios of the housing.
(4) Variations to the tension of the intertwined mesh in the bulk housing to enable pre/post tensioning prior to the cast form to enhance the cast-in compressive strength capabilities of the housing bulk strength, relative to the density and strength of the material's choice of additives to offset weight to strength ratios.
(5) Variations to the numbers of layers and cross linkages is available to the intertwined knitted steel&/fiberglass, sectional shapes and wave forms relative to the size and dimensions of the bulk material cross sectional thickness, spanning surfaces and shape.
(6) Variation to the knitted steel specification type varying from Marine Grade Stainless steel to enable ensure material stability to outdoors and chemically aggressive surface environments. Or steel types for indoor environments that are more chemically stable and tolerant for example spring steels,

### FIG. 27

Examples of Materials Fabrication Housing Forms and Enclosure Types to contain battery cell and associated components. Unique Pre-cast Housings

These figures illustrate examples of the range of enclosures to which the preferred embodiment can take into form. The variations of Profile Fabrication Enclosure Interlayers are provided for purposes of example, including the use of 3d printing to assemble and cast forms, to create multiple layers to be cast.

FIG. 27A—Sectional View: Indicative Fibre Glass Reinforced Mesh interfaces for mechanical fastening attachment points (cast in)

FIG. 27B (square)—FIG. 27C—(Circular)

Sectional View: Complex casting/3D print scenarios of in-cast structural and non-structural elements of a cross sectional

solid with vertical and horizontal supports and fastening points. Light weight facia panels can be added to close the 3D solid faces, Can include multi-step pours

FIG. 27 D—Sectional View: Various Rectangular structural

Closed and open 3D cube forms to suit cell and electronics requirements

FIG. 27E Sectional View: Various Rectangular structural

Closed and open 3D cube forms to suit cell and electronics requirements, Reinforced and partitions with additional forms

FIG. 27F and FIG. 27G—Sectional View:

Flat panels containing the battery cells built in combination with additional forms such as furniture, structural supports to buildings, furniture, architectural linings, facades or outdoor planter features, and street furniture for community amenity.

### FIG. 28

Example of an Embodiment using a particular battery cell form/technology—detailing the bus bar End Caps and cell housing terminal interactions.

This is an illustration of M1 and M2 in greater detail indicating the bus bar interconnections of the cells. The mounts of the electrically conducting bus bars are housed similar in appearance to the bulk material M3. Such that when encaps M1 and M2 are in position (including water tight seal options), that the components appear to be one single body/form. It is aesthetically optional to make M1, M2 and M3 matching or not, equivalent to tiled surface aesthetics and configurations. Including the varied aspect ratios for purpose of structural and aesthetic advantages.

### FIG. 29

Core Module—Indicative Bus Bar—Sliding Track—Plug In connection.

This diagram illustrates the introduction of additive components to M1,M2 and M3. This provides and example of adding a Tracking Rail Housing Encapsulating the Bus Bar, for the purpose of allowing users to configure the corresponding power outlet to varied locations nominated by the user.

The tracking rail, when mounted with a power outlet dock, can include an optional inverter so that either direct current outlets (USB A, USB B, or USB C or equivalent), light sockets 240V power supply (or equivalent e.g. industrial 3 phase) plug connection.

### FIG. 30

Core Module Indicative Bus Bar—Sliding Track Power Outlet (12V Example—Introducing Tracking Rail, Power Outlet and Dock

This is a more detailed illustration introducing the interaction of conducting components and how the mounting dock for the power outlets inter-connects to create a conductive bus bar electrical circuit connection. The cross sections indicate the mounting sequence and the role to which an electrically isolated fastener will allow the two members to contact each other and act as one conducting body. Further detail of these components is explained in FIG. 34A.

### FIG. 31

Expander Bar—Core Module—Example of 2×12V Modules to make 24V Array Example

Indicates the expandability/combination of modules via the interconnectable use of expander bars. The example demonstrates connecting two standard modules (for example the cell could be 12V/24V/48V) joined to make an array. The expander bars designed for specific voltages, where the electrical conducting bar is electrically insulated from the external bulk material. The Positive/Negative terminals uniquely shaped as a means to provide varied mechanical interlocks for the designation configuration and use. Such that the user will not require prior knowledge of positive or negative terminals. As the item will either compatibly interconnect or not, for the given designed purpose.

The mechanical interlocks for the specific use/shape will be specific for the given voltage and current capability. For example suitable cross section areas of conductive material relevant for 12V/24V/48V thresholds, and for high current capacity. FIG. 32

### Tracking Rail Overview

This diagram further illustrates the Tracking Rail Housing Encapsulating the Bus Bar for a larger cell array. This example demonstrates the advantage of being able to nominate power outlet location along the tracking rail length. Whereby either sacrificial perforations can be re-sealed or reusable/non reusable tamper proof plugs can be placed, such that a void is made to accommodate the power outlet mounting dock. So that the user can determine the position of the power outlet, and likewise re-locate the position if circumstance requires that to further be amended. The nature of the “sacrificial” strip is subject to the water proof nature required for the use, as much as aesthetic/functional personalisation for purposes of child resistant safety or outdoor requirements to protect against vandalism.

The tracking rail can include an “optional” inverter for providing 240V power supply (or equivalent e.g. 3 phase) plug connection.

Rail terminal plugs are mechanically designed to be only be compatible with mounts to ensure safe assembly, in this example only compatible for 24V terminals, such that the positive and negative terminals will not be required to be known by the user, other than knowing whether the interconnection will “match”.

This figure is articulating more clearly the benefit and option for allowing the user to personalise a power outlet dock with or without Direct Current power connection for various electrical connectors e.g. USB A, USB B, or USB C or equivalent and with or without an alternating current inverter (and for equivalent large battery arrays accommodate a 3-phase inverter).

### FIG. 33

Tracking Rail—Power Outlet Optional Components—Power Outlet Dock and Tracking Rail: Connection and Indicative Fastening—Symbol for Adjustable Power Supply Point

This is an illustration of the way the Tracking Rail Housing Encapsulates the Bus Bar. The tracking rail docking mount, shows the indicative cross sectional features on how the docking mount can include “optional” features, ranging from an inverter for providing 240V power supply (or equivalent e.g. 3 phase) plug connection, or 3 phase power, or a light socket, or a direct current outlet of the various kinds of connectors e.g. USB A, USB B, or USB C or equivalent.

Rail terminal plugs are mechanically designed to be only be compatible with mounts to ensure safe assembly.

Fastening points for the docking mount, tracking rail and the core modules are electrically isolated and designed to interconnect with surrounding surfaces to be a stable, structural assembly, relative to the weight and size of added components. For example the anchor points with a fastener to the tracking rail bus bar terminals are such that the connection ensures the conducting body is a full conducting body and appropriate conductivity (electrical engineered design)

Any re-located positions will require additional perforation/re-sealing of previous position to create the electrical contact.

Old position of previous perforation is to be electrically isolated/sealed and made water tight with a “plug” with either a reusable/non-reusable tamper proof plug or repaired finish to make good to original aesthetic and surface quality finish.

### FIG. 34A

### Tracking Rail, Power Outlet Dock and Coupling System

This diagram illustrates the internal components of the tracking rail and the methods to how electrical interconnection occurs.

Tracking rail housing encapsulates the expander bus bar terminals (positive and negative connecting rails). Combing the two contact surfaces of the positive and negative terminals into the fixed mechanical position, which is subsequently secured with an electrically isolated fastener to the tracking rail bus bar terminals to ensure conducting body is a full conducting body and appropriate conductivity (electrical engineered design). Such that the cross sectional surface areas are achieved to the relevant terminal/module array voltage and current requirements.

Any re-located positions will require additional perforation to create the electrical contact. As indicated by the void to which the docking mount will reside, for the electrical connection. The old position of previous perforation is to be electrically isolated/sealed and made water tight with a “plug” as described earlier.

### Design Notes for “Tracking Rail Components”:

### 1. Power Outlet Docking Base

“A” denotes the docking base of the power outlet (either Direct Current or Alternating Current) Docking base “A” has a thermal, electrically isolated and water tight housing connecting to the power outlet

Power outlet is either single phase AC/DC or 3 phase matching the particular battery array usage context “A1” indicates conducting negative terminal for power outlet docking base

“A2” conducting positive terminal for power outlet docking base A1 and A2 separated by non-conducting insulated strip

### 2. Tracking Rail Bus Bars

“B” Denotes the Tracking Rail cross section, which interconnects the positive and negative rails to the plug in points for the battery array. B1 and B2 are mounted on a rigid substrate housed to be water tight with the power outlet docking base.

“B1” indicates conducting negative terminal in the form of a rail bus bar “B2” indicates conducing positive terminal in the form of a rail bus bar

### 3. Rail Bar and Power Outlet Mounted

“A+B” denotes the power outlet docking base perforating the seal/sacrificial removal of the water tight membrane on the rail bus bar housing.

An electrically isolated water tight fastener physically pushes the surfaces so that the negative terminals and positive terminals act as one body

i.e. A1+B1 is the combined conductive body required for the negative terminal A2+B2 is the combined conductive body required for the positive terminal.

### FIG. 34B—Tracking Rail—Details

This diagram further explains the tracking rail housing. The tracking rail is effective housed in an optionally aesthetically-semi-structural fabric similar in principles to the matching material to the core modules.

The Sectional Side View of the Tracking Rail, shows the location to which the tracking rail bus bars are positioned, with the Dock/Power Outlet mounted—in electrical contact and spatial position.

Top View Tracking Rail Exterior Appearance With Power Outlet Connected indicates the “sacrificial” surface available for perforation/plugging/unplugging is aesthetically optionally disguised.

Top View Tracking Rail Exterior Appearance Connection for Charger—Electrically isolated—Removal of Sacrificial plug to use charger. Location determined relative to desired connection point along the length of the track

Top View Cross Section Tracking Rail Tracking Rail Bus Bar rails of positive and negative terminal

Indicative Perforation where the “Dock” is fastened to the tracking rail

Indicative Plug where the “Dock” was in the previous position needing to be re-sealed.

NOTE: All terminals (positive and negative terminals) are interconnected by specific compatible shapes.

Safety measures and control in the product is provided by mechanical means with the interconnecting components. e.g. Incompatible shapes of the plugs will ensure the user does not need to have prior knowledge of what “positive” and “negative” terminals are. Only when plug connectors fit will the circuit be interconnected to eventually activate the current, to enable the system to turn “On”.

So no risk of switching polarities around will occur for the specific bus bars and expander bars for the usage of 12V, 24V and 48V cells. Including usage cases of parallel and in-series arrangements.

Concealed handles and semi-detachable wheel-features to be included relative to the weight and size of various elements to assist with assembly.

### FIG. 35—

Interchangeable Component Design Between Tracking Bars and Expander Bars:

This diagram indicates the optional interchangeability of the expander bus bar connections sequences are possible. This may be a desirable option, given the tracking rails are covered, and the size of the components and connections during installation would be cumbersome to re-assemble and detach if not initially configured correctly, given the consideration to the relative weight and placement of the modules, to surrounding supports/plynths/fasteners/brackets for structural assembly to the greater context of the modules.

The interchangeability is outlined in the assembly sequence comparing “Scenario 1” from “Scenario 2” Notes. Power outlet connection compresses relevant safety sensors and latches to connect to the Internet Of Things gateway communications and remote control streams.

All “modules” have positive and negative terminals that cannot be activated/contacted unless endcaps and expander bars are inserted.

Scenario 1—Step 1 User decides the configuration interchangeably of when/how to couple the “modules” in series or retain separate functional modules Step 2 User decided to configure the modules as a 24V array

Step 3 User applies the 24V rail to draw power from the array

Step 4 User makes the “decision” for the user to personally nominate the location for the power outlet Step 5 User secures the location of the power outlet to the tracking rail base

Scenario 2 Demonstrates a change to the installation arrangement and sequence compared to Scenario 1

### FIG. 36 & FIG. 37

### Tracking Rail Bus Bar and Power Outlet

This scenario depicts the example of a 48V array (4×12V modules) with the Tracking rail. Where the advantage of determining the power outlet dock into the broad range vertical position assists user convenience for connectivity.

Likewise power outlet docking mounts can be accommodated in the single or double mount chargers rails, indicated in FIG. 41 to FIG. 45 can provided to accommodate power outlets in the vertical position in place of horizontal tracking rails connection points.

Safety measures form part of the design innovation, where the electrical interconnections are remedied by mechanical means with the interconnecting components. e.g. Incompatible shapes of the plugs will ensure the user does not need to have prior knowledge of what “positive” and “negative” terminals are. Only when plug connectors fit will the circuit be interconnected to eventually activate the current, to enable the system to turn “On”.

So no risk of switching polarities around will occur for the specific bus bars and expander bars for the usage of 12V, 24V and 48V cells. Including usage cases of parallel and in-series arrangements.

Concealed handles and semi-detachable wheel-features to be included relative to the weight and size of various elements to assist with assembly.

### FIG. 38 To FIG. 39

Power Supply/Rectified Connection Point—Example of DOUBLE SIDED PARALLEL CHARGING RAILS: 2×48V Storage Array (and parallel expander bars)

This figure indicates the introduction of the battery re-charge connection point. The optional charge point can be configured specifically for connecting battery charging plug to Grid connected power plug, Solar/Renewable charge plug, petrol Generator charge plug point or equivalent fuel cell technology interface.

The indicative power outlet, includes relevant Battery Management Systems, on/off switches, safety circuit breaker, butter knife protection systems, over load protection and Internet of Things Gateway and fast acting earth leaking switches. These power outlets are removable and changeable for the given rectifier power outlet connection required to recharge the battery array.

The role of these power supply points, it that it enables a building floor plate, or outdoor infrastructure power connection to not require pre-determined specific locations.

The role of the power supply point means that the interconnect-ability of the array, using the equivalent of in-series expander bars designed for “parallel” interconnections, such that the entire array change be charged from a centrally designated power supply point. Noting that the power supply charge point parallel rail bars can be positioned towards the ceiling height connections for ready solar roof top connection, or from the raised floor level power plug connection point. E.g. staggering the array arrangements in dual layers to achieve the parallel expander bar configurations at designated re-charge power outlet points.

It is foreseeable that these arrays will allow building floor slabs to consist of open floor plan arrangements, such that wall installations will be possible to use these preferred embodiment panels.

Note. The Internet of Things Gateway remote controls and configuration, will be able to remotely program electrical energy draw from the battery, and time the electrical grid draw to charge the modules. This is part of the optimised program system to enhance user configurations for the given programmed performance metrics.

The intelligence of the power chargers operating in combination to the modules installed, in effect make the surface area available to determine power outlet locations using the nominated energy storage fuel cells installed in modules M3.2.

### FIG. 40—

### Horizontal Tracking Rails—to Connect to Power Supply Point (Example Scenario of 2×48V or Single 48V)

These details outline the horizontal tracking rails. To connect the power outlet tracking rails to any vertical and horizontal span of the array surface area.

As mentioned in the vertical tracking rails, the power outlet dock will be optionally compatible with these horizontal tracking rail plug connection points, for isolated vertical access to locate power outlets. Such that the horizontal tracking rail is not required if a user prefers to have the power outlet in vertical vicinity to the vertical power outlet connection at potential plug locations.

The various views show the external housing, electrical conductive and electrically insulative/waterproofed seals. The semi-structural encasing combine features of the semi-sacrificial insulating filler between the Positive and Negative Tracking Rails, equivalent to the vertical tracking rails design, but in horizontal configuration.

### FIG. 41

### SINGLE SIDED CHARGING RAILS and TRACKING RAIL

Illustrated is the Optional Charge Points for connecting battery charging plug to Grid connected power plug/Solar/Renewable charge plug/Generator charge plug. It includes relevant Battery Management Systems, on/off switches, circuit breaker, over load protection and Internet Of Things Gateway. Indicative Power Supply Connection Point are compatible to “Plug-In” system connections (specific design for given usage case of 12V, 24V, 48V and 240 Volt AC/DC/3 Phase etc) and light sockets.

Includes relevant Battery Management Systems, on/off switches, circuit breaker, over load protection and Internet Of Things Gateway

### FIG. 42

DOUBLE SIDED PARALLEL CHARGING RAILS & HORIZONTAL TRACKING RAIL POWER OUTLETS CONNECTED: 2×48V Storage Array—Plinths and Water Tightness Designations for Inundation

This provides an overlay of the electrical interconnections of the components of the core modules, the power outlets, and parallel charging connection points, linked to the Internet of Things Gateway.

This example shows the embodiment installed on a raised plinth/slab to protect the cells from floor surface inundation. It is required that the installation consider environmental safety conditions, such as risk to inundation, whereby the housings for M3.1 and 3.2 must be engineered appropriately to withstand the hydrostatic pressure of IP 67 or TP68 and the variations of water tightness.

### FIG. 43

### External Appearance of Modules—Double Sided Parallel Charging Rails & Power Outlets Connected: 2×48V Storage Array

This illustrates specifically the example where the embodiment has spanning ability to locate the docking mounts into locations ranging relative to the tracking mounts.

FIG. 44A

### Double Rail Bus Bar Add on for Battery Modules—Power Supply Connection Point and Cable Connection Point

This is a detailed illustration of the vertical plug in points to support the horizontal tracking rails. It indicates the internal circuits of the rail bars and the connections to the re-charging power connections.

Note. The plug in locations to accommodate the horizontal rail bars are indicatively aligned to the tracking rail bars' optional sacrificial removable plugs compared with the reusable/non-reusable tamperproof plug options to electrically isolate and optionally make water tight, flush with the surface finish. To disguise locations of the plugs for either aesthetic and functional advantage.

### FIG. 44B

### Single Side Rail Bus Bars—Overlays and External Views

These diagrams illustrate the single rail equivalent of the of the double parallel charging rails, whereby it accommodates the horizontal tracking rails and associated power outlets.

### FIG. 45A

Interconnectable Parallel Charge (Rectifier) Cable Plugged into Power Source—Cables

Indicated are non-rigid interconnections by use of flexible cables, in substitution of rigid expansion bus bar inter connectors. The advantage of this is to allow power connections into ceiling cavities or across spatially restricted contexts to enable maximum interconnectability.

The re-charging power connection point/rectifier allows the array to extend into a disparate location/distance of “Room 2”, from “Room 1” power outlet connection point.

The choice of panels to insert into the charging rail, accommodates a maximum number of arrangements.

### FIG. 45B—

Various Adapters—Single Charge (Rectifier) Power Outlet Removed and Reconnected with a Centralised Double Charger (Bus Bar or Cable Option of Variable Lengths)
This illustration shows a de-centralised option of the rectifier configuration relative to the original individual rectifier locations. The two individual rectifiers are removed, and replaced with a larger capacity rectifier to parallel charge the 2 separate arrays is separate locations, utilising flexible cables to accommodate flexibility in the interconnections from the power supply points from the grid, generator or renewable energy source.

FIG. 46

### Embodiment Example 2—Pre-Assembled Housings and Modules (with and without Cells)—Detailed Example of SCENARIO IN FIG. 18-19, and FIGS. 21-22

This diagram indicates battery cells assembled in more generical hollow cube modules that could be used for purposes of inbuilt walls or book shelving and storage, with or without cells. The of using the expansion claps and rectifiers can allow all variations of built structures integrating “plug and play” style assemblies. whilst including semi-structurally engineered components. This example embodiment emphasises the opportunity for utilising the technology for emergency response and infrastructure contingency.

This example provide a clear indication that this embodiment can consist of an assembly of core Modules, where M1, M2 and M3.1 are installed first. Then when resources allow, users can install Modules 3.2 subsequently.

Note. Installation of the Modules 3.2 in retrospective form, would be forming part of the Internet of Things Gateway semi-virtual reality installation feature utilising the 3-dimensional parameters of the module geometries and the Geospatial Information System mapping models and the Geospatial Positioning Satellite synchronisation.

### FIG. 47

### Other Embodiment Variant—Complementary Fence/Wall

This illustrate an example embodiment of an outdoor fence/wall/screen for permanent installation.

The multi-function is being demonstrations using these modules as either a micro-grid asset, an uninterrupted power supply or grid connected asset which can provide open spaces amenity for public and private hard landscaping.

This is a demonstration of aesthetic rugged finishes suitable for chemically aggressive environments or saline water conditions. Surface treatments and finishes can be embossed and textured to suit aesthetic preferences.

This example is how scalable single phase power or 3 phase power inverter power outlet connections would provide great convenience and amenity.

### FIG. 48

### Commercial/Industrial Building Wall/Partition—Indoors/Outdoors Engineered for User Requirements

This diagram illustrates the commercial, industrial, education and open spaces embodiment for larger surface areas/volumes.

The variable usage of power include single phase, three phase, direct current and alternating current can be feasibly made available to scale. Using combined features of the remote controlled virtual power plant capability or solar sponge asset configuration settings utilising the Internet of Things Gateway.

commercial fit outs could benefit with modules, components and appliances, given that the components are additive and subtractive, and relocatable and reconfigurable.

### FIG. 49—

### Retro-Fit Energy Storage Add on for Lamp Post/Street Light

This illustration shows one of the modules retrofitted around an existing light infrastructure. Housings can be designed for relevant aesthetic and functional forms. e.g. Including planter systems and banner rails.

Associated materials used as unnecessary solid sections or voids—are now opportunity to become highly multi-functional for smart battery storage and power outlets, and associated necessary equipment in appliance-type “safe” housings.

“Dead” space is now an opportunity for incorporating energy storage systems. Ranging from ceiling cavities, building facades to outdoor street furniture and lighting infrastructure. The context of high cost real-estate can now be further optimised with space efficient solutions that can benefit owners and users with more financial gain.

This light post can be an example of an asset forming part of the Timed Energy Usage timers, to enable optimised settings for the renewable energy generation source, the Do-It-Yourself assembly would be resolved from installing Automatic Switch Controller (ASC) Plug In such that the array can be expanded from the given location.

### FIG. 50

Detached Mobile Table Topper Shelf with Outlet as Additional Furnishing (can be Removed and Used in Car or for UPS Away from Main Purpose)

Illustrated is an example of modules that are built into the kitchen island bench to be part of the kitchen cabinetry. The cavity within the cabinets can further include expansion connections to the components to interconnect with power outlets and concealed energy cells.

Removable modules can be added to other shelving components and added as or be part of cabinet wall structures and various partitions—to suit designated spatial geometries for storage of appliances/goods whilst also providing power supply outlet points for user convenient.

These modules are available for providing either back up power supply or general energy storage solutions for configuring new power outlet locations without need for cables. As charge points/rectifier connection points are housed in non-conspicuous and non-visually prominent places. Whilst providing the same amenity as a Uninterrupted Power Supply power bank, or providing optimisation of utilising energy storage during peak solar generation.

Module housings can remain empty in anticipation of buying future energy cell technology to be readily interconnected.

In-Built Concealed Outlet and Larger Energy Bank consisting of Cabinetry

Concealed Energy Bank Kitchen Island Bench

Cells Protected with Structural Housing Fit for Purpose/Load, Non-flammable housing compartments Surface finish adjustable to architectural personalisation preferences (e.g. oxide colour to order/painted/raw/terrazzo)

### Scaled Installation, Asset Management, Remote Control Configuration:

The Internet of Things Gateway (as discussed in the figures), provides the service of data management and asset management. Utilising large scale data management systems of the built-in energy storage building material will allow micro control optimisation (using large scale asset management techniques and strategies).

The system enables “Collective Power Optimization”: System controls will allow collective cumulative virtual power plant calculations and offsets. Working in conjunction with current energy market—supply, generation and usage parameters.

Micro-energy optimisation systems including energy storage into building Do-It-Yourself (DIY) products will allow greater scalability, by deconstructing the entry price to market to be lower and enabling the user to progressive purchase their asset.

This invention will enable greater use for “energy hubs” and use of power banks with mobility and agility. The role of built in-floor plan power cabled systems can be used less, when implementing micro-decentralised charging kiosks and monitored micro-scale controls. Eg. For libraries (as computer workstations are spread throughout the campus through hot desks and meeting rooms). Fixed installations can be phased out for staff meeting rooms etc.

Building construction floor plans will only require generic power “spines” for direct charging. Floor plan usage and re-design will not require additional detailed trades to install cables and conduit trays with as much specificity in the detailed design drawings. Due to the changeability and placement of the power sources and its vicinity to the linkage of the power storage and connections.

Remote settlements and farming will benefit from the micro-storage grid islands that this invention allows. Providing bespoke efficient use and placement of energy storage and supply in all variable forms without any other grid infrastructure.

### A Variation to the Virtual Power Plant

Current Virtual Power Plant technologies currently operate on the basis of wired-in technologies such as Electric Vehicles, domestic wired in power walls, and estate batteries.

Task based energy usage has been overlooked. Focused on the large scale utility oriented power supply.

Not including the micro-energy storage potential contained in isolated home office work stations, entertainment systems, lighting networks and electrical appliances people are reliant on in every day usage contexts. As outlined in these example embodiments.

The Internet of Things Gateway, provides a user the system engineering and optimisation interfaces, guided by the product design and the software interface using an “Internet Of Things” (IOT) installation and Artificial Intelligence algorithmic settings.

The examples of preferred embodiments, using “smart construction materials”, provide integrated software and hardware systems with smart devices/mobile phones and personal computer control options for management.

This system of modules and technology, allows ordinary people to assemble “Smart” construction materials into the context of an array of assets to remove the safety risk and complex services protocols out of the equation.

This invention resolves the problem from its integrated system engineering and optimisation. The IOT gateway can work alongside built-in power supply data systems, and wired in third party energy storage. The cost optimisation arrangements of the feasibility and interchangeability and interoperatability of other battery systems. E./g. Optimisation and coordination of systems electrical charging of Electrical Vehicle to grid protocols. E.g. third party battery application that may need greater energy storage and can be expanded upon, utilising this invention's Internet of Things Gateway.

It provides the user guided step-by-step services for the specifically designed products and components with a software interface using an “Internet Of Things” (IOT) Gateway. This is the safety engineered interface to assist additional “safety engineered” outcomes.

The battery management systems and sensors are designed to capture data and metric calculations both on the user's own smart device with encrypted end-end data transfers that are personalised to determine relevant data streams to the cloud.

This example preferred embodiment includes Geospatial Information System coordinates and optimisation using AI (Artificial Intelligence) and kiosk user experience scenarios for the given usage cases. Including automated sharing of “data insights”, and automation of battery and other household operations via the IOT Platform.

This example preferred embodiment leverages its functionality from sensor control systems including various safety thresholds for protection of the hardware and the user's need. Controls include identification of asset management “risk” profiles that indicate safety inspections, servicing and maintenance of particular components and modules.

This example preferred embodiment has capacity to obtain dimensional data from camera captures and inputs for the usage case of the modules. So that the system is able to generate modelled with various configurational options. Maximising the interchangeable use of components. This is in effect operating as a pre-emptive and intuitive installation guide specific to the physical circumstances. The configuration is saved in the user account and for monitoring and management purposes for battery life.

### Renewable Energy Sponge:

This example preferred embodiment can provide assistance with the peak energy demands. Acting as a buffer and offset with the task specific usage and energy storage economics. Variations to the preferred embodiments can be used to mitigate the cost of energy and infrastructure assets for low carbon-based economies, Infrastructure asset share prices are fluctuating to the financial controls of monopoly pyramid structures. The hypothesis is that DIY energy storage integrated into our building spaces and furnishings creates opportunity for infinite storage solutions depending on the embedded price of the battery technology and the by-products at the end of life. These cells can be established in various arrays for industrial estates in pre-cast formations for larger scale usage and semi-permanent

This invention integrates these key elements to achieve and collectively include micro and low voltage energy systems interfacing with high voltage energy systems.

This invention provides large-scale intelligent systems and control in micro-forms and spaces. Capturing the remnant energy efficiency opportunities through remote control data systems. This technology is not currently available in the art of energy storage, particularly in relation to coordinating micro-energy storage, where the optimization can account for large scale impact.

This invention is capturing micro-opportunities to optimizes on the spatial and financial burden of centralised infrastructure. The current art of energy efficiency focuses on centralized large scale assets built to achieve the benefit of large scale energy savings. The current arts appreciate building powerbanks to estate substation powerbanks. Virtual power stations are accounting for the larger scale and usage of powerbanks and energy storage.

Combining building materials, electricity-energy storage product markets creates savings in materials, energy and money whilst reducing carbon.

This invention is providing user interface “portal” for both operation, management and maintenance of their asset. The direct nature of this database-user control system is to ensure total quality management in the lifecycle of the product's use, installation and operation.

### INDUSTRIAL APPLICABILITY

Embodiments of the invention may be applied to built structures in a domestic or commercial or industrial context thereby to provide built structures having additional functionality of electricity storage and distribution.

1-167. (canceled)

168. A modular, interconnectable structural housing structure comprising:
an enclosure having wall components which define an internal volume within the enclosure separated from an exterior of the enclosure by the wall components;
wherein the enclosure includes electrically conductive components of a power circuit for communication of electrical signals from the internal volume to the exterior of the wall components of the enclosure, wherein sensor control fail safes provide verification to ensure plug connectors of the conductive components are correctly interconnected.

169. The structure of claim 168, wherein the internal volume encloses an electrical storage component.

170. The structure of claim 168, wherein one or more of the modular, interconnectable structural housing structure forms part of a built structure.

171. The structure of claim 168, wherein one or more of the modular, interconnectable structural housing structure forms an entirety of a built structure.

172. The structure of claim 168, wherein structural housing structures are interconnectable mechanically with adjacent structural housing structures.

173. The structure of claim 168, wherein structural housing structures are interconnectable electrically.

174. The structure of claim 168, wherein the structural housing structure has timers, rails, inverters, rectifiers, switches, bus bars and outlets, and wherein the structural housing structures, timers, rails, inverters, rectifiers, switches, bus bars, and outlets are stackable.

175. The structure of claim 168, wherein the internal volume encloses sensors, wherein the sensors include Internet of Things (IOT) sensors.

176. The structure of claim 168, wherein electrical interconnection facilitates communication of electrical power, charge, discharge and power optimisation.

177. The structure of claim 168, wherein electrical interconnection facilitates communication of electrical power from within a structural housing structure to external of the structural housing structure.

178. The structure of claim 168, wherein electrical interconnection facilitates communication of electrical power between structural housing structures.

179. The structure of claim 168, wherein electrical interconnection facilitates communication of electrical power between built structures.

180. The structure of claim 168, wherein electrical interconnection facilitates communication of communications signals for communication between structural housing structures.

181. The structure of claim 168, wherein electrical interconnection facilitates communication of communication signals for communication between built structures.

182. The structure of claim 168, wherein the wall components form a contiguous surround of the internal volume.

183. The structure of claim 168, wherein the wall components include more than one veneer, whereby an outer veneer is overlaid over and coextensive with an inner veneer.

184. The structure of claim 168, further comprising materials, wherein the materials include a heat sink.

185. The structure of claim 168, further comprising materials, wherein the materials impart a shock absorbent characteristic.

186. The structure of claim 168, further comprising clasps, wherein the clasps are electrically conductive so as to function both as a clasp and as an electrical conductor thereby to maintain juxtaposed enclosures mechanically connected when the clasp is in a clasping position and to conduct electrical signals between the juxtaposed enclosures.

187. The structure of claim 168, wherein the internal volume also encloses a single way or bi-direction vents, wherein the single way or bi-direction vents provide pressure, water, or thermal regulation of the internal volume.
